(19) United States
(12) Patent Application Publication
(10) Pub. No.: US 2026/0287629 A1
(43) Pub. Date: Sep. 24, 2026

(54) DETECTION OF ELECTRIC DISCHARGES THAT PRECEDE FIRES IN ELECTRICAL WIRING

(71) Applicant: Whisker Labs, Inc., Germantown, MD (US)

(72) Inventors: Robert S. Marshall, Ijamsville, MD (US); Christopher Dale Sloop, Mount Airy, MD (US); Stan Heckman, Chelmsford, MA (US); Donnie Bixler, Woodsboro, MD (US); Emma Hoppmann, Rockville, MD (US); Christian Pedersen, Germantown, MD (US)

(21) Appl. No.: 19/685,489

(22) Filed: May 22, 2026

Related U.S. Application Data
(63) Continuation-in-part of application No. 18/239,512, filed on Aug. 29, 2023, now Pat. No. 12,650,452.
Application No. 18/239,512 is a continuation of application No. 17/670,691, filed on Feb. 14, 2022, now Pat. No. 11,754,607.
Application No. 17/670,691 is a continuation of application No. 16/811,756, filed on Mar. 6, 2020, now Pat. No. 11,249,125.
Application No. 16/811,756 is a continuation of application No. 16/359,755, filed on Mar. 20, 2019, now Pat. No. 10,641,806.
(60) Provisional application No. 62/645,743, filed on Mar. 20, 2018.

(51) Int. Cl. G01R 27/28; G01R 31/00; G01R 31/08; H02H 1/00

(52) U.S. Cl. CPC G01R 27/28; G01R 31/001; G01R 31/085; G01R 31/086; H02H 1/0015

(57) ABSTRACT

Described herein are methods and systems for detecting electrical discharges that precede electrical fires in electrical wiring. One or more sensor devices coupled to a circuit detect one or more signal waveforms generated by electrical activity on the circuit or on nearby branch circuits. The sensor devices identify one or more transient signals within the one or more signal waveforms, and generate one or more transient characteristics based upon the identified transient signals. A server communicably coupled to the sensor devices receives the one or more transient characteristics. The server analyzes the one or more transient characteristics to identify one or more electrical discharge indications. The server generates one or more alert signals when one or more electrical discharge indications are identified.

### RELATED APPLICATIONS

This application is a continuation-in-part of U.S. patent application Ser. No. 18/239,512, filed Aug. 29, 2023, which is a continuation of U.S. patent application Ser. No. 17/670,691, filed Feb. 14, 2022, now U.S. Pat. No. 11,754,607, which is a continuation of U.S. patent application Ser. No. 16/811,756, filed Mar. 6, 2020, now U.S. Pat. No. 11,245,129, which is a continuation of U.S. patent application Ser. No. 16/359,755, filed Mar. 20, 2019, now U.S. Pat. No. 10,641,806, which claims priority to U.S. Provisional Patent Application No. 62/645,743, filed on Mar. 20, 2018, the entirety of each of which is incorporated by reference herein.

### TECHNICAL FIELD

The subject matter of the application relates generally to detection of early-stage electrical discharges, including arc faults, in electrical wiring.

### BACKGROUND

Electricity travels over conductors (“wires”) on the grid, inside the home (e.g., circuits, breaker panels, etc.), up to and inside connected devices and appliances. According to statistics released by the U.S. Fire Administration National Fire Data Center (available at www.usfa.fema.gov/downloads/pdf/statistics/v19i8.pdf, see Table 7), electrical arcing in residential electrical wiring and outlets account for over 87% of electrical fires-which are one of the most dangerous threats to life and property. Arc faults (also called arcs) are high-power, continuous electric discharges between two or more conductors-typically occurring in residential buildings when the integrity of an electrical wire or insulation is compromised (e.g., through physical damage, water damage, corrosion, age, or loose connections, among others). Events such as lightning strikes and power surges can also initiate the breakdown of insulation and lead to a compromised wire. As a result of the compromised wire, small, sporadic electrical discharges begin to occur and the insulating material that surrounds the wire is carbonized. As the electrical discharges continue over time, the insulation is increasingly eroded, and the electrical discharges increase in intensity. Eventually, strong electrical discharges become continuous arc faults that form in the wire-resulting in large flow of current and large releases of energy (with correspondingly high temperatures). Due to the proximity of the wire to wood frame, insulation, and/or similar combustible materials, when the temperatures produced by the arcs are high enough, they are likely to produce fire. It would be a great advantage in preventing electrical fires if one could detect, and be warned about, the small electrical discharges that may occur for days, weeks, or months before they become large enough to create electrical arcing (as is described in Yereance, R. A., and Kerkhoff, T., Electrical Fire Analysis, 3rd ed., page 206, Charles C. Thomas, Springfield IL (2010)).

Electrical fires occur when a conductor fails to conduct, or an insulator fails to insulate. Conductors fail to conduct because of joint fractures, the last strand of a cable breaks, an outlet, ‘push-in’ or other connection or junction on a conductor loosen, or in some other way the surface area between the conductors becomes too small to serve as a safe and reliable connection. Consequently, the lack of a quality connection can result in a high resistance connection that produces heat and leads to physical and chemical processes that oxidize the connection, further increasing resistance and heat. Electrical arcing often occurs across these poor connections depending on many factors, including but not limited to physical changes in the connection (temperature), the energy load drawn across the connection, and the changing quality (or lack of quality) of the connection.

Insulators fail where a flexible cord or rigid insulator fractures or pollutants or water infiltrates an intended insulation opening. Fractures may arise from defects in manufacturing, hammer blows during construction, or repeated stress in use. Each time a small electrical failure occurs across one of these fractures, a bit more of the insulator is damaged, (usually) extinguishing the immediate failure but (usually) facilitating future failures. Most organic insulators “char,” slowly transforming them into more conductive simpler organic materials through a process named “carbonization of insulation.” In other words, the job of the insulator is slowly compromised.

In turn, arcing along these carbonized paths produces “scintillations,” dim flashes of red, orange, yellow, or white light. Scintillations and the fault currents associated with them are sporadic and highly intermittent. As scintillations and fault currents evolve and become more active, they generate pulses with high-frequency content. These pulses propagate through the home's electrical network. This process, arc tracking, is a slow process that can take from a few weeks up to many years. These electrical discharges may eventually become continuous arc faults, resulting in a large flow of current and large energy releases (with correspondingly high temperatures) that can ignite a fire.

Electrical arcing produces impulsive signals at ignition and extinction many times in each 60 Hz electrical cycle. Impulsive signals produce broadband electrical noise, including high-frequency energy that propagates freely through home wiring, which behaves as a communications network at high frequencies.

The above-mentioned electrical discharges can occur in various ways, including: parallel, series, and line-to-ground discharges. A parallel electrical discharge occurs when current/electrons flows from one conductor to another through a gas or dielectric material because of a large voltage difference between the conductors-typically through damaged insulation or the air. FIG. 1A is a diagram of a parallel electrical discharge. The electrical circuit has two wires 102a, 102b, each of which is surrounded by an insulating material. If the insulation between the wires breaks down, then electrical discharges (such as discharge 104) can occur between the wires. Examples of parallel electrical discharges include carbonization (i.e., breakdown of the insulating material) and wet tracking (i.e., moisture on the surface of the wire that enables currents to form).

A series electrical discharge occurs when a single conductor is damaged to an extent that resistance through the conductor is increased and creates voltage differences high enough for discharges to occur within the conductor and into the surrounding insulation (or even to external objects, if the conductor is exposed). FIG. 1B is a diagram of a series electrical discharge. The electrical circuit includes a damaged wire 106 that produces an electrical discharge 108. Examples of series electrical discharges include ground pyrolysis (i.e., current flowing from the conductor to nearby wood), and last strand (i.e., breakage of the wire resulting in increase in heat and ignitable gases). A special type of series discharges occurs in a phenomenon known as a glowing connection (as shown in FIG. 1C). In such cases electrical conductors are touching, but not firmly connected together. An oxide layer forms at the boundary of the interface which increases the resistance of the conductors at the junction. If current is flowing through the interface, the temperature can rise to dangerous levels (e.g., the white area 110 shows a high temperature at an electrical outlet) which can ignite nearby materials and cause a destructive fire. By the time an electrical discharge has progressed to the point that it causes a fire, it is too late to take corrective action and prevent loss. It is important to detect the occurrence of such electrical discharges in electrical wiring as early as possible so that remedial measures can be put in place.

Technology such as arc-fault circuit interrupters (AFCI) currently exist to detect early-stage electrical discharges, such as arc faults. In electrical outlets equipped with AFCI technology, an AFCI detects arc faults in a circuit and breaks the circuit upon detection of such faults to prevent an electrical fire from happening. However, AFCIs are relatively expensive and must be installed on each circuit in a building to detect electrical discharges on the individual circuits.

Detecting electrical discharges on a circuit within an electrical infrastructure is sufficient to finding and mitigating hazards which could become electrical fires, however a further improvement would be to develop methods and technologies that allow customers and professionals to more quickly identify when and where electrical discharges are occurring.

### SUMMARY

Therefore, what is needed is a method and system that detects early-stage electrical discharges before they are large enough to start a fire in electrical wiring systems, such as those found in homes and other buildings. The methods and systems described herein provide the advantage of detecting early-stage electrical discharges in electrical wiring when they begin to form, which enables rapid notification of the potential fire danger. In addition, the techniques described herein enable the long-term automatic monitoring of electrical wiring systems for electrical discharges (e.g., weeks, months, years) to obtain detailed information on activity and trends in a building's electrical wiring system-including the ability to distinguish between different electrical discharge severity levels, monitoring for events such as surges, sags and brownouts which can initiate carbonization of insulation and initiation of electrical discharges, correlate detection of electrical discharges with the operation of appliances and devices running in the home (for example, the arcing may occur within a device such as an air conditioning unit; long-term monitoring provides the opportunity to correlate the discharges with the operation of the air conditioning unit, and the device can correlate electrical problems on the electrical grid by aggregating information from monitoring across multiple homes). Also, in some embodiments, the system leverages a single monitoring device that plugs into an existing electrical outlet-instead of complicated, expensive, or dangerous installation of other devices or monitoring components.

The invention, in one aspect, features a system for detecting electric discharges that precede electrical fires in electrical wiring. The system comprises one or more sensor devices coupled to a circuit, each sensor device is configured to detect one or more signal waveforms generated by electrical activity on the circuit or on nearby branch circuits. Each sensor device is configured to identify one or more transient signals within the one or more signal waveforms, and each sensor device is configured to generate one or more transient characteristics based upon the one or more transient signals. The system comprises a server computing device communicably coupled to the one or more sensor devices. The server computing device is configured to receive the transient characteristics from each of the sensor devices. The server computing device is configured to analyze the transient characteristics to identify one or more electrical discharge indications. The server computing device is configured to generate one or more alert signals when one or more electrical discharge indications are identified.

The invention, in another aspect, features a computerized method of detecting electrical discharges that precede electrical fires in electrical wiring. One or more sensor devices coupled to a circuit detect one or more signal waveforms generated by electrical activity on the circuit or on nearby branch circuits. Each sensor device identifies one or more transient signals within the one or more signal waveforms, and each sensor device generates one or more transient characteristics based upon the one or more transient signals. A server computing device communicably coupled to the one or more sensor devices receives the one or more transient characteristics from each of the sensor devices. The server computing device analyzes the transient characteristics to identify one or more electrical discharge indications. The server computing device generates one or more alert signals when one or more electrical discharge indications are identified.

The invention, in another aspect, features a sensor device for detecting electrical discharges that precede electrical fires in electrical wiring, the sensor device coupled to a circuit. The sensor device comprises a module that senses electrical activity on the circuit and detects one or more signal waveforms of the electrical activity. The sensor device comprises a processor that identifies one or more transient signals within the one or more signal waveforms, generates one or more transient characteristics based upon the identified transient signals, analyzes the transient characteristics to identify one or more electrical discharge indications, and generates one or more alert signals when one or more electrical discharge indications are identified.

The invention, in another aspect, features a system for detecting electrical discharges that precede electrical fires in electrical wiring. The system comprises one or more sensor devices coupled to a circuit, each sensor device configured to detect one or more signal waveforms generated by electrical activity on the circuit or on nearby branch circuits. The system comprises a server computing device communicably coupled to the one or more sensor devices. The server computing device receives the one or more signal waveforms from each sensor device. The server computing device analyzes the one or more signal waveforms to identify one or more electrical discharge indications. The server computing device generates one or more alert signals when one or more electrical discharge indications are identified.

The invention, in another aspect, features a computerized method of detecting electrical discharges that precede electrical fires in electrical wiring. One or more sensor devices each coupled to a circuit detect one or more signal waveforms generated by electrical activity on the circuit or on nearby branch circuits. A server computing device communicably coupled to the one or more sensor devices receives the one or more signal waveforms from each sensor device. The server computing device analyzes the one or more signal waveforms to identify one or more electrical discharge indications. The server computing device generates one or more alert signals when one or more electrical discharge indications are identified.

The invention, in another aspect, features a sensor device for detecting electrical discharges that precede electrical fires in electrical wiring. The sensor device comprises a module that detects one or more signal waveforms generated by electrical activity on the circuit or on nearby branch circuits. The sensor device comprises a processor that receives the one or more signal waveforms from each sensor device, analyzes the one or more signal waveforms to identify one or more electrical discharge indications, generates one or more alert signals when one or more electrical discharge indications are identified.

Any of the above aspects can include one or more of the following features. In some embodiments, the one or more signal waveforms comprise a full voltage cycle waveform. In some embodiments, the one or more sensor devices sample the full voltage cycle waveform at a frequency in a range between 10 MHz and 100 MHz.

In some embodiments, identifying one or more transient signals within the one or more signal waveforms comprises: a) dividing the samples of the full voltage cycle waveform into a plurality of bins; b) determining a mean value and a maximum value for each of the plurality of bins; c) determining a difference between the mean value and the maximum value; d) repeating steps a)-c) for each of a plurality of other samples of the full voltage cycle waveform to determine an accumulated maximum value for each bin across all of the samples; and e) determining a derivative of each accumulated maximum value across the plurality of bins. In some embodiments, generating one or more transient characteristics based upon the identified transient signals comprises determining an average transient amplitude over a voltage cycle of the full voltage cycle waveform, and determining an average transient amplitude for a plurality of phase sections within the voltage cycle.

In some embodiments, analyzing the transient characteristics to identify one or more electrical discharge indications comprises determining a ratio of average peak transients in one or more of the phase sections near a maximum voltage to average peak transients near a zero crossing of the voltage cycle, and identifying the average peak transients in one or more of the phase sections near a maximum voltage as electrical discharge indications, when the ratio is above a predetermined threshold. In some embodiments, generating one or more alert signals when one or more electrical discharge indications are identified comprises determining a count of the identified electrical discharge indications occurred within a predetermined amount of time, and generating one or more alert signals based upon the count of the identified electrical discharge indications.

In some embodiments, identifying one or more transient signals within the one or more signal waveforms comprises a) determining a derivative of the samples of the full voltage signal waveform across a full voltage cycle; b) dividing the samples of the full voltage cycle waveform into a plurality of bins; c) determining a maximum value for each of the plurality of bins; d) repeating steps a)-c) for each of a plurality of other samples of the full voltage cycle waveform to determine an accumulated maximum value for each bin across all of the samples; and e) determining a derivative of each accumulated maximum value across the plurality of bins. In some embodiments, generating one or more transient characteristics based upon the identified transient signals comprises determining an average transient amplitude over a voltage cycle of the full voltage cycle waveform, and determining an average transient amplitude for a plurality of phase sections within the voltage cycle.

In some embodiments, analyzing the transient characteristics to identify one or more electrical discharge indications comprises determining a ratio of average peak transients in one or more of the phase sections near a maximum voltage to average peak transients near a zero crossing of the voltage cycle, and identifying the average peak transients in one or more of the phase sections near a maximum voltage as electrical discharge indications, when the ratio is above a predetermined threshold. In some embodiments, generating one or more alert signals when one or more electrical discharge indications are identified comprises determining a count of the identified electrical discharge indications occurred within a predetermined amount of time, and generating one or more alert signals based upon the count of the identified electrical discharge indications.

In some embodiments, the one or more sensor devices sample the full voltage cycle waveform at 80 MHz upon detecting that the one or more signal waveforms have reached a threshold value. In some embodiments, identifying one or more transient signals within the one or more signal waveforms comprises identifying one or more samples of the full voltage cycle waveform that exceed a threshold value, and storing the identified one or more samples. In some embodiments, generating one or more transient characteristics based upon the identified transient signals comprises, for each identified sample: determining a count of peaks in the identified sample; determining a rise time of the peaks in the identified sample; determining a pulse width of the identified sample; and determining an integral of the identified sample. In some embodiments, analyzing the transient characteristics to identify one or more electrical discharge indications comprises categorizing the identified sample as an electrical discharge indication when the count of peaks in the identified sample is above a predetermined threshold and when the rise time of the peaks in the identified sample is above a predetermined threshold. In some embodiments, generating one or more alert signals when one or more electrical discharge indications are identified comprises determining a count of the identified electrical discharge indications occurred within a predetermined amount of time, and generating one or more alert signals based upon the count of the identified electrical discharge indications.

In some embodiments, the one or more sensor devices identify one or more transient signals within the one or more signal waveforms and generate one or more transient characteristics based upon the identified transient signals using a transient detection profile stored in a memory module of the sensor device. In some embodiments, the server computing device generates an updated transient detection profile based upon transient characteristics received from one or more of the sensor devices and transmits the updated transient detection profile to each of the one or more sensor devices. In some embodiments, the one or more sensor devices apply the updated transient detection profile to identify subsequent transient signals within the one or more signal waveforms and generate the one or more transient characteristics.

In some embodiments, the server computing device transmits the one or more alert signals to a remote computing device. In some embodiments, the server computing device transmits the one or more alert signals to at least one of the one or more sensor devices. In some embodiments, the at least one of the one or more sensor devices activates a visual indicator upon receiving at least one of the one or more alert signals. In some embodiments, the visual indicator is a light emitting diode (LED) component of the at least one of the one or more sensor devices. In some embodiments, the server computing device uses one or more machine learning algorithms to analyze the one or more signal waveforms to identify one or more electrical discharge indications.

The invention, in another aspect, features a computerized method of detecting hazardous electrical discharge activity patterns in electrical wiring. One or more sensor devices, coupled to a circuit, sense a multiple voltage cycle waveform generated by electrical activity on the circuit or on nearby branch circuits. A computing device coupled to the sensor devices detects a pattern of electrical discharge activity occurring in the multiple voltage cycle waveform based upon transient characteristics of the waveform in each of a plurality of cycles. The computing device recognizes the pattern of electrical discharge activity as a hazard event. The computing device identifies one or more conditions related to the pattern of electrical discharge activity. The computing device generates one or more alert messages based upon the pattern of electrical discharge activity and the identified conditions.

The invention, in another aspect, features a system for detecting hazardous electrical discharge activity patterns in electrical wiring. The system includes one or more sensor devices coupled to a circuit, and a computing device coupled to the sensor devices. The sensor devices sense a multiple voltage cycle waveform generated by electrical activity on the circuit or on nearby branch circuits. The computing device detects a pattern of electrical discharge activity occurring in the multiple voltage cycle waveform based upon transient characteristics of the waveform in each of a plurality of cycles. The computing device recognizes the pattern of electrical discharge activity as a hazard event. The computing device identifies one or more conditions related to the pattern of electrical discharge activity. The computing device generates one or more alert messages based upon the pattern of electrical discharge activity and the identified conditions.

Any of the above aspects can include one or more of the following features. In some embodiments, detecting the pattern of electrical discharge activity occurring in the multiple voltage cycle waveform comprises detecting an instance of electrical discharge activity in each of a plurality of cycles of the multiple voltage cycle waveform; comparing the detected electrical discharge activity instances using characteristics of each electrical discharge activity instance to determine a match; and grouping the matching electrical discharge activity instances into a patterns of electrical discharge activity. In some embodiments, the transient characteristics comprise one or more of: a ratio of (i) average peak transients in one or more phase sections of the waveform cycle near a maximum voltage to (ii) average peak transients near a zero crossing of the waveform cycle, and an average of peak transients in one or more of the phase sections near a maximum voltage when the ratio is above a predetermined threshold. In some embodiments, the computing device determines a cause of the pattern of electrical discharge activity using the identified conditions.

In some embodiments, the conditions related to the pattern of electrical discharge activity comprise one or more of: atmospheric conditions at a location of the sensor devices, temporal conditions, electrical activity conditions associated with an electrical device coupled to the circuit, or power quality conditions associated with a power distribution system to which the sensor devices are coupled. In some embodiments, the atmospheric conditions comprise one or more of precipitation, wind activity, solar activity, or outdoor temperature. In some embodiments, the temporal conditions comprise a discrete time of day or a continuous period of time. In some embodiments, the power quality conditions are one or more of: a power surge or a power sag. In some embodiments, the power quality conditions are identified on a power distribution system inside a building where the sensor devices and the circuit are located. In some embodiments, the power quality conditions are identified on a power distribution system that provides power to a building where the sensor devices and the circuit are located. In some embodiments, the electrical activity conditions comprise one or more of: the electrical device turning on or the electrical device turning off.

In some embodiments, the computing device transmits the generated alert messages to one or more remote computing devices. In some embodiments, one or more of the sensor devices receives at least one of the alert messages and activates an alert indication device embedded in the sensor device upon receiving the alert message. In some embodiments, the alert indication device comprises a light emitting diode (LED).

The invention, in another aspect, features a computerized method of detecting hazardous electrical discharge activity patterns in electrical wiring. One or more sensor devices, coupled to a circuit, sense a multiple voltage cycle waveform generated by electrical activity on the circuit or on nearby branch circuits. A computing device, coupled to the sensor devices, detects a pattern of electrical discharge activity occurring in the multiple voltage cycle waveform based upon transient characteristics of the waveform in each of a plurality of cycles. The computing device classifies the detected pattern of electrical discharge activity as a hazard event based upon a similarity between the detected pattern of electrical discharge activity and one or more known patterns of hazardous electrical discharge activity. The computing device generates one or more alert messages based upon the classified pattern of electrical discharge activity.

The invention, in another aspect, features a system for detecting hazardous electrical discharge activity patterns in electrical wiring. The system includes one or more sensor devices coupled to a circuit and a computing device coupled to the sensor devices. The sensor devices sense a multiple voltage cycle waveform generated by electrical activity on the circuit or on nearby branch circuits. The computing device detects a pattern of electrical discharge activity occurring in the multiple voltage cycle waveform based upon transient characteristics of the waveform in each of a plurality of cycles. The computing device classifies the detected pattern of electrical discharge activity as a hazard event based upon a similarity of the detected pattern of electrical discharge activity to one or more known patterns of hazardous electrical discharge activity. The computing device generates one or more alert messages based upon the classified pattern of electrical discharge activity.

Any of the above aspects can include one or more of the following features. In some embodiments, the one or more known patterns of hazardous electrical discharge activity include a pattern of circuit breaker arcing within an electric panel, a pattern of electric device arcing, and a pattern of power supply arcing. In some embodiments, the one or more known patterns of hazardous electrical discharge activity are stored as two-dimensional images in a database communicatively coupled to the computing device. In some embodiments, the computing device generates a two-dimensional image corresponding to the detected pattern of electrical discharge activity occurring in the multiple voltage cycle waveform. In some embodiments, classifying the detected pattern of electrical discharge activity as a hazard event comprises comparing one or more characteristics of the two-dimensional image of the detected pattern of electrical discharge activity to one or more characteristics of the two-dimensional images of the known patterns of hazardous electrical discharge activity to determine the similarity. In some embodiments, classifying the detected pattern of electrical discharge activity as a hazard event comprises executing a machine learning image classification model using the two-dimensional image of the detected pattern of electrical discharge activity as input to generate the similarity to one or more of the two-dimensional images of the known patterns of hazardous electrical discharge activity. In some embodiments, the machine learning image classification model is based upon a convolutional neural network.

In some embodiments, the computing device transmits the generated alert messages to one or more remote computing devices. In some embodiments, one or more of the sensor devices receives at least one of the alert messages and activates an alert indication device embedded in the sensor device upon receiving the alert message. In some embodiments, the alert indication device comprises a light emitting diode (LED). In some embodiments, the computing device identifies one or more conditions related to the detected pattern of electrical discharge activity. In some embodiments, the computing device generates the one or more alert messages based upon the classified pattern of electrical discharge activity and the identified conditions.

The invention, in another aspect, features a computerized method of detecting hazardous electrical discharge activity patterns in electrical wiring. One or more sensor devices coupled to a circuit sense a multiple voltage cycle waveform generated by electrical activity on the circuit or on nearby branch circuits. A computing device detects a pattern of electrical discharge activity occurring in the multiple voltage cycle waveform based upon transient characteristics of the waveform in each of a plurality of cycles. The computing device transmits data corresponding to the pattern of electrical discharge activity to a remote computing device. The remote computing device identifies an occurrence of a hazard event based upon the data corresponding to the pattern of electrical discharge activity.

The invention, in another aspect, features a system for detecting hazardous electrical discharge activity patterns in electrical wiring. The system includes one or more sensor devices coupled to a circuit, a computing device coupled to the one or more sensor devices, and a remote computing device coupled to the computing device. The one or more sensor devices sense a multiple voltage cycle waveform generated by electrical activity on the circuit or on nearby branch circuits. The computing device detects a pattern of electrical discharge activity occurring in the multiple voltage cycle waveform based upon transient characteristics of the waveform in each of a plurality of cycles. The computing device transmits data corresponding to the pattern of electrical discharge activity to the remote computing device. The remote computing device identifies an occurrence of a hazard event based upon the data corresponding to the pattern of electrical discharge activity.

Any of the above aspects can include one or more of the following features. In some embodiments, detecting the pattern of electrical discharge activity occurring in the multiple voltage cycle waveform comprises detecting an instance of electrical discharge activity in each of a plurality of cycles of the multiple voltage cycle waveform, comparing the detected electrical discharge activity instances using characteristics of each electrical discharge activity instance to determine a match, and grouping the matching electrical discharge activity instances into a pattern of electrical discharge activity. In some embodiments, the transient characteristics comprise one or more of: a ratio of (i) average peak transients in one or more phase sections of the waveform cycle near a maximum voltage to (ii) average peak transients near a zero crossing of the waveform cycle, and an average of peak transients in one or more of the phase sections near a maximum voltage when the ratio is above a predetermined threshold.

In some embodiments, the remote computing device determines a cause of the hazard event based upon the data corresponding to the pattern of electrical discharge activity. In some embodiments, determining a cause of the hazard event comprises identifying one or more potential locations of the hazard event in a building electrical system that includes the circuit.

In some embodiments, the remote computing device determines one or more conditions related to the pattern of electrical discharge activity. In some embodiments, the conditions related to the pattern of electrical discharge activity comprise one or more of: atmospheric conditions at a location of the sensor devices, temporal conditions, electrical activity conditions associated with an electrical device coupled to the circuit, or power quality conditions associated with a power distribution system to which the sensor devices are coupled.

In some embodiments, the remote computing device transmits one or more alert messages to a mitigation service computing system upon identifying an occurrence of a hazard event. In some embodiments, one or more of the sensor devices receives at least one of the alert messages and activates an alert indication device embedded in the sensor device upon receiving the alert messages. In some embodiments, a mobile computing device receives at least one of the alert messages and displays the received alert messages to a user of the mobile computing device. In some embodiments, the remote computing device communicates with the mitigation service computing system to troubleshoot the hazard event. In some embodiments, the remote computing device executes a decision tree algorithm to troubleshoot the hazard event as part of the communication with the mitigation service computing system. In some embodiments, the computing device correlates one or more conditions with the pattern of electrical discharge activity and transmits the one or more conditions to the remote computing device as part of the data corresponding to the pattern of electrical discharge activity.

The invention, in another aspect, features a computerized method of detecting hazardous electrical discharge activity in electrical wiring. One or more sensor devices coupled to a circuit sense a multiple voltage cycle waveform generated by electrical activity on the circuit or on nearby branch circuits. A computing device coupled to the one or more sensor devices applies plurality of specialized hazard detection models to the waveform data, each specialized hazard detection model generating a probability score for a distinct category of hazardous electrical activity. The computing device generates a composite threat score for each of the one or more sensor devices based upon the probability scores. The computing device issues one or more alert signals when the composite threat score for a sensor device meets or exceeds a configurable threshold.

As used herein, the term “threat” refers to any condition or pattern of activity indicating an elevated likelihood of harm or hazardous outcomes at a monitored location, including but not limited to electrical fire hazards arising from electrical discharge activity. It should be appreciated that the term is intended to be non-limiting as further described herein.

The invention, in another aspect, features a system for detecting hazardous electrical discharge activity in electrical wiring. One or more sensor devices coupled to a circuit sense a multiple voltage cycle waveform generated by electrical activity on the circuit or on nearby branch circuits. A computing device coupled to the one or more sensor devices applies plurality of specialized hazard detection models to the waveform data, each specialized hazard detection model generating a probability score for a distinct category of hazardous electrical activity. The computing device generates a composite threat score for each of the one or more sensor devices based upon the probability scores. The computing device issues one or more alert signals when the composite threat score for a sensor device meets or exceeds a configurable threshold.

Any of the above aspects can include one or more of the following features. In some embodiments, applying the plurality of specialized hazard detection models comprises applying each model to a structured summary of the waveform data collected over a preceding time window. In some embodiments, the structured summary comprises, for each voltage cycle captured during the time window, one or more of: amplitude characteristics of candidate transient events; a root mean square voltage; and a count of candidate transient events.

In some embodiments, the plurality of specialized hazard detection models comprises a glowing connection detection model, and wherein applying the glowing connection detection model comprises identifying segments of the waveform data matching known glowing connection waveform characteristics; determining abrupt voltage changes that are consistent with a glowing connection in the identified segments; and classifying the identified segments to generate a glowing connection probability score.

In some embodiments, the plurality of specialized hazard detection models comprises a coincident voltage dip and arcing detection model, and wherein applying the coincident voltage dip and arcing detection model comprises detecting and refining candidate voltage dip events in the waveform data; determining whether each refined candidate voltage dip event is temporally coincident with elevated arcing activity within a predetermined window; extracting a feature vector characterizing both the voltage dip and the coincident arcing activity; and classifying the feature vector and the coincidence determination to generate a coincident voltage dip and arcing probability score. In some embodiments, confirmed candidate events are filtered by removing events whose timing coincides with one or more of: a known utility grid disturbance and a nearby weather event.

In some embodiments, generating the composite threat score comprises applying a machine learning model to a feature set derived from one or more of: current detection model outputs; hazard signal history data for the sensor device; voltage activity data for the sensor device; and time-of-day pattern data for the sensor device. In some embodiments, a rate of change of composite threat scores generated across successive analysis windows is quantified, where the configurable threshold has greater sensitivity for a sensor device exhibiting a rapidly increasing rate of change.

In some embodiments, one or more predefined weighting rules are applied to the hazard detection model scores. Where detection of hazard events by two or more specialized hazard detection models occurs within a same analysis window, the weighting rules result in an automatic elevation of the composite electrical fire threat score. In some embodiments, a hazard event is automatically promoted to a heightened escalation status, bypassing the configurable electrical fire threat score threshold, when a score generated by one or more of the specialized hazard detection models meets or exceeds a predetermined threshold

In some embodiments, each hazard event with sufficiently high hazard detection model score is annotated with structured metadata comprising the model score, associated characterization features and electrical fire hazard type. In some embodiments, one or more categorical tags are assigned to each hazard event with sufficiently high hazard detection model score, wherein the categorical tags characterize one or more of the electrical fire hazard type, severity, confidence level, and recommended escalation action

Other aspects and advantages of the invention will become apparent from the following detailed description, taken in conjunction with the accompanying drawings, illustrating the principles of the invention by way of example only.

### BRIEF DESCRIPTION OF THE DRAWINGS

The advantages of the technology described above, together with further advantages, may be better understood by referring to the following description taken in conjunction with the accompanying drawings. The drawings are not necessarily to scale, emphasis instead generally being placed upon illustrating the principles of the technology.

FIG. 1A is a diagram of a parallel arc fault.

FIG. 1B is a diagram of a series arc fault.

FIG. 1C is a diagram of a glowing connection.

FIG. 2 is a block diagram of a system for detecting electrical discharges that precede electrical fires in electrical wiring.

FIG. 3 is a diagram of an exemplary electrical transmission network.

FIG. 4A is a diagram of field-collected measurements of an exemplary communication channel for indoor, residential power-line networks.

FIG. 4B is a diagram of transfer characteristics for three different circuits and a comparison 20 m long cable measured in a lab setting.

FIG. 5 is a flow diagram of a computerized method of detecting electrical discharges that precede electrical fires in electrical wiring.

FIG. 6A is a detailed flow diagram of a computerized method of detecting electrical discharges that precede electrical fires in electrical wiring.

FIG. 6B is a detailed flow diagram of a computerized method of detecting electrical discharges that precede electrical fires in electrical wiring.

FIG. 6C is a detailed flow diagram of a computerized method of detecting electrical discharges that precede electrical fires in electrical wiring.

FIGS. 7A-7C are diagrams of exemplary waveform data generated by the sensor device that depict transients indicative of electrical discharge activity.

FIGS. 8A-8C are diagrams of exemplary waveform data generated by the sensor device for identifying transient characteristics.

FIG. 9 is a diagram of a transient amplitude ratio over time.

FIG. 10 is a diagram of a likelihood of electrical discharge activity occurring over time.

FIG. 11 is a diagram of an exemplary user interface of a remote computing device for displaying an alert signal notification.

FIG. 12 is a diagram of exemplary waveform data for safety signals generated by a testing device.

FIG. 13 is a block diagram of a proxy device that can be used in conjunction with the system of FIG. 2.

FIGS. 14A-14E are diagrams showing fire precursor arcing signals collected by a sensor device installed in a test home.

FIG. 15 is a diagram showing more detail of the arcing signals of FIG. 14C.

FIG. 16 is a diagram showing more detail of an individual pulse from an electrical discharge.

FIG. 17 is a diagram with a number of graphs showing system test results.

FIG. 18 is a histogram showing amplitude of pulses from laboratory data compared with amplitude of pulses re-created by a proxy device.

FIG. 19 is a plot showing how fire precursor signals appear over time.

FIG. 20 is a plot for a device running on the electrical network that is generating HF electrical activity.

FIG. 21 is a diagram of graphs of root mean square (RMS) Voltage changes over time associated with an appliance turning on and off.

FIG. 22 is an exemplary visualization for an electrical discharge activity pattern, where the pattern is generated from the voltage changes of FIG. 21 as detected by system 200.

FIG. 23 is another exemplary visualization for an electrical discharge activity pattern generated by system, including an unfiltered view and a filtered view.

FIG. 24A is another exemplary visualization for an electrical discharge activity pattern, where the pattern is generated due to arcing at an electrical panel bus bar in a particular home and the pattern occurs at two different time periods.

FIG. 24B is another exemplary visualization for an electrical discharge activity pattern, where the pattern is generated due to arcing at an electrical panel bus bar in a different home than in FIG. 24A.

FIG. 25 is an exemplary heat map of electrical discharge activity patterns occurring over time, using the electrical discharge activity pattern of FIG. 22.

FIG. 26 is another exemplary heat map of electrical discharge activity patterns occurring over time, using the electrical discharge activity pattern of FIG. 24A.

FIG. 27 is a flow diagram of a computerized method of detecting electrical discharges that occur in electrical wiring across multiple cycles of a voltage waveform.

FIG. 28 is a diagram of an exemplary use case timeline for detecting electrical discharge patterns that occur in electrical wiring across multiple cycles of a voltage waveform and identifying related conditions.

FIG. 29 is a flow diagram of a computerized method of detecting electrical discharges that occur in electrical wiring across multiple cycles of a voltage waveform based upon known hazardous electrical discharges.

FIGS. 30A-30D comprise a diagram of an exemplary decision tree algorithm for troubleshooting a narrow parallel discharge as detected by the system.

FIG. 31 is a diagram of an exemplary user interface for alerting a customer of a detected fire hazard.

FIG. 32 is a diagram of an exemplary decision tree algorithm for troubleshooting a hazard using a detected electrical activity pattern that matches a known hazardous electrical discharge pattern.

FIG. 33 is a block diagram of an artificial intelligence-based threat assessment subsystem for identifying and prioritizing severe fire risks by aggregating outputs from a plurality of specialized hazard detection models.

FIG. 34 is a block diagram illustrating the algorithmic processing performed by the glowing connection detection model.

FIG. 35 is a block diagram illustrating the algorithmic processing performed by the coincident voltage dip and arcing (CVDA) detection model.

### DETAILED DESCRIPTION

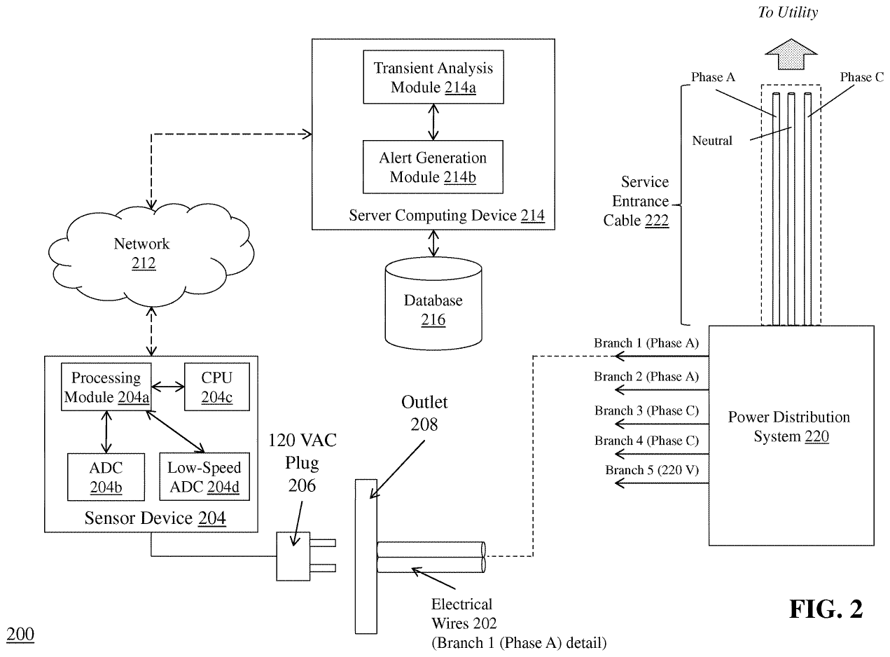

FIG. 2 is a block diagram of a system 200 for detecting electrical discharges that precede electrical fires in electrical wiring. The system 200 includes electrical wires 202 that comprise a circuit in a power distribution system 220 (e.g., an electrical system in a residential or commercial building) that transfers power received from a service entrance cable 222 to branch circuits (such as the wires 202) which feed the power to appliances and outlets (e.g., outlet 208) in the building. Electrical discharges create a very fast impulse of current that travel throughout the electrical power distribution system via transmission line effects. The high frequency signal created by the electrical discharge travels through the home much like the high frequency signals use in power line communications.

Generally, the wires that provide power to circuits, outlets, devices, and appliances in buildings are the medium over which fire precursor signals travel from origin to sensor. Precursors are impulsive discharges and result in electromagnetic signals that travel along the power distribution wires in a building. Every location in the wiring (both fixed house wiring and mobile cords to devices and appliances) has a transfer function to every outlet in the house, and the precursor signals arrive at the sensor modified by this transfer function. The methods and systems described herein leverage methods similar to those developed in power line carrier communication techniques to measure and identify very broad frequency content which travels through a home's electrical network.

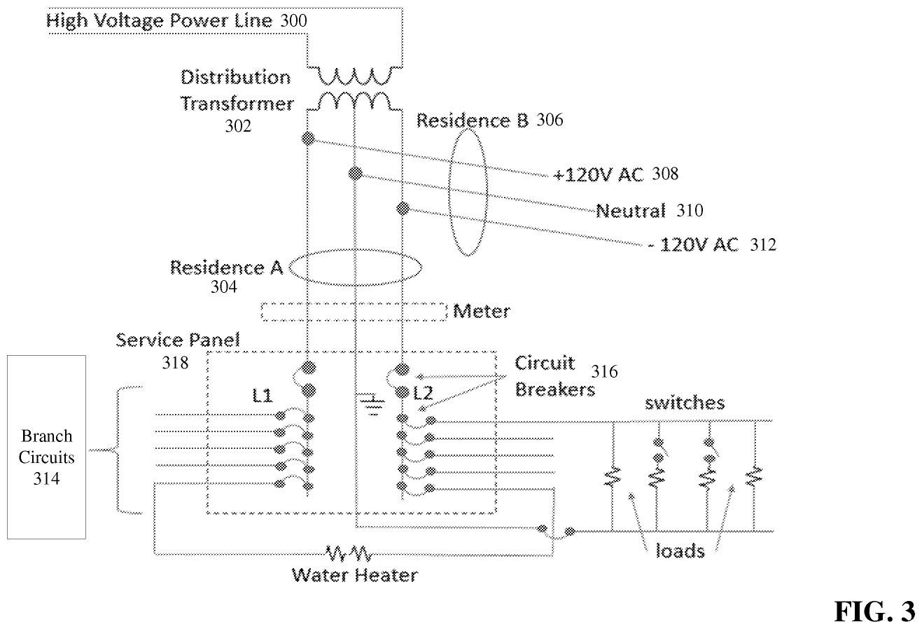

FIG. 3 is a diagram of an exemplary electrical network servicing one or more residences. As shown in FIG. 3, electricity from a high voltage power line 300 passes through an electrical transformer 302 and is delivered to one or more residences (e.g., Residence A 304, Residence B 306) through a +120V AC line (L1) 308, a neutral line 310, and a −120V AC line (L2) 312. The lines L1 and L2 are coupled to a plurality of branch circuits 314 via circuit breakers 316 in a service panel 318 inside the residence. It should be appreciated that communication is possible from any circuit on L1 to any circuit on L2.

Communicating using power lines has been considered and used since the turn of the 20th century. In the last twenty years, various companies have released products that provide 100 Mbps to 1 Gbps local area network communication over in-building electrical distribution systems. This work resulted in the standardization of power line communication in IEEE 1901 and the widespread availability of “ethernet over powerline” adapters for consumer use, and broadband communication over in-building power lines is a mature technology.

There are two major issues associated with communicating over power lines (i.e., the channel): the transmission and attenuation characteristics of a transmitter and receiver on different circuits of the building and the channel noise environment. The powerline channel is challenging because there are many discontinuities due to branches (e.g., each outlet on a circuit) as well as loads with frequency and time dependent impedances (e.g., due to different device power draw, construction, and on vs. off characteristics). The devices that are responsible for the time variance are also responsible for both narrow and broad band noise injection due to switching power supplies and other non-linear equipment elements. Exemplary techniques relating to currently available powerline communication is described in C. Cano, A. Pittolo, D. Malone, L. Lampe, A. M. Tonello, A. G. Dabak, “State of the art in power line communications: From the applications to the medium,” IEEE J. Sel. Areas Commun., vol. 34, pp. 1935-1952 July 2016 (available at https://arxiv.org/pdf/1602.09019.pdf), which is incorporated herein by reference.

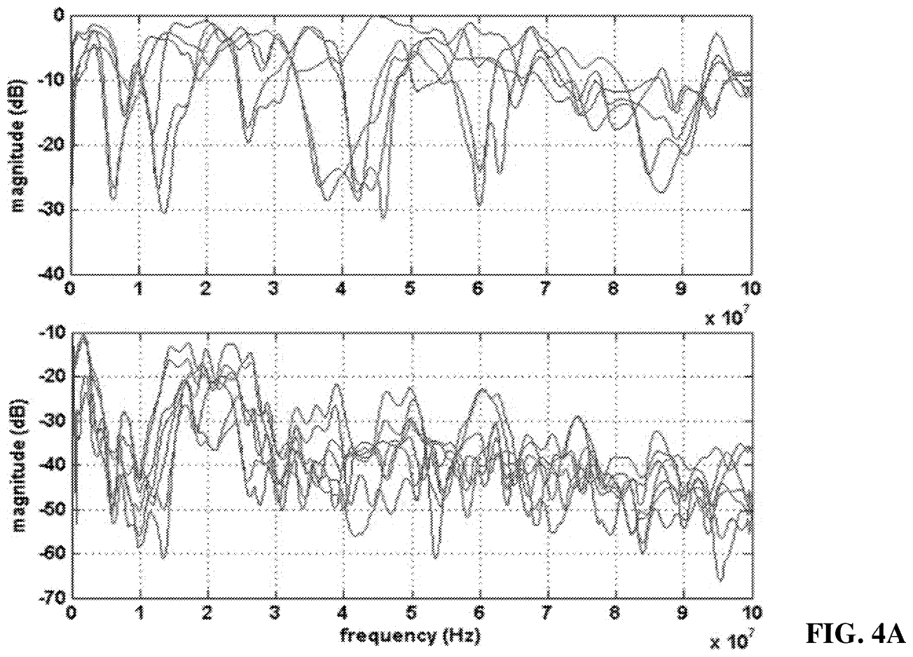

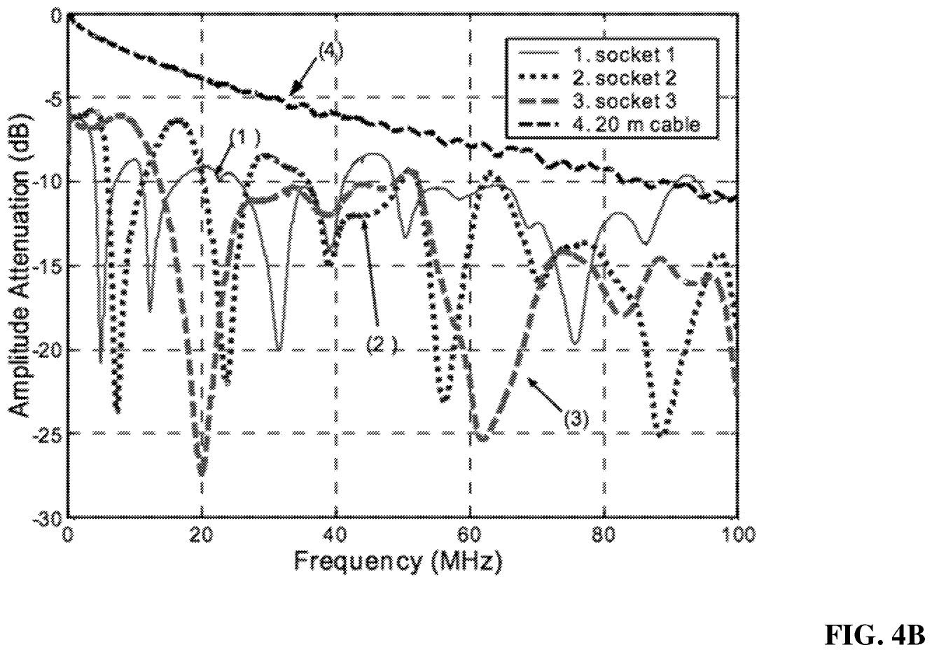

Power line channel transmission characteristics have been the subject of significant field measurement and modeling activities that culminated in the IEEE 1901 standard ratification in 2010 (as described in “IEEE Standard for Broadband Over Power Line Networks: Medium Access Control and Physical Layer Specifications, IEEE Standard 1901-2010,” September 2010. FIG. 4A shows field-collected measurements of an exemplary communication channel for indoor, residential power-line networks. The top chart in FIG. 4A represents multiple pairs of transmitters and receivers on the same circuit, and the bottom chart in FIG. 4A shows multiple transmitter and receiver pairs where the units are on different circuits (described in M. Tlich, A. Zeddam, F. Moulin, F. Gauthier, “Indoor power-line communications channel characterization up to 100 MHz—Part I: One-parameter deterministic model,” IEEE Trans. Power Del., vol. 23, no. 3, pp. 1392-141 July 2008). Measurement results taken in Spain show similar characteristics confirming that changes in mains configuration and wiring style result in similar overall characteristics (see C. Cano, et al., supra). The more interesting and difficult case is the chart in FIG. 4B which shows the transfer characteristics for three different circuits and a comparison 20 m long cable measured in a lab setting (described in E. Liu, Y. Gao, O. Bilal, and T. Korhonen, “Broadband characterization of indoor powerline channel,” Proc. Int. Symp. Power Line Commun., Zaragoza, Spain, 31 Mar.-2 Apr. 2004).

The charts of FIGS. 4A and 4B show variable frequency dependence for a particular channel but relatively flat attenuation on average. The sites used for gathering these data were varied in size from apartments to large homes and in age of construction. The channel characteristics are similar in many ways to stationary wireless communication channels. Wireless channels experience fading (i.e., frequency, position, and time dependent attenuation) due reflections of signals off objects in the environment (i.e., multipath induced fading). The same effect is at play here because discontinuities, mismatched impedances, and branches in the wiring result in signal reflections. In the time domain, these reflections manifest themselves as amplitude and time shifted copies of the original signal arriving at the receiver. In the frequency domain, the frequency components of these copies either constructively or destructively interfere causing peaks and notches in the transfer characteristic as observed in the charts.

Power line communication systems use the same techniques for signal encoding and noise resilience that are employed in broadband, wireless local area networks (e.g., IEEE 802.11n), chiefly orthogonal frequency division multiplexing (OFDM). OFDM is a good solution because it is a technique for spreading information across a wide band of the spectrum while also reducing the impact of signal dispersion and fading.

The power line environment is challenging for communication, but market success of Ethernet over power line products demonstrate that it is possible for broadband signals to traverse the complicated electrical network. Narrow band communication is very challenging due to extreme frequency selectivity that is dependent on individual, time varying channel conditions. Circuit to circuit signal attenuations are significant but are typically less than 50 dB making it possible for signals sourced almost anywhere in the electrical wiring to be detected at a receiver elsewhere in the house wiring (i.e., at an electrical socket).

Turning back to FIG. 2, the system 200 further includes a sensor device 204 coupled via a 120 VAC plug 206 to an electrical outlet 208 of the branch circuit wires 202. The sensor device comprises electronic components (e.g., processing module 204a, high-speed ADC 204b, CPU 204c, low-speed ADC 204d) which couple the sensor device to the electrical infrastructure in a way that allows the electrical discharge signals to be amplified while in some embodiments, also filtering out unwanted 60 Hz signal and electrical noise generated by appliances running on the electrical system. The processing module 204a includes components such as capacitors, resistors, and amplifiers that sense electrical activity occurring on the electrical wires 202 of the branch circuit and capture the sensed electricity as waveform data. In some embodiments, the processing module 204a includes a filter that can limit a frequency response of the sensor device to a range in which electrical discharges have a high signal-to-noise ratio. The filtering can be implemented using hardware components or in firmware installed on the processing module 204a. It should be noted that the electrical activity occurring on electrical wires 202 of the branch circuit includes signals transmitted to and from the power distribution system 220. In this way, a single sensor is capable of seeing electrical discharge signals throughout the full electrical distribution system 220, including the other branch circuits. Although FIG. 2 depicts a single sensor device 204, it should be appreciated that the system 200 can comprise two or more sensor devices positioned to sense electrical activity in a power distribution system. Multiple sensors sending data to a server computing device can provide increased sensitivity and work together to provide information on the location of where electrical discharges are occurring.

In some embodiments, the sensor device 204 comprises two parallel voltage sampling paths operating at different sampling rates and serving complementary functions. The first sampling path comprises the high-speed ADC 204b, which samples the voltage waveform at up to 27 million samples per second for the purpose of detecting high-frequency transient signals indicative of electrical discharge activity, as described herein. The second sampling path comprises the low-speed ADC 204d, which applies a low-pass filter to the voltage waveform and samples the filtered signal at approximately 30 kHz. The low-speed ADC 204d is configured to capture the fundamental 60 Hz voltage waveform with sufficient fidelity to compute root mean square (RMS) voltage values for each voltage cycle, providing a continuous, low-bandwidth record of the voltage environment at the location of the sensor device 204. As shown in FIG. 2, both the high-speed ADC 204b and the low-speed ADC 204d are coupled to the CPU 204c of the sensor device 204, which processes the outputs of both sampling paths and transmits the resulting data (including the transient summary data derived from the high-speed ADC 204b and the RMS voltage values derived from the low-speed ADC 204d) to the server computing device 214 via the network 212, where the data is incorporated into the hourly summary data as described herein.

In some embodiments, location can be determined using time-of-arrival techniques, where the time difference of arrival of a transient signal to each sensor device provides a relative distance to the location of the electrical discharges on the wire. Generally, the sensor device 204 is configured to see the shape of pulses. The pulse shapes the sensor device sees are the source pulse shape plus reflections of that shape from every branch, termination, or impedance change in the electrical system wiring. The time between reflections is the product of differences in distance divided by group velocity. The magnitude and polarity of reflections is determined by the complex impedance of the load or junction. The timing of various reflections tell the location of the source in the circuit; the shape changes of those reflections indicate the impedance of the loads and junctions that produced the reflections. For example, if two sensor devices are installed on the same circuit at different locations, time differences of arrival at the two devices can determine locations in the circuit-even for pulses whose reflections cannot be seen above the noise.

As mentioned above, in one embodiment, the sensor device 204 can capture up to 27 million waveform samples per second and allocate the samples into 512 bins. The sensor device 204 determines a maximum amplitude in each of the bins and generates waveform data using the binned values. The sensor device 204 also performs functions to obtain derivative values of the waveform signals, in order to reduce the bandwidth and processing requirements of the sensor hardware. For example, the sensor device 204 can discard adjacent waveform samples to get the first derivative, and then repeat the process to get the second derivative. In one embodiment, the sensor device 204 adds several adjacent samples and subtracts several adjacent samples to obtain a wavelet that is then analyzed against previously captured wavelets to determine whether any changes in the signal have occurred.

The sensor device 204 is communicably coupled to a server computing device 214 via a communication network 212. In one embodiment, the sensor device 204 is equipped with communication components (e.g., antenna, network interface circuitry) that enable the sensor device 204 to communicate with the server computing device 214 via a wireless connection.

The communication network 212 enables the other components of the system 200 to communicate with each other in order to perform the process of detecting electrical discharges in electrical wiring as described herein. The network 212 may be a local network, such as WiFi or a LAN, or a wide area network, such as the Internet and/or a cellular network. In some embodiments, the network 212 is comprised of several discrete networks and/or sub-networks (e.g., cellular to Internet) that enable the components of the system 200 to communicate with each other.

The server computing device 214 is a combination of hardware, including one or more special-purpose processors and one or more physical memory modules, and specialized software modules—such as transient analysis module 214a—that are executed by a processor of the server computing device 214, to receive data from other components of the system 200, transmit data to other components of the system 200, and perform functions for detecting electrical discharges in electrical wiring as described herein. In some embodiments, the module 214a is a specialized set of computer software instructions programmed onto a dedicated processor in the server computing device 214 and can include designated memory locations and/or registers for executing the specialized computer software instructions. Further explanation of the specific processing performed by the module 214a will be provided below. It should be appreciated that, in some embodiments, the sensor device 204 can be configured to operate as a standalone device, in that the processing described herein with respect to the server computing device 106 can be performed by the sensor device 204 (i.e., a processor and memory can be embedded in the sensor device that conducts the data collection, analysis, and alerting processes described herein).

The database 216 comprises transient and/or persistent memory for data storage that is used in conjunction with the process of detecting electrical discharges in electrical wiring as described herein. Generally, the database 216 is configured to receive, generate, and store specific segments of data for use by the server computing device 214. In some embodiments, all or a portion of the database 216 can be integrated within the server computing device 214, or be located on a separate computing device or devices. For example, the database 216 can comprise a database such as MySQL™ available from Oracle Corp. of Redwood City, California. In another example, the database 216 can comprise a cloud-based storage medium, such as Amazon Web Services (AWS)™, that uses DynamoDB™. In other embodiments, the database can be located in memory, e.g., on the server computing device 214 and/or sensor module 204.

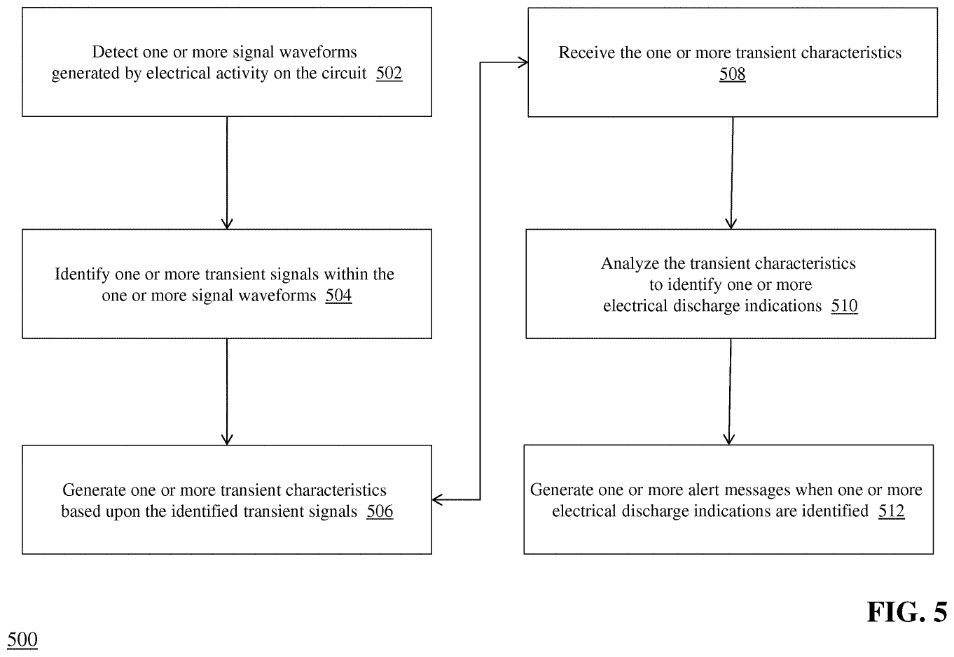

FIG. 5 is a flow diagram of a computerized method 500 of detecting early-stage arc faults in electrical wiring, using the system 200 of FIG. 2. One or more sensor devices (e.g., sensor device 204) coupled to a branch circuit (e.g., Branch 1 circuit comprising wires 202) detect (502) one or more signal waveforms generated by electrical activity on the branch circuit. For example, because an electrical discharge is an impulse change in current, the signal generated by the electrical discharge transmits down the electrical wires 202 reflecting around any junction. These signals have a delay in returning, which is typically based upon the length of the wire. The signals also exhibit a phase shift, which enables the system 200 to identify transient signals in the waveform which represent activity that relates to an electrical discharge (even a very small electrical discharge) on the electrical wires 202 as described herein.

The sensor device 204 identifies (504) one or more transient signals within the one or more signal waveforms that are detected. The sensor device 204 generates (506) transient characteristics based upon the identified transient signals and transmits the transient characteristics to server computing device 214. The transient analysis module 214a receives (508) the sets of transient characteristics from each sensor device 204 and analyzes (510) the transient characteristics to identify one or more electrical discharge indications. The alert generation module 214b generates (512) one or more alert signals when one or more electrical discharge indications are identified.

It should be appreciated that, in some embodiments, the sensor device 204 can detect the one or more signal waveforms (step 502) and transmit the one or more signal waveforms to the transient analysis module 214a for further processing, including identifying transient signals (step 504), generating transient characteristics (step 506), analyzing the transient characteristics (step 510), and generating alert signals (step 512). It should further be appreciated that, in some embodiments, the sensor device 204 can perform all of the steps of FIG. 5 internally. In some embodiments, the sensor device 204 compresses the one or more signal waveforms prior to transmitting the signal waveforms to the transient analysis module 214a—in order to conserve network bandwidth, improve processing capacity and performance, and the like.

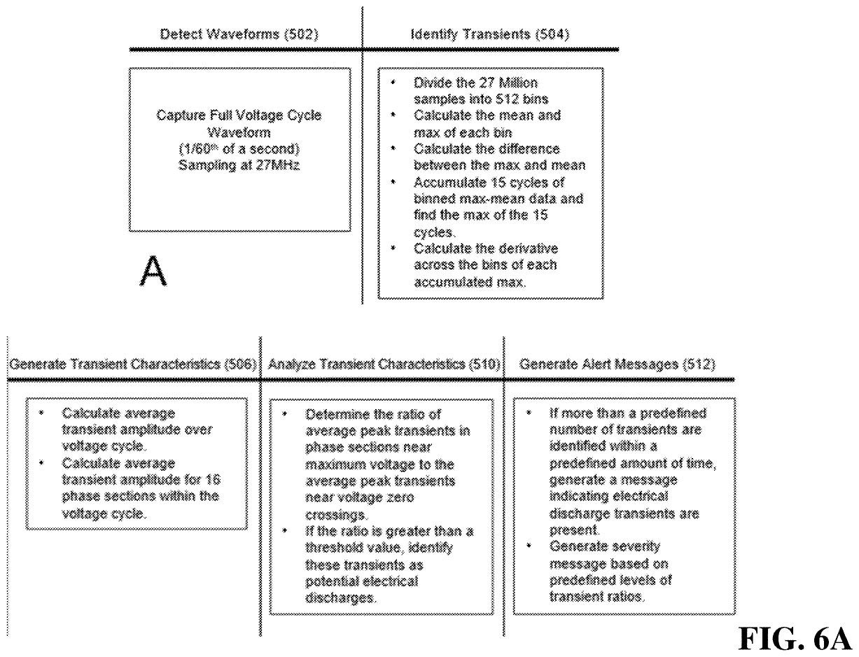

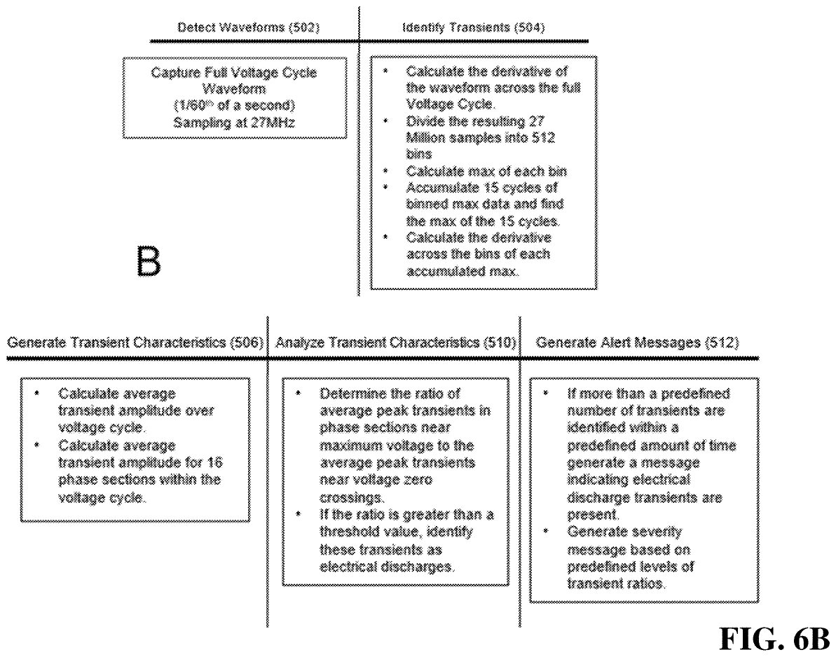

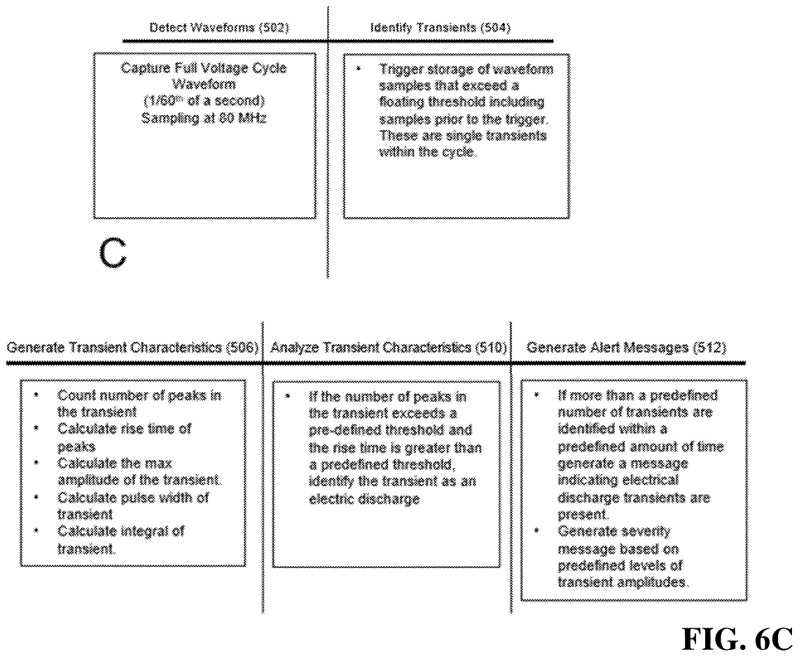

In some embodiments, the alert generation module 214b transmits the one or more alert signals to a remote computing device (e.g., a mobile phone, tablet, smart watch, and the like). The remote computing device can, e.g., display a message or indicator (such as a warning icon) on a screen associated with the remote computing device based upon receipt of the one or more alert signals. For example, the alert signal can comprise a packet-based message including a corpus of text that indicates a dangerous condition or hazard as detected by the system 200. In some embodiments, the alert generation module 214b transmits the one or more alert signals to one or more of the sensor devices 204. The sensor devices 204 can activate one or more components (e.g., embedded components in the sensor device) upon receipt of the one or more alert signals. For example, upon receiving an alert signal from the alert generation module 214b, the sensor device(s) 204 can activate an LED element that lights up and/or flashes on the exterior of the sensor device 204 to indicate that a dangerous condition or hazard has been detected by the system 200. Additional detail about the steps of FIG. 5 is provided below with respect to FIGS. 6A to 6C.

FIGS. 6A to 6C comprise a detailed flow diagram of computerized methods of detecting electrical discharges that precede electrical fires in electrical wiring, using the system 200 of FIG. 2 and according to the framework described above with respect to FIG. 5. FIGS. 6A to 6C include three different methods that may be used by the system 200 to detect electrical discharges-Method A (FIG. 6A), Method B (FIG. 6B), and Method C (FIG. 6C). It should be appreciated that these methods are exemplary, and other methods may be contemplated for use with the system described herein. Also, it should be appreciated that the Methods A, B, and C may be used independently or in conjunction with each other. In one embodiment, the sensor device 204 may include multiple logical and/or physical processors (e.g., CPU 204c) that each processes the waveform data according to one of the Methods A, B, or C.

For example, in Methods A and B, the high-speed analog-to-digital converter (ADC 204b) of sensor device 204 detects waveforms (502) by capturing a full voltage cycle waveform ( 1/60^{th} of a second), sampling at 27 MHz—while in Method C, the ADC 204b captures a full voltage cycle waveform ( 1/60^{th} of a second), sampling at 80 MHz upon detecting that the waveform has reached or exceeded a threshold (so as to conserve bandwidth and memory resources). In all methods, the low-speed ADC 204d operates continuously and in parallel with the high-speed ADC 204b, providing a separate, independent stream of RMS voltage measurements that is transmitted to the server computing device 214 together with the transient summary data generated from the high-speed sampling path.

The CPU 204c of sensor device 204 can identify transients (504) in the waveform data in several different ways. For example, in Method A, the CPU 204c performs a binning process on the sampled waveform data by dividing the 27 million samples into 512 bins. The CPU 204c calculates the difference between the maximum and the minimum of each bin and calculates the difference between the maximum and the mean of each bin. Next, the CPU 204c accumulates 15 cycles of binned maximum-mean data and determines the maximum of the 15 cycles. Then, the CPU 204c calculates the derivative across the bins of each accumulated maximum.

In Method B, the CPU 204c calculates the derivative of the waveform across the full voltage cycle. The CPU 204c divides the resulting 27 million samples into 512 bins and calculates the maximum of each bin. Next, the CPU 204c accumulates 15 cycles of binned maximum data and determines the maximum of the 15 cycles. Then, the CPU 204c calculates the derivative across the bins of each accumulated maximum.

In Method C, the CPU 204c triggers storage of waveform samples that exceed a floating threshold including samples prior to the trigger—these are single transients within the cycle.

Continuing with FIGS. 6A to 6C, the CPU 204c of sensor device 204 can generate transient characteristics (506) in different ways. For example, in Methods A and B, the CPU 204c calculates the average transient amplitude over the full voltage cycle and calculates the average transient amplitude for 16 phase sections within the voltage cycle. In Method C, the CPU 204c counts the number of peaks in the transient, calculates the rise time of the peaks, calculates the maximum amplitude of the transient, calculates the pulse width of the transient, and calculates the integral of the transient.

When the sensor device 204 determines that a change has occurred in the voltage waveform data based upon the binning process described above, the sensor device 204 transmits the transient characteristic data to the server computing device 214 via network 212. The transient analysis module 214a receives (504) the transient characteristic data from the sensor device 204 and analyzes (506) the waveform data to identify one or more electrical discharge indications in the signal waveform. In one example, the signal analysis module 214a reconstructs the signal waveform using the received data and compares the distribution of transients (including where the transients occur in phase) to an expected distribution of transients. For example, the signal analysis module 214a can determine where the transients occur in phase as well as how repeatable the transients are—e.g., do the transients exhibit a regular pattern in the waveform (which may indicate operation of a device or appliance on the circuit) or do the transients exhibit an irregular pattern (which may indicate electrical discharge and/or arc fault activity).

In some embodiments, the CPU 204c of sensor device 204 transmits the determined transient characteristics to the transient analysis module 214a of server computing device 214, and the module 214a receives the transient characteristics. It should be appreciated that, in some embodiments, the sensor device 204 can be configured as a standalone module that does not require a connection to a server computing device 214—in these embodiments, the sensor device 204 can also perform the steps of analyzing the transient characteristics (510) and generating alert signals (512), and further in some embodiments, the step of transmitting alert signals to a remote computing device (as described previously). In some embodiments, the alert signals can be generated locally within the sensor device 204 and used to trigger other components of the sensor device 204—such as a speaker or other audio component embedded in the sensor device 204, or a light or other visual component (e.g., LED) embedded in the sensor device 204—to alert nearby persons that potentially dangerous electrical activity is occurring.

The transient analysis module 214a can analyze the transient characteristics (510) received from the sensor device 204 in different ways. For example, in Methods A and B, the module 214a determines the ratio of average peak transients in phase sections near maximum voltage to the average peak transients near voltage zero crossings. If the ratio is greater than a threshold value, the module 214a identifies these transients as potential electrical discharges. In Method C, the module 214a evaluates whether the number of peaks in the transient exceeds a predefined threshold and whether the rise time is greater than a predefined threshold. If so, the module 214a identifies the transient as a potential electrical discharge.

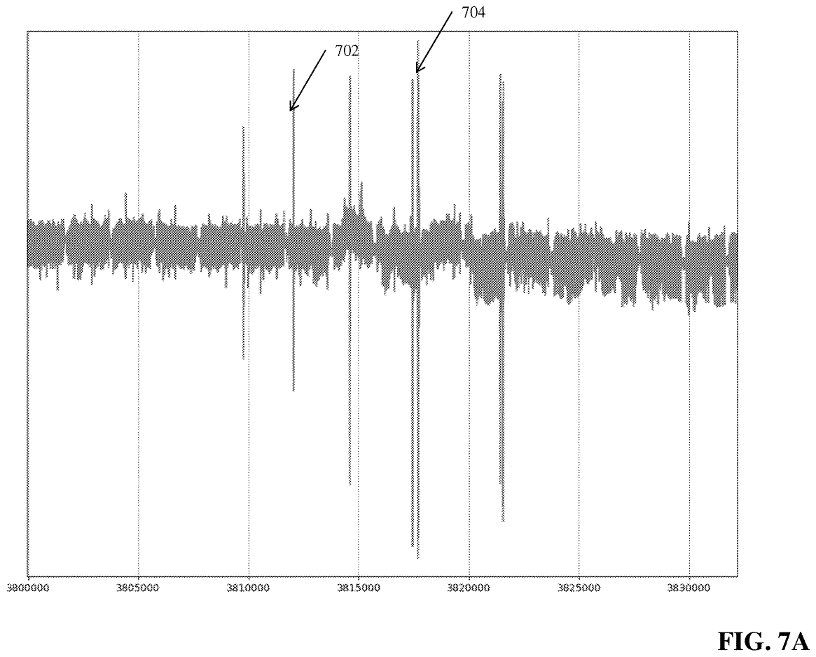

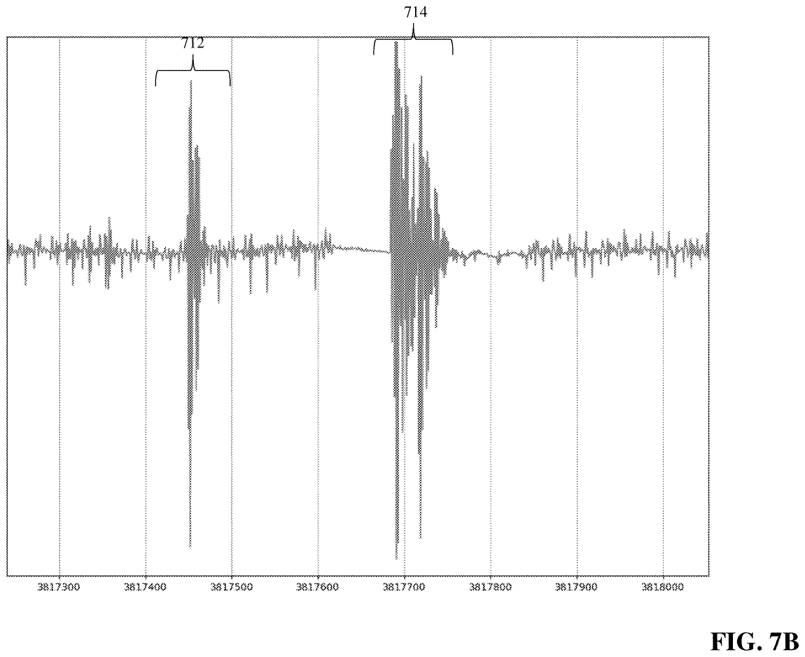

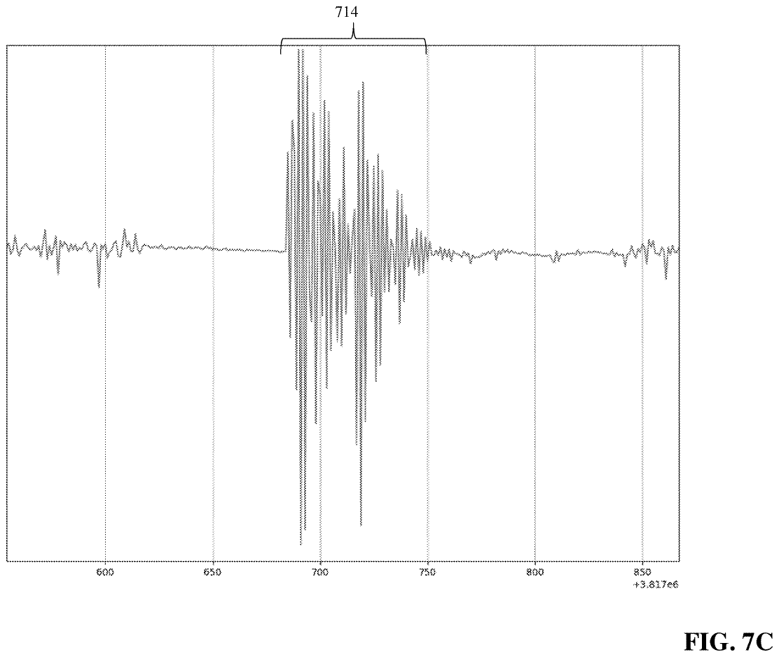

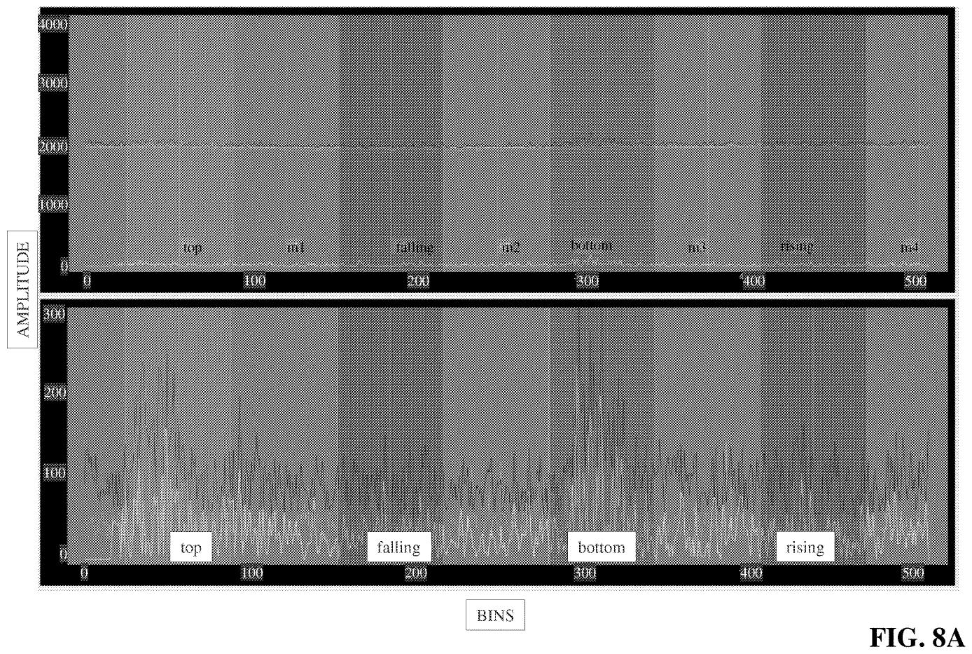

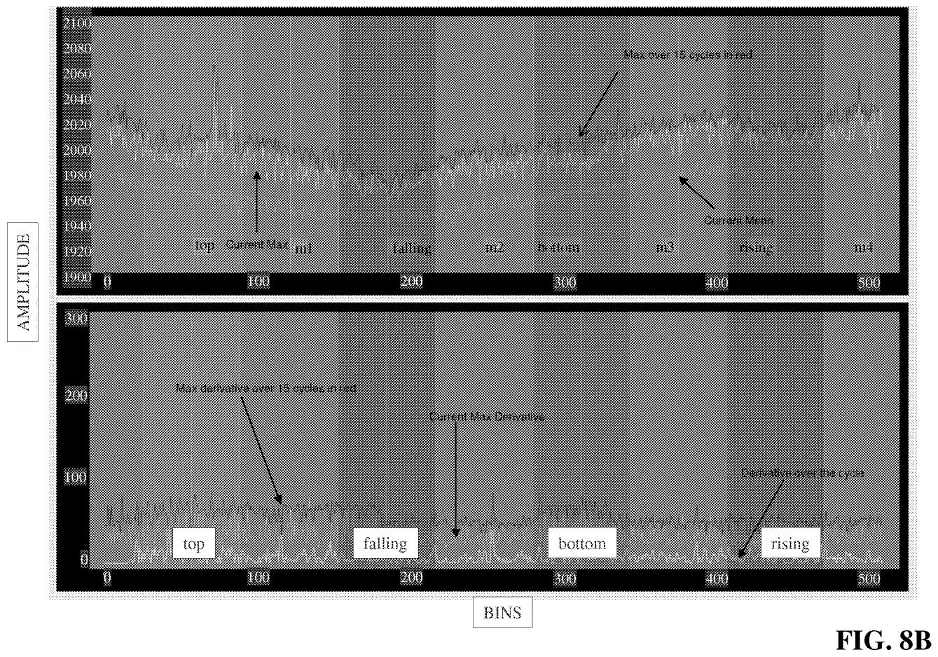

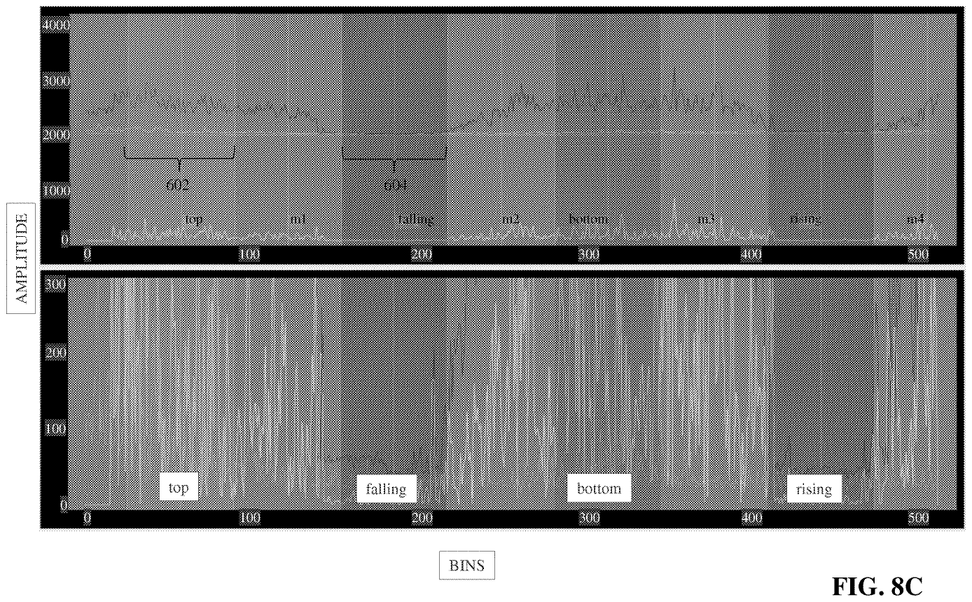

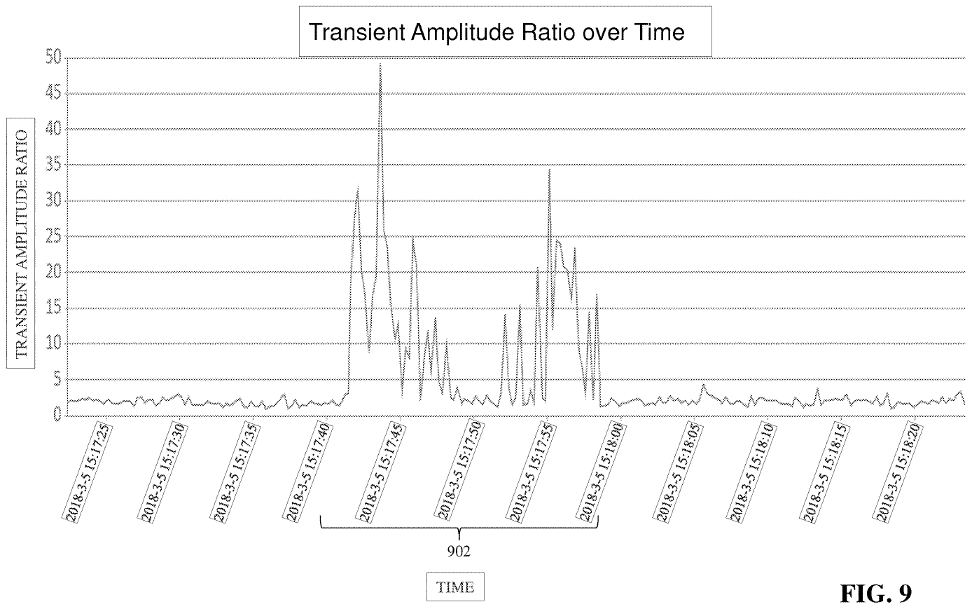

FIGS. 7A-7C and 8A-8C are diagrams of waveform data captured by CPU 204c of the sensor device 204 that depict transient signals. FIG. 7A is an exemplary diagram of a waveform for two milliseconds of sampled voltage data, captured at 16 million samples per second. As shown in FIG. 7A, most of the waveform data is general electrical background noise generated by items such as appliances and electromagnetic signals in the air. However, the waveform data also exhibits several larger spikes (e.g., 702, 704)-which are transients that may indicate electrical discharge activity in the electrical circuit.

FIG. 7B is an exemplary diagram that shows a portion of the waveform from FIG. 7A, enlarged to show additional detail. As seen in FIG. 7B, the shape of the individual transients (e.g., 712, 714) appears. Taking an even closer look, FIG. 7C is an exemplary diagram that shows a portion of the waveform (i.e., two μs) from FIG. 7B, enlarged to show additional detail. As shown in FIG. 7C, the transient 514 exhibits a ring-down structure, which indicates the amount of time it takes for attenuation of the signal. In addition, the transient 714 has very fast changes in voltage and a fast rise time. As explained above for Method C, the CPU 204c of sensor device 204 can use this type of sampled waveform data to generate transient characteristics (506) for transmission to the transient analysis module 214a.

FIGS. 8A-8C are exemplary diagrams that show how the CPU 204c of sensor device 204 can divide the sampled waveform signal into 512 bins (i.e., as described above with respect to Methods A and B). An exemplary full voltage cycle waveform is shown in FIG. 8A, with the bin number assigned across the x-axis and the amplitude represented on the y-axis. FIG. 8B is another exemplary voltage cycle waveform, with annotations showing how the CPU 204c of sensor device can identify transients as described above with respect to Methods A and B. As shown in FIG. 8B, the CPU 204c can determine the current max, the current mean, and the max over 15 cycles—as well as the max derivative over 15 cycles, the current max derivative, and the derivative over the full voltage cycle. FIG. 8C is an exemplary voltage cycle waveform, with an annotation depicting a potential electrical discharge identified by the transient analysis module 214a. As described above with respect to Methods A and B, the transient analysis module 214a can determine the ratio of average peak transients in phase sections near maximum voltage (e.g., section 802) to the average peak transients near voltage zero crossings (e.g., section 804). The transient analysis module 214a can generate a representation of the ratio (see FIG. 9). As shown in FIG. 9, the time period from 15:17:40 to 15:18:00 (indicated by 902) is when electrical discharges were being created on the electrical wiring.

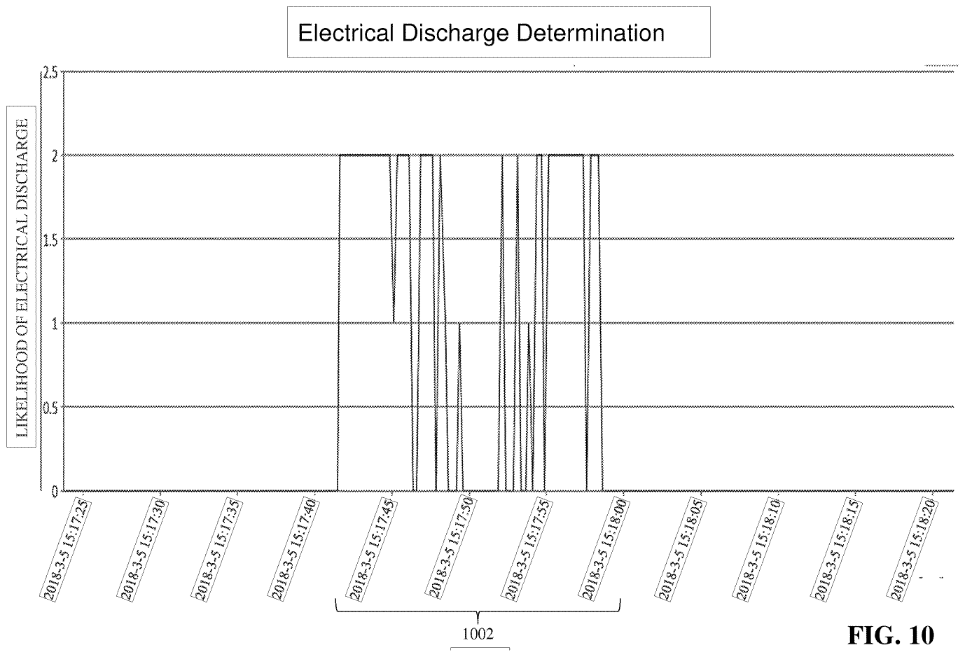

In some embodiments, the transient analysis module 214a can convert the ratio data from FIG. 9 into a metric that indicates the likelihood of electrical discharges occurring based upon the ratio. FIG. 10 is an exemplary diagram showing the likelihood of electrical discharges occurring during a specified time period, based upon the ratio data from FIG. 9. As shown in FIG. 10, the likelihood of electrical discharges moves from 0 to 2 at 15:17:40 and fluctuates between 0 and 2 until 15:18:00. In this example, a value of 2 indicates a high likelihood of electrical discharges occurring.

Upon identifying electrical discharge indicators in the transient characteristic data, the alert generation module 214b of server computing device 214 generates an alert signal (512) relating to the detected electrical discharge indicators. In some embodiments, the alert generation module 214b automatically identifies one or more remote devices that are monitoring (or are otherwise associated with) the building or location where the sensor device 204 is connected to the branch circuit and automatically transmits) an alert signal to these remote devices. The remote devices can include computer-based devices, such as mobile phones, tablets, desktop PCs, smart appliances, IoT devices, smart watches, and the like. The remote devices can also include horns, sirens, lights, and other audiovisual indicator devices.

In some embodiments, the database 216 includes information related to identification of the remote devices (e.g., IP address, phone number, email address), and the alert generation module 214b uses the identification information to prepare an alert signal for each remote device. In some embodiments, the alert generation module 214b uses any standard communication protocol or technique, such as packet-based delivery (e.g., text messaging, XML, email), circuit-based delivery (e.g., paging, voice messaging), and the like. For example, the alert signal can take the form of a packet-based communication (e.g., a message) with a header and body that comprises certain data elements. The alert signal can include information relating to the type of arc fault detected by the system 200, the approximate location of the electrical discharge activity (e.g., using the time-of-arrival techniques described above), an identification of the sensor device 204 and its position in the building, and other relevant information (e.g., identification of appliances or other electrical devices connected to the same branch circuit, etc.).

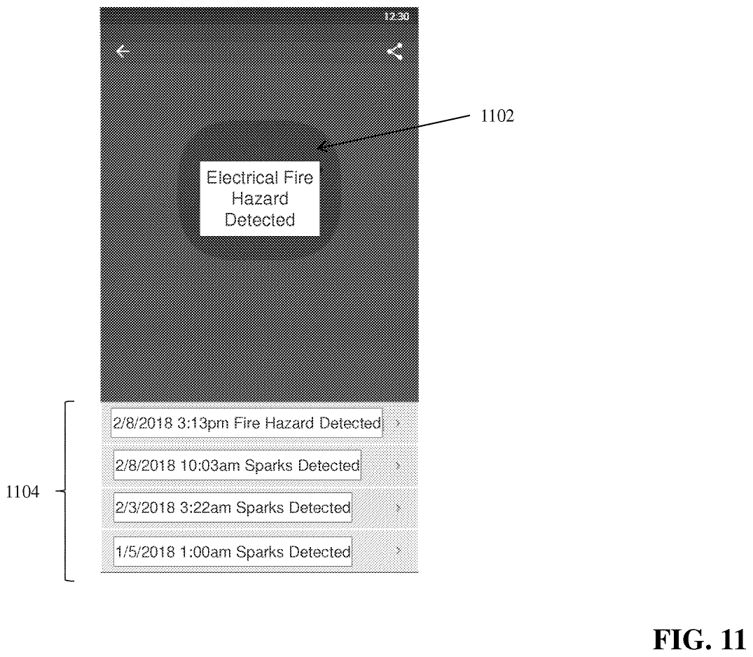

FIG. 11 is an exemplary diagram of a user interface of a remote computing device (e.g., a mobile phone) for displaying a message to a user based upon receipt of an alert signal. As shown in FIG. 11, an app installed on the remote computing device can be coupled to the server computing device 214 (e.g., via the Internet) and can be configured to automatically listen for alert signals pushed from the alert generation module 214b. When an alert signal arrives at the remote computing device, the app can automatically display a warning indicator 1102 (e.g., a red, flashing graphic or icon) that notifies the user of an electrical fire hazard. The user interface can also include a log of prior electrical discharge activity detected (e.g., other events in the user's home).

In this way, the system and method described herein provide significant advantages over currently-available arc fault detection technology, in that the present system can detect small transients occurring in a branch circuit, that may be indicative of electrical discharge activity in the circuit, much earlier and with much more accuracy than traditional arc fault detectors. The system and method described herein also leverage a network-based processing architecture to capture signal data for a particular branch circuit over time, which can both enable immediate detection of changes in the electrical activity profile for the branch circuit and provide useful information to upstream entities such as utility companies and appliance manufacturers about the types of anomalies that may be occurring in a power system.

Also, it should be appreciated that multiple different sensor devices can be installed in various buildings across a common electrical grid operated by a utility provider (e.g., many different homes may have a sensor device attached to the building's electrical system to monitor for electrical discharges as described above). Each of these distributed sensor devices can communicate with one or more centralized server computing devices that send data to, and receive data from, the sensor devices. In this configuration, the server computing device can collect electrical discharge detection data from the sensor devices and aggregate the data for analysis. In one example, the server computing device can implement machine learning techniques and algorithms that use electrical discharge and/or transient data from a plurality of sensor devices installed in different homes and buildings, along with feedback from end users, to improve upon its transient detection and characterization algorithms.

In some embodiments, analyzing transient characteristics to identify one or more electrical discharge indications is enhanced by the application of machine learning techniques. Techniques such as boosted trees (as described in xgboost.readthedocs.io/en/latest/tutorials/model.html and Friedman, Jerome H., “Gradient Function Approximation: A Gradient Boosting Machine,” The Annals of Statistics, Vol. 29, No. 5 (October 2001), pp. 1189-1232, incorporated herein by reference) allow for the automated selection of various characteristics based on truth data sets from houses or buildings with known electrical discharge signals or truth data sets generated in a lab. Machine learning allows for development of a more detailed computational model and relationships between transient characteristics and electrical discharge indications than a human could manually derive. In some embodiments, time series features such as autocorrelation lags and kurtosis from these transient characteristics are further computed over a tumbling window and provide these features to the machine learning model to provide further context and improve accuracy. As truth data sets for both electrical discharge indications or false positives expands, the machine learning models can be improved, and further developed firmware can be deployed to the sensor in a continuous cycle of improvement.

In addition, the server computing device can distribute updated software methods for identifying transients and transient characteristics (i.e., in the form of firmware or similar upgrades) to the sensor devices for execution—thereby automatically synchronizing the sensor network with the latest algorithms for protecting the home. Also, multiple sensor devices placed in multiple homes can correlate data about commonly-detected voltage waveforms and transients to pinpoint the potential location of electrical grid problems and communicate to grid operators or utility providers to take action.

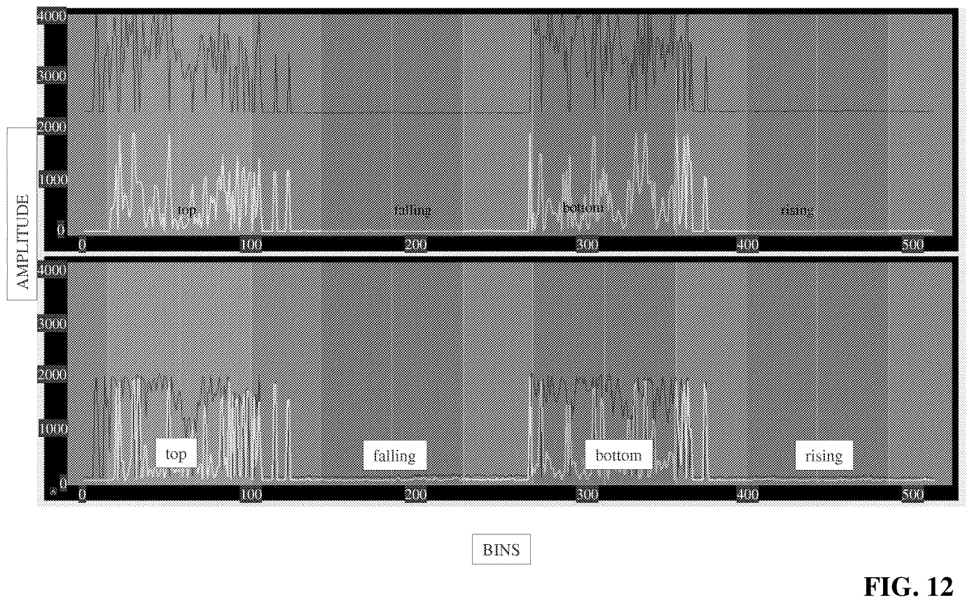

Another aspect of the systems and methods described herein can include the incorporation of a device that generates signals that look like dangerous electrical discharges, but instead are introduced to the electrical wiring via a separate electronic device (which in some embodiments, is embedded in the sensor device 204). These signals (also called safety signals) can be used to test the operation of the sensor device 204, so that any malfunctions or other problems with the sensor device 204 can be identified. FIG. 12 is a diagram of an exemplary waveform generated from detection of the safety signals. As shown in FIG. 12, these transients are similar to the types of transients that would be created if a dangerous electrical discharge was occurring on the wiring. It should be noted that these transients are small enough to be detected by the sensor device 204, but not large enough to trip an AFCI.

Another important aspect of the systems and methods described herein is the development of an apparatus to test the effectiveness of the sensor device in detecting fire precursors that occur at any location in a home. One possible way to accomplish this would be to take a damaged cord that is producing fire precursor pulses to many homes and measure how well pulse signals are detected from other outlets in the home. The drawback of this approach is that it would take a significant amount of time to send a trained technician that can safely produce the signals and the study would only measure the signals over a short period of time—while someone was monitoring the system within the home. No reasonable individual would welcome a damaged (and hazardous) electrical cord in their house for an extended period of time.

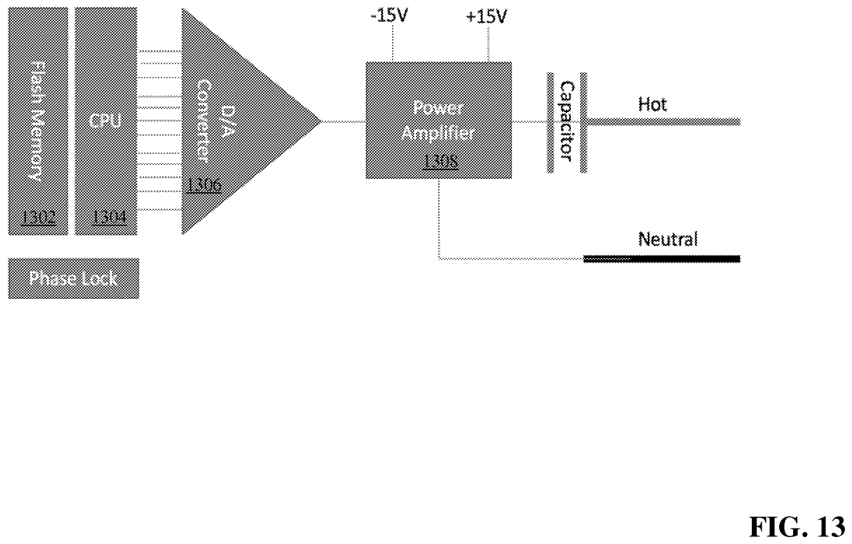

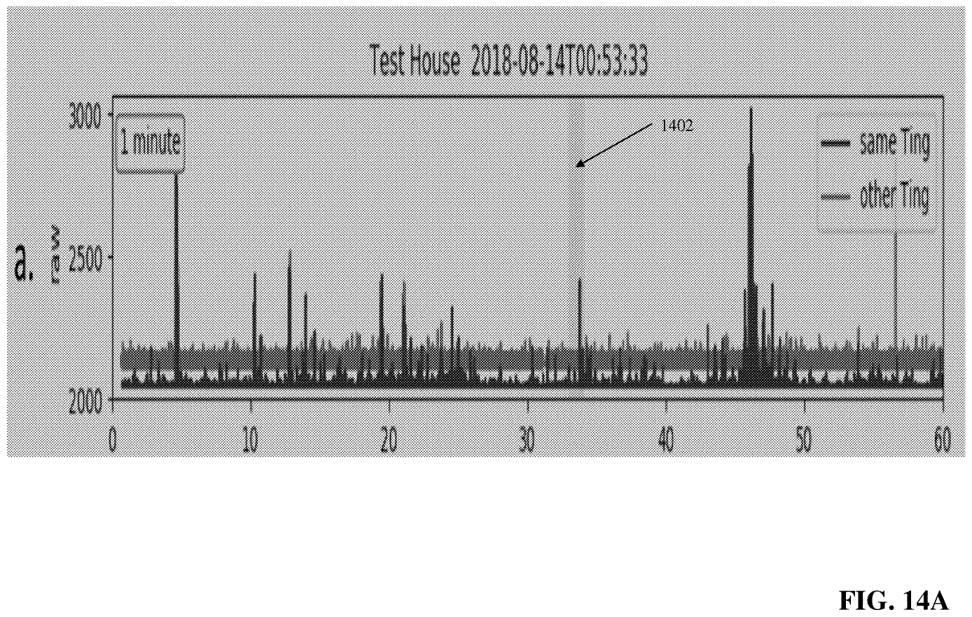

An alternate and more scalable approach is the use of a proxy device which can replay fire signals that are produced and recorded in the laboratory by real fire precursors. This proxy device allows for economical deployment of hundreds of units to varying types of homes across the country, along with an ability to track signal detection performance over long periods of time. FIG. 13 is a block diagram of a proxy device 1300 that can be used in conjunction with the system 200 of FIG. 2.

As shown in FIG. 13, the proxy device 1300 comprises a flash memory module 1302, a CPU 1304, a digital-to-analog signal converter (DAC) 1306, and a power amplifier 1308. The device 1300 utilizes the DAC and the power amplifier (coupled to the electrical system via the power capacitor) to simulate the fire precursor signals. The DAC 1306 can produce signals at 120 MHz for short periods of time. The CPU is phase locked with the zero crossing from the power mains to generate pulses that occur at appropriate locations in the phase. Pulse information is read by the CPU from the flash memory and recorded pulses are reproduced through the D/A converter and Power Amplifier.

The proxy device 1300, when deployed in a plurality of homes, helps to answer the following questions:
1) How well do the fire precursor arcing signals travel in a home's electrical system?
2) How well do the methods and systems described herein identify electrical fire signals and distinguish these signals from those created by other appliances in the home?

To determine how well fire precursor pulse signals travel in the home electrical system, the proxy device 1300 and sensor device 204 were deployed in a test home, along with a test fixture that when plugged into an electrical outlet at the home, produces scintillation pulses for detection. The test fixture included a power cord plugged into a standard wall outlet with Hot, Neutral and Ground conductors. The power cord was spliced to include resistors through which any currents creating by scintillations or electrical discharges must pass. The end of the power cord was connected to a plug through which various test apparatuses can be connected. The test fixture included a plastic NEMA enclosure through which a damaged extension cord was passed. The damaged electrical cord can be exposed to various substances which cause electrical discharges to occur. For example, the substance could be graphite powder, water or a solution of water, soap and salt. A differential analog to digital converter measures the voltage across a resistor of known resistance to calculate the current flow through the resistor. Resistors of various sizes were selected to provide appropriate amount of gain depending on the expected peak current generated by exposing the damaged cord to various substances. The test home is a large single-family home of approximately 4,000 square feet. The home has typical types of electronics equipment including flat screen televisions, audio equipment and computers. The electronics equipment is typically protected by surge suppressor power strips.

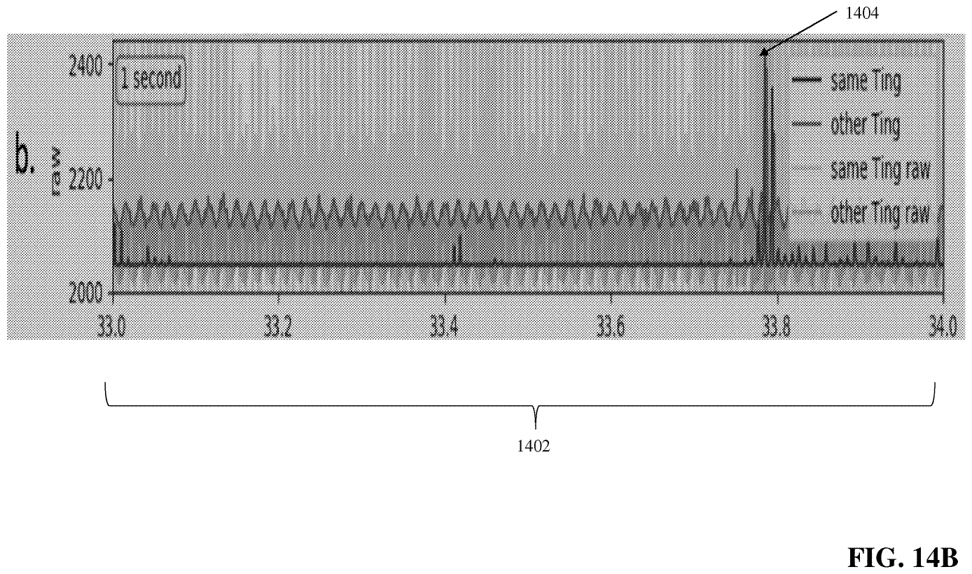

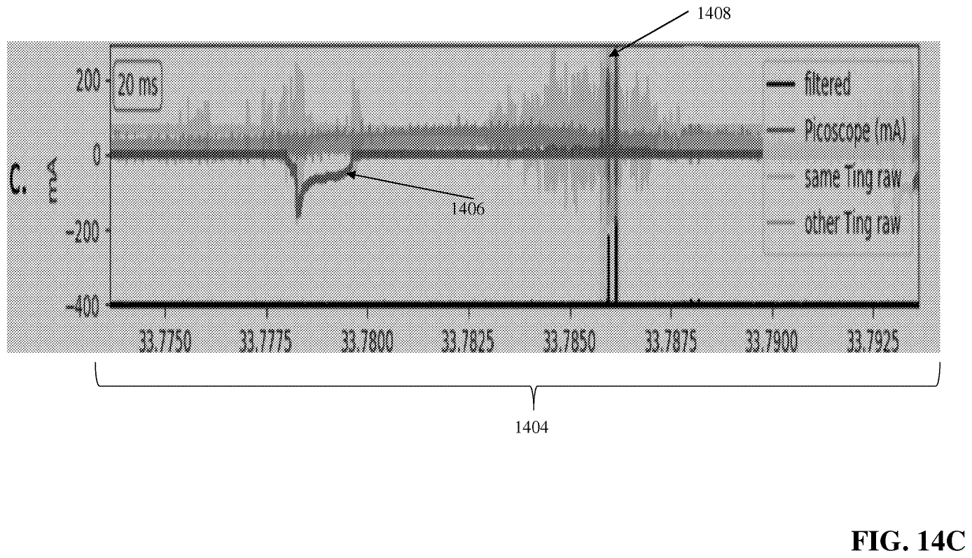

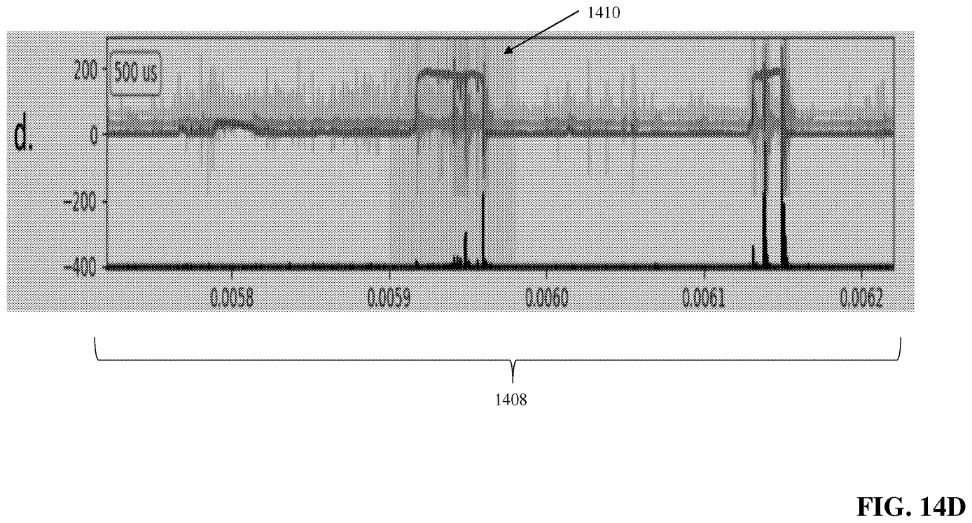

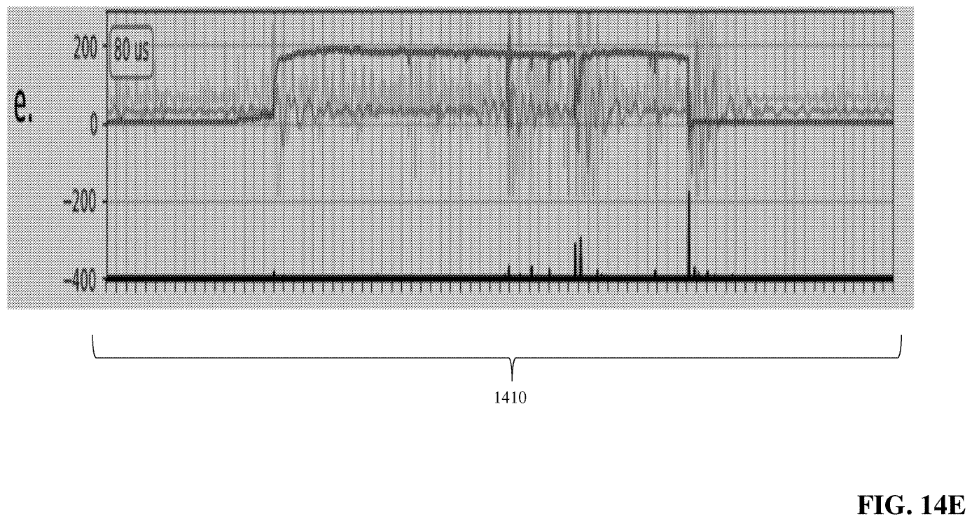

FIGS. 14A-14E are diagrams showing fire precursor arcing signals collected from the test home. The graph in FIG. 14A shows 60 seconds of a measurement of peak analog to digital converter output from two sensors. The sensor device labeled “Same Ting” is on the same 120V leg/phase, and is on the same branch circuit as the test fixture. The sensor device labeled “Other Ting” is on the opposite 120V leg/phase of the power network on a different branch circuit. Larger amplitude signals indicate times when the test fixture is creating fire precursor pulses. For example, in FIG. 14A the Same Ting line and Other Ting line jump up to approximately 2400 raw digital units in the area highlighted in the area 1402—indicating that both sensor devices detected a fire precursor pulse. The graph in FIG. 14B shows the highlighted period 1402 from FIG. 14A as zoomed into one second of time.

For the graph in FIG. 14C, data from FIG. 14B is further zoomed in to 20 milliseconds of time—which is denoted by the area 1404 in FIG. 14B. In FIG. 14C, the measurement of current 1406 through a 10-ohm resistor on the hot line of the test fixture is shown. This is the current that flows when breakdown on the insulator occurs and is observed as an electrical discharge and is evidenced in the form of heat and light.

FIGS. 14D and 14E show further zoomed-in periods of the current flow through the 10-ohm resistor and the resultant waveforms as seen by the sensor devices. The graph in FIG. 14D shows the highlighted period 1408 from FIG. 14C as zoomed into 500 microseconds of time, while the graph in FIG. 14E shows the highlighted period 1410 from FIG. 14D as zoomed into 80 microseconds.

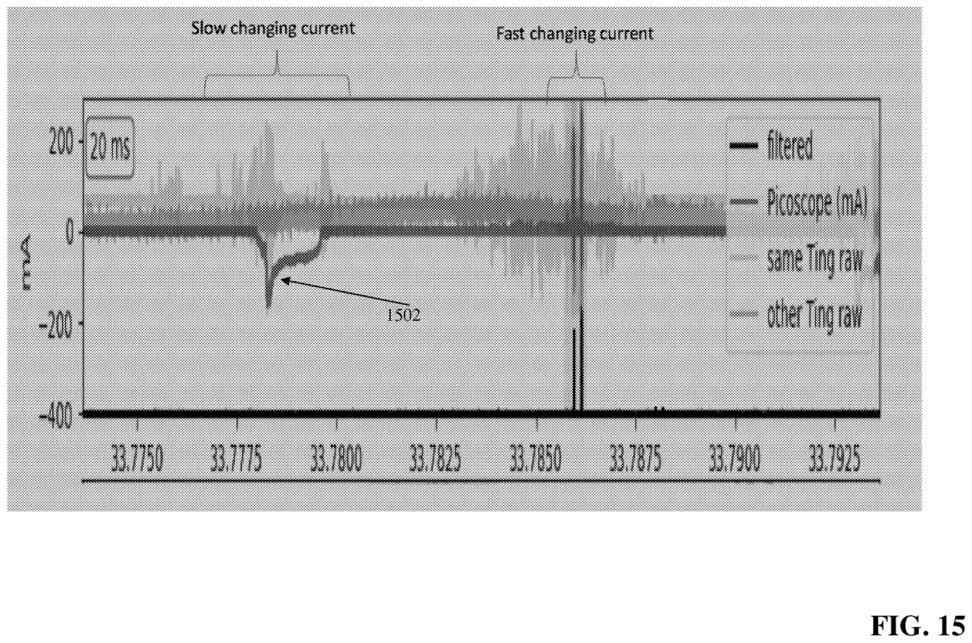

FIG. 15 shows a more detailed version of FIG. 14C, highlighting two times where electrical breakdown occurred and which the sensor devices measured current through the 10-ohm resistor. In this example, one appreciates that electrical breakdown can produce currents that change slowly over a time period of many microseconds, to currents that start and stop very fast, on the order of nanoseconds to tens of nanoseconds. As can be seen in FIG. 15, the slowly changing currents produce a visible signal 1502 in the sensor device on the same circuit (“Same Ting”), but not in the sensor device on a different leg (“Other Ting”), while the fast-changing currents are visible in the signals from both sensor devices.

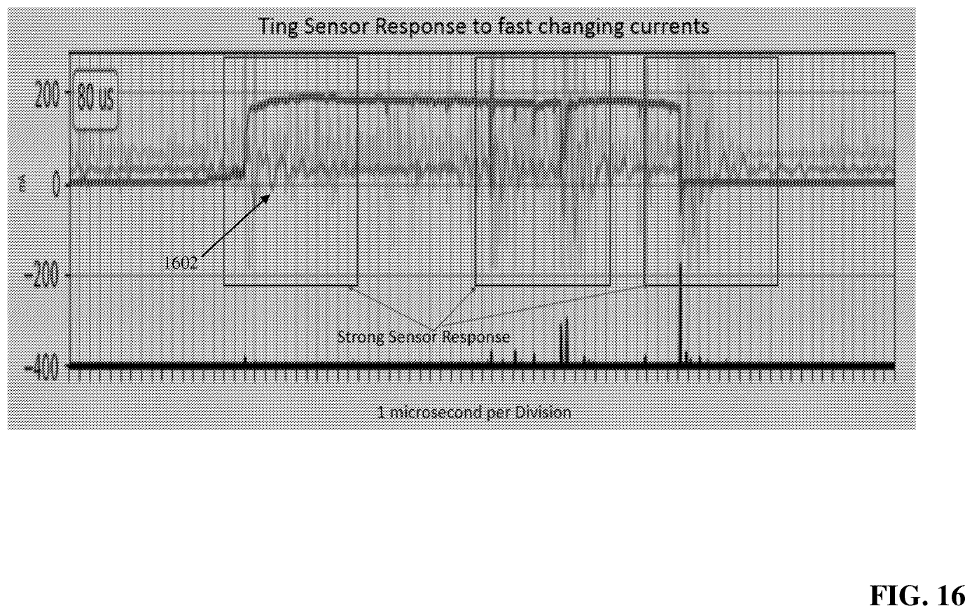

FIG. 16 shows a more detailed look at one of the individual pulses from an electrical discharge with some information on the current change rates as the current starts flowing, then experiences several interruptions to the current flow until finally being extinguished. Note that at each fast change in the current, both sensor devices see a sharp rise in signal followed by a characteristic ring-down. This demonstrates that the characteristic of the electrical discharge that makes the biggest impact on how well signals travel through the electrical network is the very fast rise time and fall time of the currents. Note that as the discharge starts, the characteristic ring down signal 1602 appears, but as the current continues at the same level, the sensor device on the opposite phase does not have a strong response. This is an important finding for the development of the proxy device, as it means that as long as the proxy device can simulate the fire precursor fast pulse currents rise and fall times, then it can re-create the most relevant part of the signal and does not need to re-create the longer continuing currents.

It should be appreciated that the proxy device 1300, which functions as an arbitrary waveform generator, reproduces laboratory waveforms imperfectly. It can only generate voltage steps at certain digital clock edges and it can only generate steps of certain discrete amplitudes. The system performs lossy compression on the data, preserving only the largest peaks and preserving their shapes. The impedance of the proxy device 1300 is not the same as the impedance of a damaged portion of insulator, so reflections from the proxy device differ from reflections from a damaged cable. As a result, it is important to confirm that the proxy device is sufficient to produce signals at the sensor device 204 similar to the signals produced by real scintillations in damaged insulation.

To test this, insulation on a wire was damaged in the laboratory, the currents produced by scintillations in the damaged insulation were measured, and voltages produced by those scintillations at a sensor device on a different circuit in the laboratory were simultaneously measured. The proxy device 1300 was then programmed to replay the scintillations that were measured, the damaged insulation was replaced with the proxy device, and again currents produced at the proxy device and voltages produced at a sensor device on a different circuit were simultaneously measured.

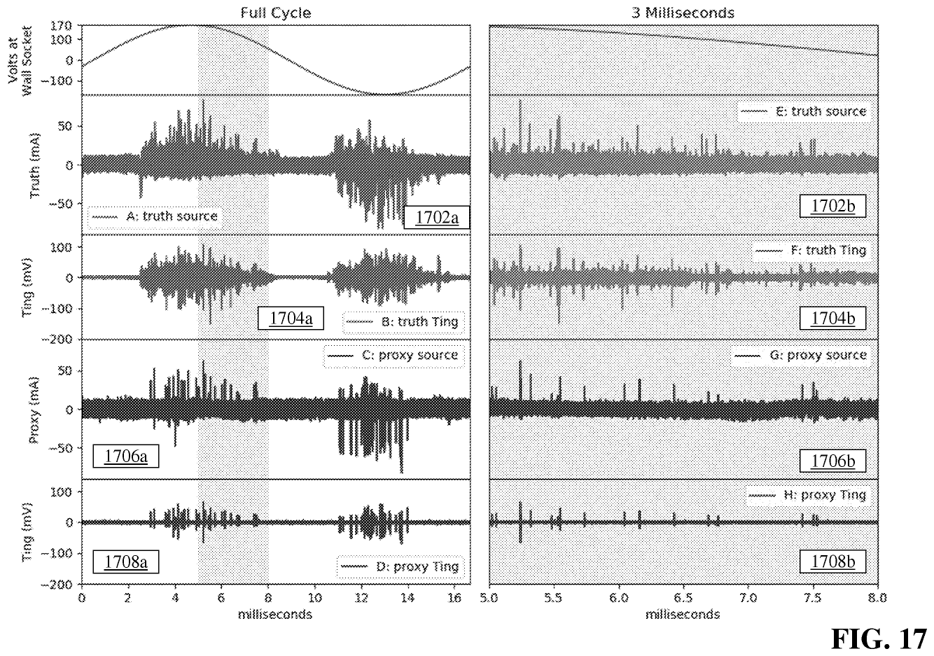

FIG. 17 shows the results of the testing described above. Graph 1702a shows the current initially measured in the laboratory from damaged insulation. Graph 1704a shows the voltage a sensor device measured at another circuit, produced by the current pulses shown in graph 1702a. Graph 1706a shows the current produced by the proxy device, and graph 1708a shows the voltage measured by a sensor device on another circuit. Graphs 1702b, 1704b, 1706b, and 1708b show the same measurements of graphs 1702a, 1704a, 1706a and 1708a, respectively, at a higher time resolution. The sensor voltages produced by the proxy device are not identical to those initially measured, but they are similar enough to use.

A second characteristic of fire precursor pulse signals that determine if they travel through the house is the amplitude of the pulse. Larger amplitude pulses produce a larger response in the sensor device 204. The relationship between the amplitude of the current and the size of the sensor device response can be seen in graphs 1702b and 1704b. Larger current amplitudes in graph 1702b are observed as larger sensor responses in 1704b. Similarly, larger amplitude currents produced by the proxy device, result in larger responses at the sensor device (see graphs 1706b and 1708b). Currents on the order of 25 mA are sufficient to produce a response in the sensor device 204 with sufficient signal to noise ratio to be detected.

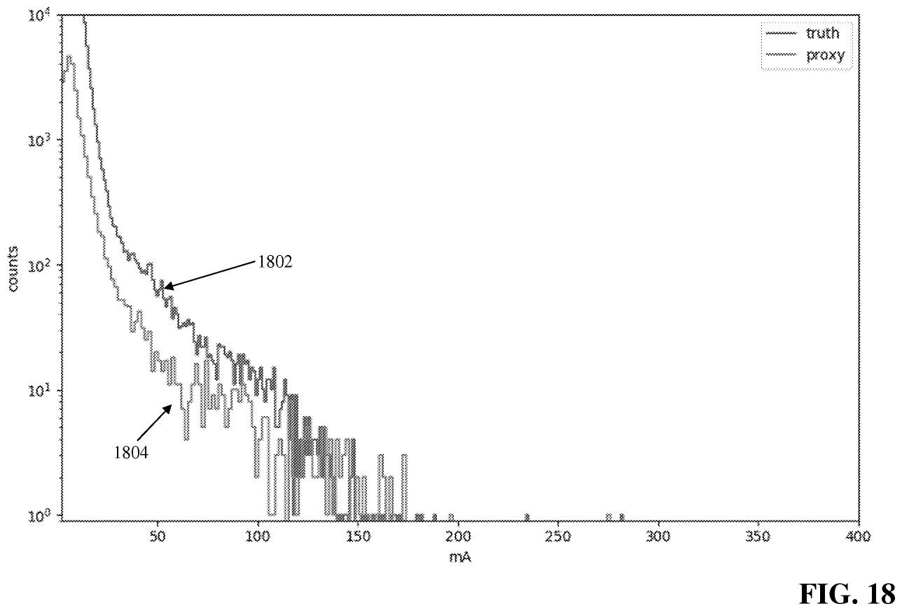

Fire precursors can generate thousands of pulses over a single power cycle a large percentage of which are not large enough in amplitude to travel through the electrical infrastructure and be seen by a sensor device on the opposite leg. The proxy device 1300 is capable of producing a limited number of pulses per cycle. The proxy device is programmed to focus on generating the largest and fastest pulses which are expected to be detected throughout the house. In some embodiments, the proxy device 1300 can communicate with a server computing device (e.g., server computing device 214) to notify the server of times which it is operating and which mode it is operating. In this case, it is easy to correlate the times where the proxy device indicates it is running to sensor device output to verify that the sensor device detects the signal. In this example, the proxy device 1300 was programmed to create fast pulses with amplitudes that ranged from 0 milliamps to 300 milliamps. FIG. 18 shows a histogram of the amplitude of pulses found in a five second set of data that was acquired in the lab, labeled “truth” (dark gray, 1802). Additionally, a histogram of the amplitude of pulses re-created by the proxy device is shown in light gray (1804). Generally, the counts of proxy pulses is less than from the truth data source. As described above, this is because of the limits of the proxy device memory to hold enough data to reproduce every pulse, so the focus is on reproducing the largest pulses.

Note that pulse current amplitudes in the proxy test data set are small in comparison to the peak amperes which trigger arc fault circuit interrupters. An AFCI will trip at about 50 amps for a parallel arc and 5 amps for a series arc (as described in J. Wafer, “The Evolution of Arc Fault Circuit Interruption”, The 51^{st} IEEE HOLM conference on Electrical Contacts, 2005). By detecting pulse currents with these small amplitudes, the sensor device described herein is able to alert a homeowner well in advance of the level at which the arcing becomes dangerous and fire hazard is imminent. This timeframe between when scintillations are detected and the arc grows large enough to be dangerous can be on the order of hours to years (as described in Twibell, J. D., Electricity and Fire, pp. 61-104 in Fire Investigation, N. N. Daéid, ed., CRC Press, Boca Raton, FL (2004)).

Having demonstrated that fire precursors create signals on the power network that travel throughout and can be detected by a single sensor device, the second question for detection efficiency relates to how well the sensor device can distinguish between fire precursor signals and man-made or other interfering signals which can be sensed on a power line. Fire precursor signals exhibit certain characteristics of parallel arcs which are exploited for identification (note that series arcs have other characteristics that can be exploited for identification-such as low signal at zero crossings with a large amplitude impulse just outside the area of the zero crossing, and glowing connections have yet different characteristics that can be exploited for identification):
1) The fire precursor pulse signals are on average larger near voltage peaks and weakest, approaching zero near the voltage zero crossings.
2) Pulse signals are randomly distributed in time across multiple cycles and are randomly distributed across the phase.

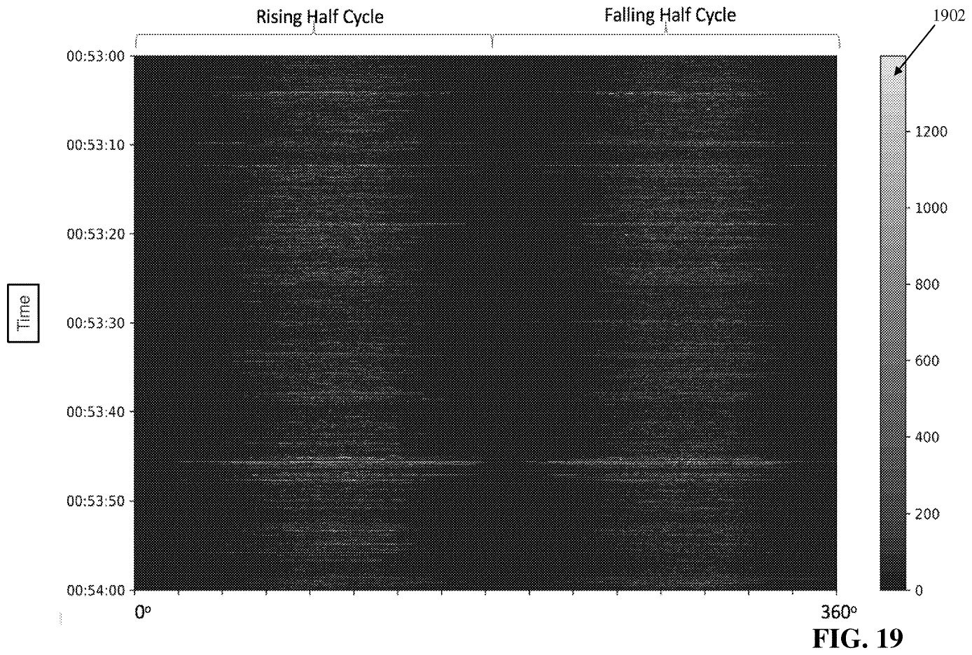

FIG. 19 shows a plot of how fire precursor signals look over time. Time on the plot is increasing from top to bottom. Each row of the plot is representative of a single power cycle with the rising half cycle indicated on the left and the falling half cycle indicated on the right. The scale 1902 indicates the amplitude of HF signals detected at various places in the power cycle phase. For parallel arcs, the HF amplitude increases at the peaks of the power cycle and goes to zero at the zero voltage crossings.

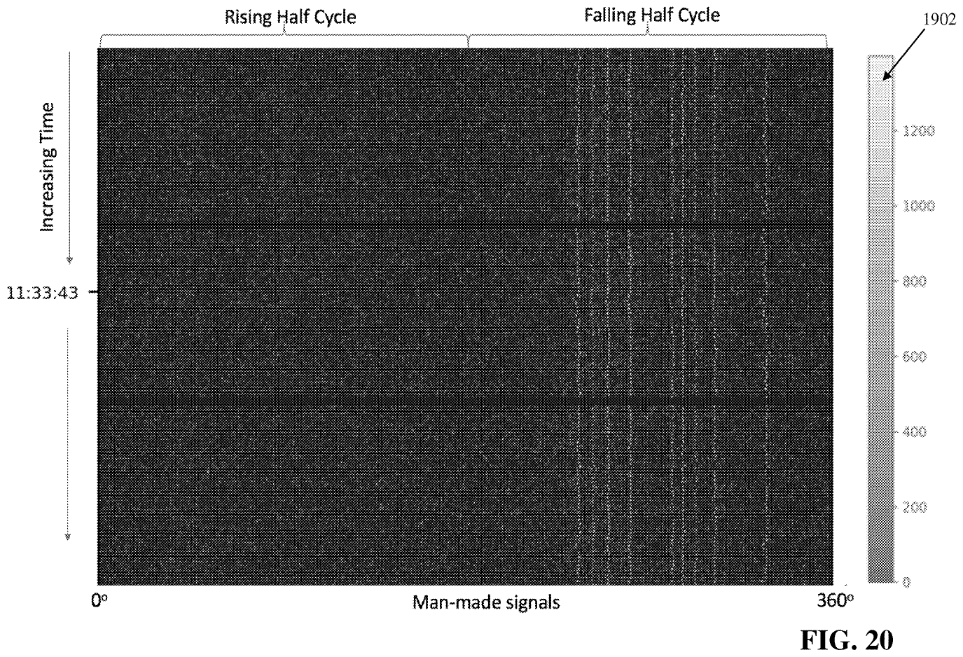

For comparison, FIG. 20 shows the plot of FIG. 19 for a device running on the electrical network that is generating HF electrical activity. A typical feature of devices running on an electrical network is that HF electrical activity is in repeatable places in the phase over longer periods of time. This is indicated by the vertical lines in the falling half cycle. The sensor algorithms described herein exploit the differences between man-made devices which generate predictable and repeating signals from fire precursor signals which are more variable in time and amplitude.

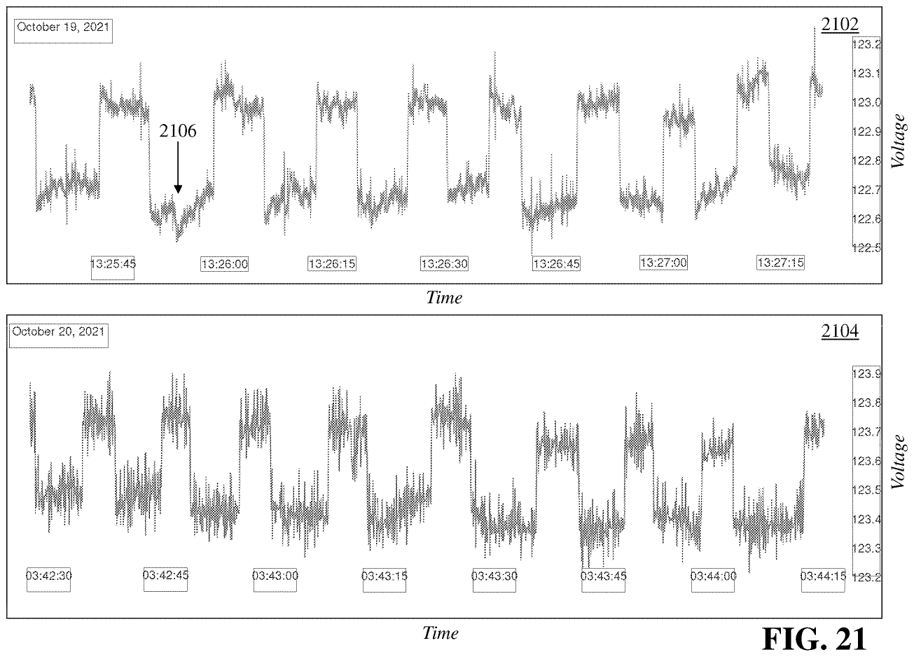

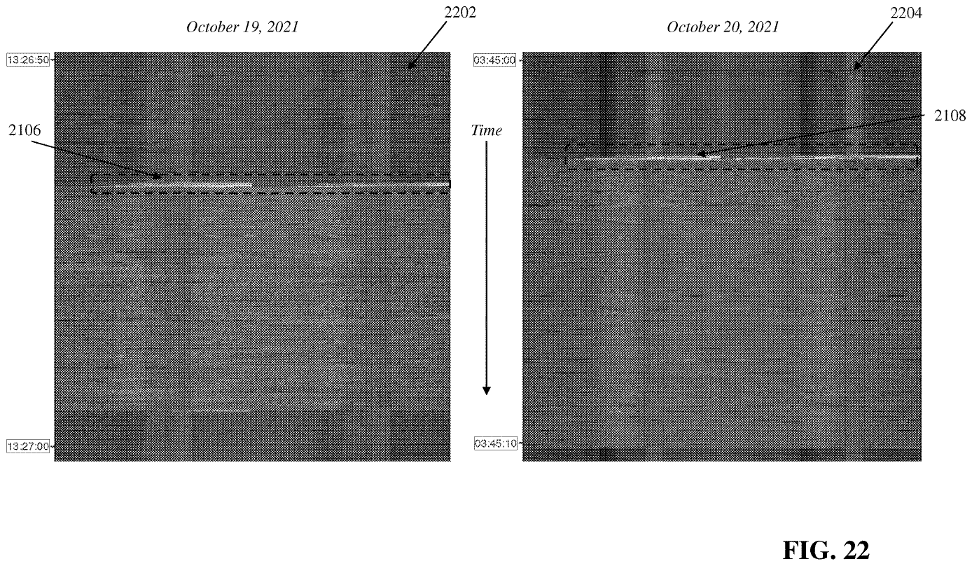

Building upon the ability to identify individual arcing events as described above, another important aspect of the fire precursor detection and mitigation techniques described herein is the ability to group the identified individual arcing events into patterns of electrical discharge activity and recognize the patterns as potential fire precursors based upon either comparing the pattern to one or more known hazardous electrical discharge patterns (such as a comparison of transient characteristics of the waveforms) and determining a match or by identifying other conditions (e.g., weather, time of day, continuous occurrence, power quality events, etc.) that align with the detected pattern, in order to understand a cause of the electrical discharge activity and proactively mitigate the risk of destructive fires. FIG. 21 is a diagram of graphs of root mean square (RMS) Voltage changes over time associated with an appliance (e.g., an oven) turning on and off. As shown in FIG. 21, the top graph 2102 and the bottom graph 2104 are captured from different days (top=Oct. 19, 2021; bottom=Oct. 20, 2021) showing the voltage pattern from the oven turning on and off. As can be appreciated, when the oven turns on, the voltage drops (see, e.g., reference 2106). The electrical discharge activity associated with the turning on of the oven is shown in the visualization of FIG. 22 (described below). When the oven turns on, this creates an electrical activity pattern 2104 which is the same on Oct. 20, 2021 as the electrical activity pattern 2102 on Oct. 19, 2021. The RMS Voltage over time shows the same type of activity which allows system 200 to relate the turning on of the oven to the arcing pattern.

As described in this specification, an electrical discharge activity pattern can be visualized as a two-dimensional image where each cycle (representing one power cycle) is visualized by a horizontal row of pixels representing the transient characteristics. A row of pixels begins with the upward zero crossing of the power cycle, and the vertical axis represents how the electrical discharge activity patterns change from cycle to cycle. FIG. 22 is an exemplary visualization for an electrical discharge activity pattern, where the pattern is generated from the voltage changes of FIG. 21 as detected by system 200 due to faulty wiring of the electric oven. As shown in FIG. 22, image 2202 comprises an electrical discharge activity pattern generated from the voltage changes detected between 13:26:22 to 13:27:22 on Oct. 19, 2021. Image 2204 comprises the electrical discharge activity pattern generated from the voltage changes detected between 03:44:32 and 03:45:32 on Oct. 20, 2021. As can be appreciated, the electrical discharge activity patterns between images 2202 and 2204 are nearly identical. When the oven turns on, each of the activity patterns exhibits an arcing discharge indication—the bright areas 2206 and 2208, respectively.

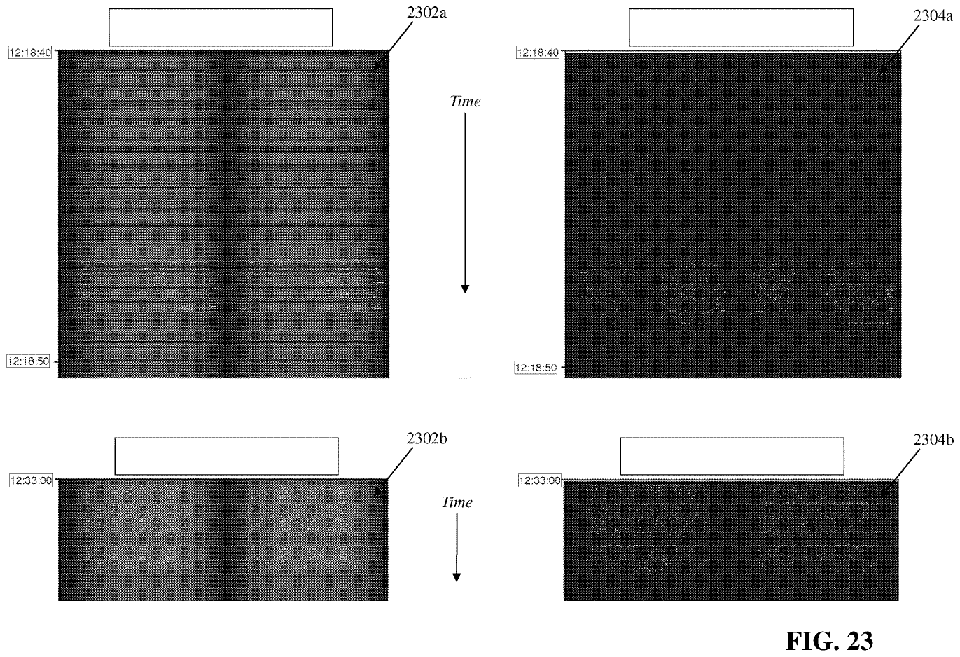

FIG. 23 is another exemplary visualization for an electrical discharge activity pattern generated by system 200, including an unfiltered view and a filtered view. As shown in FIG. 23, the left-hand images 2302a and 2302b represent an unfiltered view of an electrical discharge activity pattern occurring in an electrical system of a home. The electrical discharge activity pattern is generated due to any of a number of deficiencies with the electrical system (such as those examples described previously). Image 2302a comprises an electrical discharge activity pattern detected in a one-minute window (e.g., 12:18:40 to 12:19:40). Image 2302b comprises an electrical discharge activity pattern detected in another, later one-minute window (e.g., 12:33:00 to 12:34:00). Similarly, the right-hand images 2304a and 2304b in FIG. 23 represent the same electrical discharge activity pattern as represented in images 2302a and 2302b with a filter applied to remove repeating background activity. As can be appreciated, the electrical discharge activity patterns between corresponding images 2302a and 2304a, and images 2302b and 2304b, are very similar.

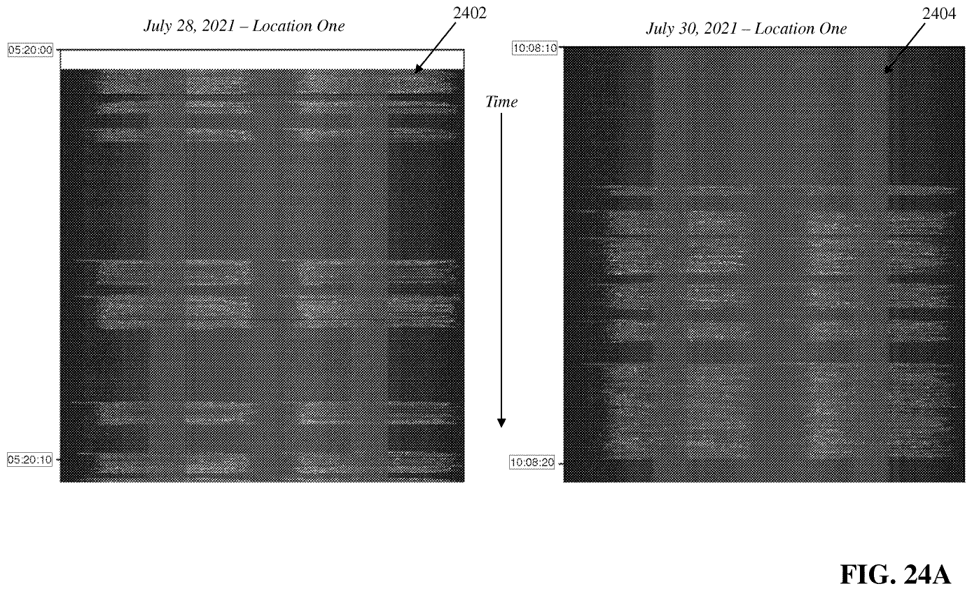

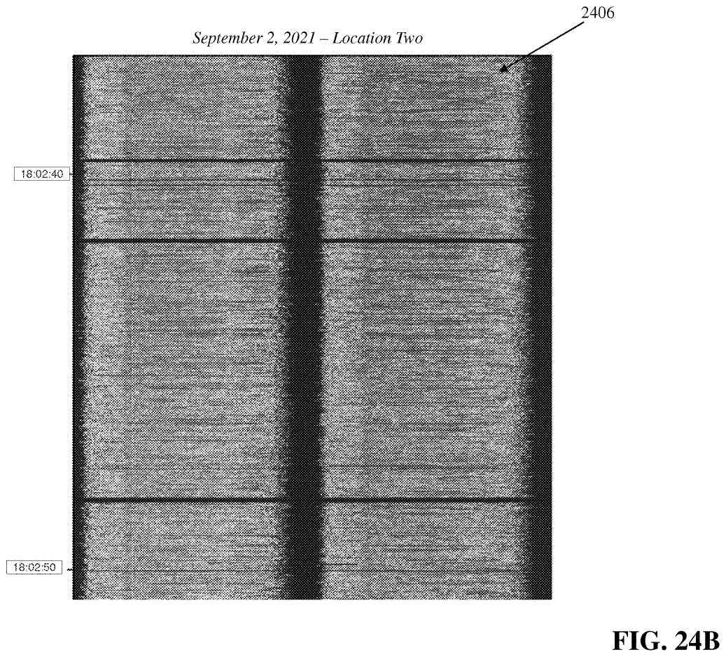

FIG. 24A is another exemplary visualization for an electrical discharge activity pattern, where the pattern is generated due to arcing at an electrical panel bus bar in a particular home (Location One) and the pattern occurs at two different time periods. As shown in FIG. 24A, image 2402 comprises an electrical discharge activity pattern detected between 05:20:00 and 05:20:10 on Jul. 28, 2021. Image 2304 comprises the electrical discharge activity pattern detected between 10:08:10 and 10:08:20 on Jul. 30, 2021 at the same home. As can be appreciated, the electrical discharge activity patterns between images 2402 and 2404 are highly similar.

FIG. 24B is another exemplary visualization for an electrical discharge activity pattern, where the pattern is generated due to arcing at an electrical panel bus bar in a different home (Location Two) than in FIG. 24A. As shown in FIG. 24B, image 2406 comprises an electrical discharge activity pattern detected at the home between 18:02:37 and 18:02:50 on Sep. 2, 2021. Although brighter (likely due to the sensor devices being closer to the electrical panel), the pattern depicted in the image 2406 of FIG. 24B is very similar to the pattern depicted in the images 2402, 2404 of FIG. 24A. Advantageously, this similarity enables system 200 to store electrical discharge activity patterns detected at a first location, e.g., in a library of patterns, and compare the patterns stored in the library to electrical discharge activity patterns detected at a second location—in order to quickly determine that a similar cause may be responsible for the discharge activity at the first location and the second location. Further details regarding the use of a library of electrical discharge activity patterns is provided below.

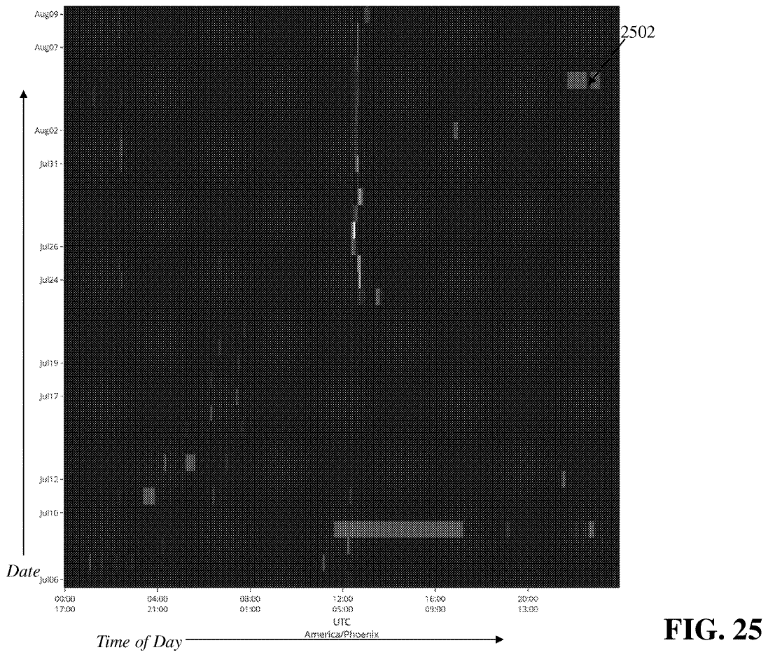

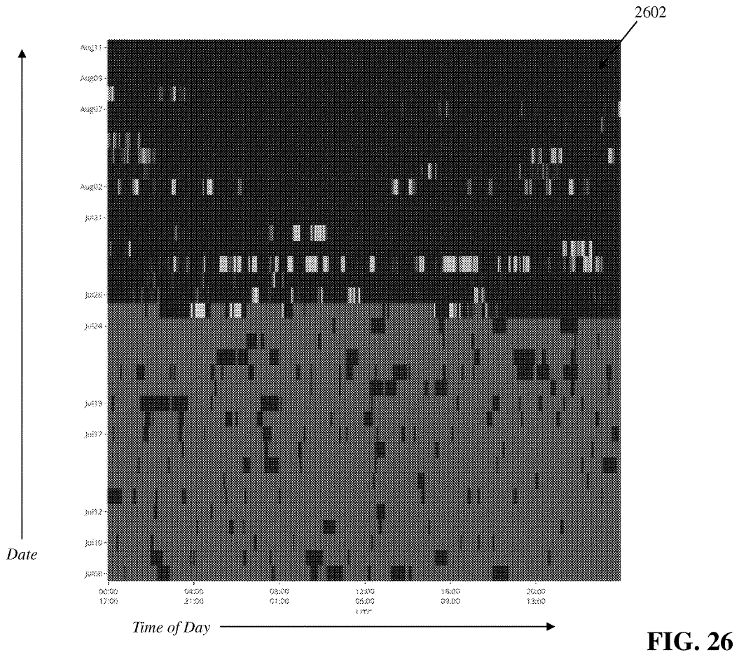

When one or more electrical discharge activity patterns are detected and recognized as hazardous, other associated events (e.g., specific devices turning on or off, grid-related surge or sag power quality events, atmospheric conditions such as solar, temperature, wind, and/or precipitation, and electrical activity occurring at consistent times of day and/or for consistent durations during the day) can be identified as aligning with the occurrence of the discharge activity patterns to further refine the decision of whether a pattern of electrical discharge activity represents a fire risk and to focus on a potential cause of the discharge pattern. FIG. 25 is an exemplary heat map 2502 of electrical discharge activity patterns occurring over time, using the electrical discharge activity pattern of FIG. 22. As shown in FIG. 25, the heat map 2502 identifies dates and times of day when the same electrical discharge activity pattern is occurring (as indicated by the white or light-colored sections). As can be appreciated, the electrical discharge activity pattern occurs at the same time (e.g., around 1200 UTC) each day. In this example, because the same activity pattern is correlated with the same time each day, the system 200 can be configured to raise an alert to the customer and/or the resolution team (as will be described below).

Similarly, FIG. 26 is another exemplary heat map 2602 of electrical discharge activity patterns occurring over time, using the electrical discharge activity pattern of FIG. 24A. As shown in FIG. 26, the heat map 2602 identifies dates and times of day when the electrical discharge activity pattern is occurring (as indicated by the white or light-colored sections). As can be appreciated, the electrical discharge activity correlates to a period of continuous activity.

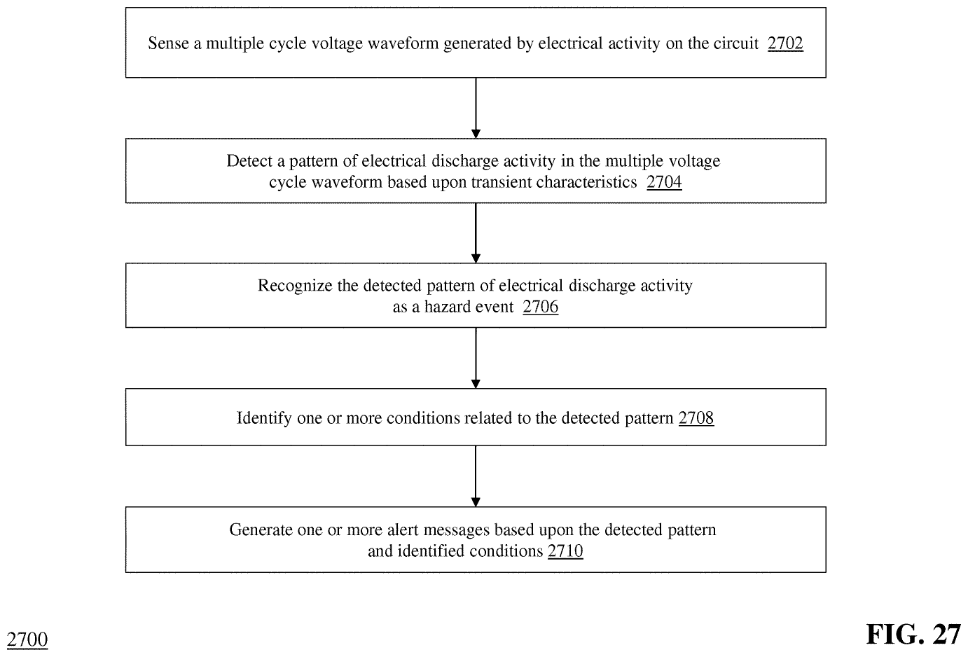

FIG. 27 is a flow diagram of a computerized method 2700 of detecting electrical discharges that occur in electrical wiring across multiple cycles of a voltage waveform, using the system 200 of FIG. 2. One or more sensor devices (e.g., sensor device 204) coupled to a branch circuit (e.g., Branch 1 circuit comprising wires 202) sense (step 2702) a multiple voltage cycle waveform generated by electrical activity on the branch circuit. For example, because an electrical discharge is an impulse change in current, the signal generated by the electrical discharge transmits down the electrical wires 202 reflecting around any junction. These signals have a delay in returning, which is typically based upon the length of the wire. The signals also exhibit a phase shift, which enables the system 200 to detect transient signals in the waveform which represent activity that relates to an electrical discharge (even a very small electrical discharge) on the electrical wires 202 as described herein. In the context of the method of FIG. 27, sensing a multiple voltage cycle waveform advantageously enables the system 200 to analyze waveforms from multiple cycles and determine whether a pattern of electrical activity is occurring, as will be described in greater detail below. The sensor devices 204 transmit the multiple voltage cycle waveform (or at least a portion of the waveform that contains multiple cycles) to server computing device 214.

Transient analysis module 214a of server computing device 214 detects (step 2704) one or more patterns of electrical discharge activity in the multiple voltage cycle waveform based upon transient characteristics of the waveform across a plurality of cycles. As described above with respect to FIGS. 5, 6A-6C, 7A-7C, 8A-8C, 9, and 10, the transient analysis module 214a can analyze transient characteristics of the received waveform to identify electrical discharge activity. In some embodiments, module 214a can categorize each individual electrical discharge activity occurrence as a “series” or “parallel” discharge. As can be appreciated, series and parallel discharges have distinctive signatures within a voltage cycle and module 214a can be configured to detect the distinctive signature of a series and/or parallel discharge in the waveform.

Because in this example the waveform comprises multiple voltage cycles, transient analysis module 214a further determines whether a same type or signature of electrical discharge activity occurs in multiple consecutive or non-consecutive cycles of the waveform-which may indicate a consistent or recurring pattern of electrical discharge activity. For example, module 214a can compare transient characteristics for the waveform in two different cycles and determine whether the transient characteristics match. If a match is determined, module 214a can group the electrical discharge activity from each cycle into a pattern for further analysis. Grouping of the electrical discharge activity into one or more patterns is beneficial to isolating whether arcing is happening, e.g., at the same location in the home over time and/or in similar physical ways. For example, if water is seeping into electrical wiring, such activity will produce a similar pattern of electrical discharge activity occurring over time.

After the transient analysis module 214a has detected one or more patterns of electrical discharge activity, module 214a recognizes (step 2706) the detected pattern of electrical discharge activity as a hazard event. In some embodiments, module 214a recognizes that the pattern is a hazard event based upon analysis of the transient characteristics of the pattern. For example, when the pattern exhibits certain transient characteristics (e.g., a ratio of (i) average peak transients in one or more phase sections of the waveform cycle near a maximum voltage to (ii) average peak transients near a zero crossing of the waveform cycle, and an average of peak transients in one or more of the phase sections near a maximum voltage when the ratio is above a predetermined threshold) that meet or exceed predetermined ranges or threshold values, module 214a can recognize that the pattern is a hazard event and requires further investigation and analysis.

After recognition that the detected pattern is a hazard event, transient analysis module 214a identifies (step 2708) one or more conditions related to the pattern of electrical discharge activity. As can be appreciated, certain types of conditions or events may produce electrical discharge activity patterns on a home's electrical system, or influence already-existing electrical discharge activity patterns, to indicate a potential arcing event or risk of fire. These conditions can include atmospheric events in proximity to the location of the home, such as solar conditions, air temperature, wind direction/wind speed, and/or precipitation. For example, if module 214a determines that the same pattern of electrical discharge activity indications occurs each time it rains at a particular home, it could mean that rainwater is getting into the home's electrical system and causing the discharges. In this case, module 214a can identify that the occurrence of rain aligns with the electrical discharge activity pattern and determine a possibility that the rain is causing the pattern. As a result, system 200 can generate an alert message that prompts the homeowner to investigate whether any structural compromise has occurred with the home (e.g., missing roof shingles, cracked siding, leaking foundation, etc.) to impact the safety of the electrical system.

Conditions that generate or affect patterns of electrical discharge activity may also include grid-based or local infrastructure-based power quality events, such as surge events or sag events. Changes in power quality being received at the home, or occurring within the home, can cause electrical discharge indications to be detected by the system 200—in some cases, these discharge indications can have a particular pattern or signature that corresponds to the power quality event. For power quality events within the home, this could mean loose wiring in an electrical panel or on an individual circuit and can point an electrician to look for a certain type of arcing. This is normally associated with an arcing pattern that is series arcing because of a failed conductor. In the case where the arcing is associated with grid-based power quality events, it could be that the arcing is outside of the home and could be in wiring between the home and the transformer if only impacting nearby homes on the grid, or if impacting multiple homes that are far apart to not be on the same transformer, it could indicate arcing between a substation and the home.

Transient analysis module 214a can correlate the electrical discharge activity indications with power quality event information received from, e.g., a utility provider. For example, when the utility confirms that a power quality event occurred at a specific date and time, and module 214a detects a pattern of electrical discharge activity indications at the same time, module 214a can correlate the pattern to the power quality event. Therefore, module 214a can determine whether the electrical discharge activity indications suggest an arcing event (e.g., certain power quality events may exacerbate arcing events occurring in faulty wiring in a home) or are instead related solely to the power quality event based on, e.g., the transient characteristics of the waveform and the knowledge that a power quality event occurred.

Conditions that generate or affect patterns of electrical discharge activity may also include the activation or deactivation of electronic devices in the home. For example, when a certain device turns on/off, or begins drawing power (such as an HVAC system, appliance, electric blanket, power supply, etc.), there may be an associated change in voltage that is unique to the device. Transient analysis module 214a can associate patterns of electrical discharge activity with power changes caused by devices to determine whether the patterns are indicative of hazardous activity or not. In one example, a homeowner may track his or her device usage over time and provide that information to system 200 for correlation to electrical discharge activity. In another example, sensor device 204 and/or server computing device 214 can be configured to automatically detect changes in voltage on the circuit and/or home electrical system and associate those changes with known signatures of electronic devices.

Any of the above conditions that generate or affect patterns of electrical discharge activity can include a time of day and/or duration of the event to enable more efficient identification of hazardous electrical discharge activity captured by system 200. For example, transient analysis module 214a can monitor the electrical discharge activity and determine that the same electrical discharge activity pattern occurs every day at a prescribed time and for a consistent duration. In another example, module 214a can determine that an electrical discharge activity pattern continuously occurs. Over time, module 214a can correlate this pattern with one or more conditions to determine whether a single cause of the activity can be determined. In cases where the pattern occurs consistently but cannot be reasonably correlated to any conditions that suggest the activity does not comprise arcing in the electrical system, module 214a can determine that an arcing event is likely occurring and generate a notification message.

After identification of conditions related to the electrical discharge activity pattern, alert generation module 214b of server computing device 214 generates (step 2710) one or more alert messages based upon the detected patterns and identified conditions. Module 214b transmits the messages to a remote computing device (e.g., a mobile phone, tablet, smart watch, and the like). The remote computing device can, e.g., display a message or indicator (such as a warning icon) on a screen associated with the remote computing device based upon receipt of the one or more alert signals. For example, the alert signal can comprise a packet-based message including a corpus of text that indicates a dangerous condition or hazard as detected by the system 200. In some embodiments, the alert generation module 214b transmits the one or more alert signals to one or more of the sensor devices 204. The sensor devices 204 can activate one or more components (e.g., embedded components in the sensor device) upon receipt of the one or more alert signals. For example, upon receiving an alert signal from the alert generation module 214b, the sensor device(s) 204 can activate an LED element that lights up and/or flashes on the exterior of the sensor device 204 to indicate that a dangerous condition or hazard has been detected by the system 200. In some embodiments, alert generation module 214b generates alert messages upon determining a risk of fire associated with one or more of the classified patterns and transmits the alert messages to a remote computing device when the risk of fire is at or above a predetermined threshold.

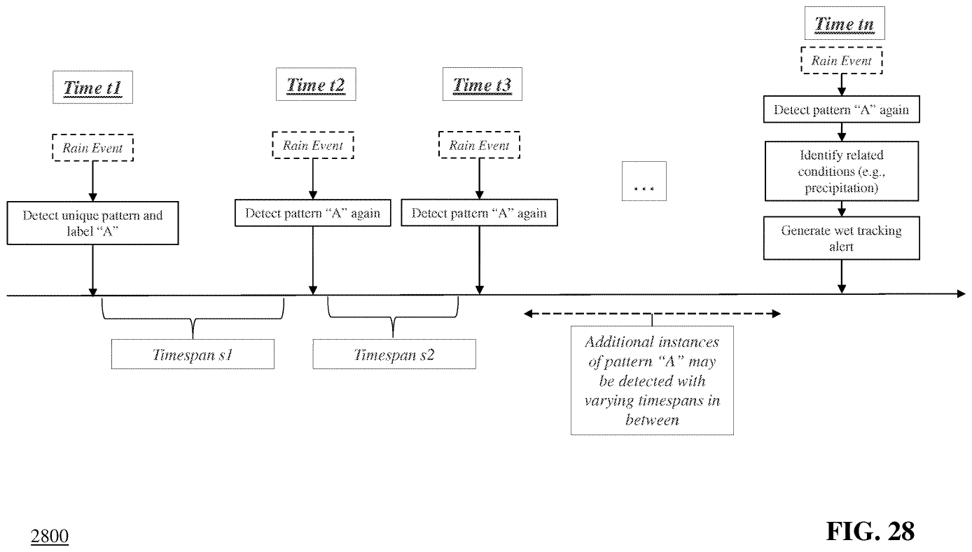

FIG. 28 is a diagram of an exemplary use case timeline 2800 for detecting electrical discharge patterns that occur in electrical wiring across multiple cycles of a voltage waveform and identifying related conditions, using the system 200 of FIG. 2. The exemplary use case described with respect to FIG. 28 involves the periodic detection of a unique electrical discharge pattern that system 200 has not previously detected. As shown in FIG. 28, at Time t1, a rain event occurs at a home where the sensor devices are installed. As can be appreciated, due to deficiencies in home construction or maintenance, rainwater may seep into the interior of the home and come in contact with electrical wiring to cause arcing (also called wet tracking). As the wet tracking occurs, sensor devices 204 installed in the home sense a multiple cycle voltage waveform generated by electrical activity on the circuit or on nearby branch circuits (which includes the wet tracking activity) and transient analysis module 214a detects a unique pattern of electrical discharge activity generated from the wet tracking. In this case, module 214a has not previously detected the same or similar electrical discharge activity pattern. Module 214a applies a label to the detected pattern (e.g., “A”) and stores the labeled pattern in, e.g., database 216 for future reference. In some embodiments, module 214a also stores metadata associated with the labeled pattern, including but not limited to customer information, sensor device information (e.g., IP address, MAC address), location of the home, date/time when the pattern is detected, other conditions (e.g., atmospheric conditions at the home, power quality conditions on the grid servicing the home), etc.

Later, at Time t2, another rain event occurs at the location and module 214a detects pattern “A” again. Module 214a determines that the pattern detected at 2 matches the pattern “A” stored in database 216, and module 214a records a second occurrence of pattern “A.” The timespan between t1 and t2 (Timespan s1) can be days, weeks, months, years, etc. Again, at Time 13, another rain event occurs and module 214a detects pattern “A” for a third time. As above, module 214a determines that the pattern detected at 13 matches pattern “A,” and module 214a records a third occurrence of pattern “A” (along with some or all of the metadata described above). As can be appreciated, due to the randomness and variability of rain events, the timespan between t2 and t3 (Timespan s2) is a different length than Timespan s1. After Time t3, additional rain events occur and module 214a detects further instances of the occurrence of pattern “A” at the home with varying timespans in between the pattern detection.

Then, at Time tn, another rain event occurs and module 214a detects electrical discharge activity corresponding to pattern “A” again. At this point, a sufficient number of occurrences of pattern “A” have been detected to enable module 214a to identify related conditions that align with the occurrences of pattern “A.” For example, at each time that pattern “A” is detected, module 214a can determine that it was raining at the home (e.g., using weather data captured from an external data source and tracked over time). As a result, in some embodiments, module 214a can classify pattern A as a wet tracking event. Alert generation module 214b generates an alert message for transmission to the homeowner and/or monitoring/mitigation service, indicating that a potentially hazardous pattern of electrical discharge activity has occurred at the home a plurality of times and each time it was raining at the home. Using this information, the homeowner or monitoring/mitigation service can coordinate with an electrician or home repair technician to, e.g., physically inspect the home and the wiring system to determine whether any leaks are occurring that cause the discharge activity. In the event that a leak is found and it is determined that wet tracking is causing the discharge, module 214a can be configured to store pattern “A” in database 216 as a “wet tracking” pattern for reference in the future against other unknown patterns.

As can be appreciated, over time as more and more hazardous electrical discharge activity is detected, correlated to identified conditions, and mitigated, a library of known hazardous electrical discharge activity patterns (and associated causes of such discharge activity) can be generated for use in more efficiently recognizing hazardous discharges and more quickly generating alert messages for homeowners. As one example, a faulty electric blanket produces a unique electrical discharge activity pattern and this unique pattern can be recognized by system 200 in electrical discharge activity captured from another home. Because system 200 has already classified this pattern as a hazard, system 200 can immediately generate an alert message for transmission to the homeowner without requiring analysis of other conditions (e.g., weather, time, power quality, etc.) to determine a potential cause.

Advantageously, as mentioned above database 216 can store a library of known hazardous electrical discharge activity patterns (such as waveform snippets, 2D images, and/or transient characteristics), e.g., that were previously detected by system 200 and confirmed as relating to previously discovered and mitigated fire hazards. Examples of such fire hazards can include but are not limited to: circuit breaker and/or bus bar arcing within an electrical panel of the home, electrical appliances (such as heating pads, electric blankets, space heaters, etc.), and power supplies for computers or other electronics. Transient analysis module 214a can retrieve the known hazardous electrical discharge activity patterns from database 216 and compare the known patterns to one or more patterns detected by sensor devices to determine whether one or more of the known patterns matches the detected patterns. In one example, module 214a can use a fuzzy threshold when determining a match—e.g., if a certain number of transients in the detected pattern match transients in the known pattern(s), then module 214a confirms that the patterns match. When a detected pattern matches one of the known patterns, module 214a classifies the identified pattern as a hazard event according to the known pattern type.

As explained above, the electrical discharge activity patterns can be visualized as two-dimensional (2D) images. These images beneficially enable module 214a to utilize artificial intelligence (AI)-based image classification techniques to identify matching electrical discharge activity patterns. Exemplary AI-based image classification techniques and models implemented in module 214a can comprise convolutional neural networks (CNNs), artificial neural networks, k-nearest neighbor algorithms, decision trees, Random Forest algorithms, and/or support vector machines. Module 214a can train an image classification model using the known hazardous activity patterns, so that when a new, unknown discharge activity pattern is provided as input to the model, the model can generate a classification of the unknown pattern (e.g., hazard, no hazard) as well as identifying one or more known patterns that are closest to the unknown pattern. It should also be appreciated that known electrical discharge activity patterns can be added to database 216 for individual homes, buildings, electrical systems, etc., and module 214a can utilize the above-referenced AI-based image classification techniques to classify incoming electrical discharge activity pattern data using the library of known patterns. Furthermore, when a true physical source of arcing is identified (e.g., during mitigation efforts), the library can be annotated with more specific metadata about the identified hazard. In some embodiments, metadata can include things like series/parallel discharge, a device type and/or device model the hazard is associated with, etc. This metadata beneficially enables the system 200 to, e.g., subsequently identify in future analyses the specific make(s) and model(s) of devices that are well-known hazards.

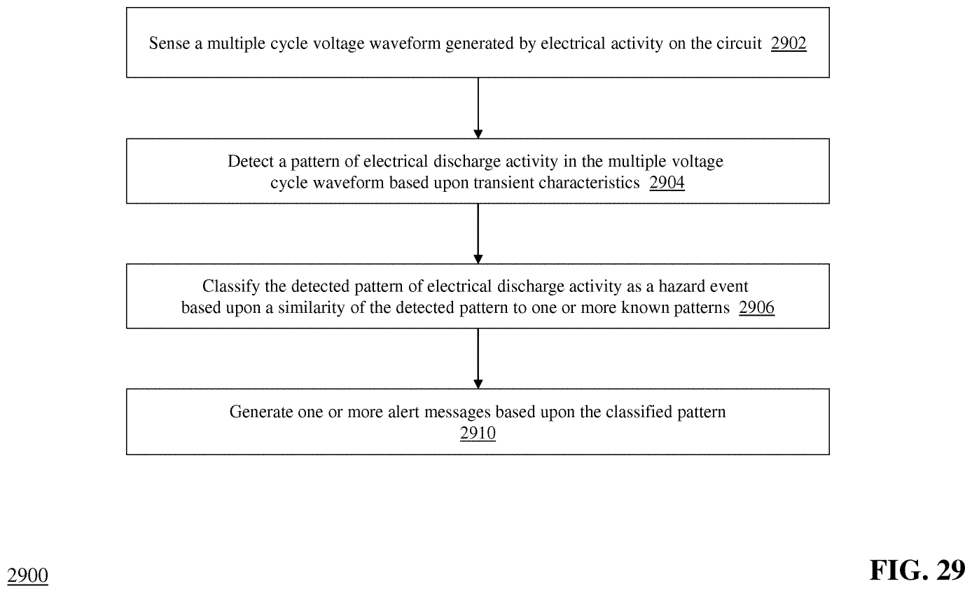

FIG. 29 is a flow diagram of a computerized method 2900 of detecting electrical discharges that occur in electrical wiring across multiple cycles of a voltage waveform based upon known hazardous electrical discharges, using the system 200 of FIG. 2. As described previously, one or more sensor devices (e.g., sensor device 204) coupled to a branch circuit (e.g., Branch 1 circuit comprising wires 202) sense (step 2902) a multiple voltage cycle waveform generated by electrical activity on the branch circuit, and the sensor devices 204 transmit the multiple voltage cycle waveform (or at least a portion of the waveform that contains multiple cycles) to server computing device 214. Transient analysis module 214a of server computing device 214 detects (step 2904) one or more patterns of electrical discharge activity in the multiple voltage cycle waveform based upon transient characteristics of the waveform across a plurality of cycles.

After the electrical discharge activity pattern is detected, module 214a can utilize the library of known hazardous discharge activity patterns in database 216 to determine whether the detected pattern is the same as one or more of the known patterns. Module 214a classifies (step 2906) the detected pattern of electrical discharge activity as a hazard event based upon a similarity of the detected pattern to one or more of the known patterns. In some embodiments, module 214a can compare a two-dimensional image of the detected pattern to one or more two-dimensional images of known hazardous patterns (as described above) and determine one or more similarities between the patterns (e.g., pixel similarity, shape similarity, edge similarity, feature extraction, etc.). For example, module 214a can convert the two-dimensional images into multidimensional vectors and compare the vectors to determine a similarity measure. In some cases, the similarity measure can be quantified as a distance measure-such as Euclidean distance, cosine similarity, or Hausdorff distance. Two images can be considered matching where the distance measure is within a predetermined range of values, such as between 0.9 and 1.0 (where 1.0 indicates an exact match and 0.0 indicates no match).

In the event that the detected pattern matches one or more known patterns, module 214a can retrieve metadata associated with the known pattern from database 216 (e.g., conditions associated with the pattern, cause of the pattern, etc.) and generate (step 2908) one or more alert messages based upon the classified pattern and the retrieved metadata for transmission to the homeowner devices/mitigation service computing devices. In some embodiments, the known pattern can correspond to a specific device type (e.g., model, make), specific conditions (e.g., atmospheric conditions, time conditions, power quality conditions), and/or other causative factors and modules 214a can include any or all of this information in the alert message.

In some embodiments, after matching the detected pattern to one or more known patterns, transient analysis module 214a can identify one or more conditions related to the detected pattern of electrical discharge activity and/or known patterns of electrical discharge activity. As can be appreciated, the identified conditions can be used to enhance the alert message provided to the homeowner/mitigation service, and assist in more precisely determining a potential cause of the discharge. For example, the detected pattern may match a known pattern relating to power supply arcing. Module 214a can further identify that the detected pattern most often occurs at 8:00 am. Module 214a correlates this timestamp with the detected pattern of electrical discharge activity, and alert generation module 214b can include the timestamp information in an alert message. The timestamp information provides the homeowner with additional context regarding the power supply arcing issue and may lead the homeowner to perform specific investigative steps to confirm the arcing. For example, the homeowner may start his or her work day each morning at 8:00 am by turning on a computer connected to the power supply. With knowledge of a) the power supply arcing and b) the timestamp, the homeowner can quickly isolate the behavior of turning on the computer as generating the arcing issue and determine that the computer power supply is likely to blame.

In some embodiments, a detected pattern may not match any of the known hazardous activity patterns. In this case, transient analysis module 214a can transmit the detected pattern to a remote computing device (not shown)—such as a system analyst device—for visual presentation of the detected pattern to a user. The user can analyze the detected pattern to determine whether the pattern indicates or suggests a hazard event and/or a risk of fire (or at least requires further physical investigation with the homeowner to confirm or rule out). The remote computing device can transmit the decision made by the user to transient analysis module 214a for classification of the detected pattern. When the user determines that the detected pattern is indicative of a hazard event or risk of fire, module 214a can store the detected pattern in database 216 and in some cases, use the detected pattern for comparison and analysis of subsequent electrical activity patterns-thereby producing a self-learning feature for fire detection. Alternatively, when the user determines that the detected pattern is not indicative of a hazard event (e.g., risk of fire), transient analysis module 214a can discard the detected pattern or store the identified pattern in database 216. In another example, if the detected pattern does not match any of the known arcing patterns, module 214a can continue by rejecting or discarding the detected pattern as a false positive hazard event.

It should be appreciated that given the nature of electrical fire precursors-small, hidden, and persistent once they start—it is not enough to indicate to a homeowner via an alert message that a hazard exists. In some embodiments, a mitigation service or operations team can receive the alert message and automatically contact the homeowner to coordinate a plan to identify the source of the problem and mitigate the risk. Typically, the fire risk is not imminent. In many cases, however, the analysis performed by system 200 has revealed a definitive cause type, supplying the homeowner and mitigation service with key information and shaping their discussion to isolate the source. Most homeowners are able to provide some contextual value to isolate further- or even outright identify—the precise cause of the arcing event(s). Therefore, the benefits and advantages of the technology described herein become apparent-enabling the ability to automatically detect fire precursor activity in an electrical system, categorize and classify the activity according to a potential or predicted risk of fire, and proactively coordinate with the homeowner, utility, and/or service professionals to remediate the problem well before any danger to life or property has arisen.

Once a hazard is detected, system 200 can be configured to assist the homeowner and/or representatives at the mitigation service to initiate a troubleshooting process in order to locate, mitigate, and/or remediate the hazard. Advantageously, the troubleshooting process provides for active customer engagement with suggested actions that are specific to the hazard detected by system 200 (as described above).

In addition, the troubleshooting process enables multiple different interfaces for a customer to perform the troubleshooting. As can be appreciated, a customer may wish to go through troubleshooting steps on their own prior to talking to a support representative at the mitigation service or a customer may wish to perform troubleshooting steps at a time when a support representative is unavailable (e.g., after normal business hours). Also, some troubleshooting steps require the customer to perform an action (e.g., inspect outlets or cords, turn on/off lights, etc.) and for the system 200 to get feedback on any changes that are seen to the electrical activity after the customer action. Beneficially, the troubleshooting process described herein provides both automated and assistive experiences so that fire hazards can be quickly and/or expertly addressed as needed.

Alert generation module 214b of server computing device 214 is configured to initiate the automated troubleshooting process with the customer when a hazard is detected. In some embodiments, all or part of the functionality of alert generation module 214b can be located on a computing device that is remote from server computing device 214 (e.g., a computing device configured to communicate directly with a mitigation service). In some embodiments, module 214b can be programmed with, e.g., one or more decision tree algorithms that uses characteristics and features of the electrical activity detected by the system 200 (and, in some cases, other data associated with the hazard) to determine responsive steps-including but not limited to, a) requesting additional information from the customer, b) instructing the customer to perform an action, and/or c) conducting further analysis of the hazard data- and continue the traversal of the decision tree algorithm to arrive at a resolution of the hazard. Generally, a decision tree comprises a plurality of nodes arranged in a hierarchical structure where each node represents a decision point. The nodes are connected via parent-child relationships, such that output from a parent node determines which child node is the next decision point to traverse. In some embodiments, each node on the decision tree comprises the following components:
1. Node input requirements (typically based on output from a parent node);
2. Electrical activity information input (as detected and analyzed by system 200)—e.g., arcing signal type, correlation with other device signals and/or external signals such as weather;
3. An action to be taken by the customer—e.g., a question that needs to be answered, instructions to perform an action in the home;
4. A response from the customer—e.g., an answer to a question, an acknowledgment that the action was performed; and
5. Action complexity level—e.g., can the action be completed by the customer or is someone with more specialized training/experience needed (such as an electrician).

Generally, upon evaluating a given node in the decision tree and generating an output, the decision on which child node to execute next is based on the best match of the output to the input requirements of the available child nodes. For example, when the parent node asks the customer a simple question such as “Have you experienced flickering lights?”, the decision tree may include multiple child nodes each based on expected answers such as “Yes,” “No,” or “I don't know.” If the customer answers “yes,” then the decision tree is traversed to the child node with the “yes” input requirement and that node is executed next.

Other cases may not be so easy to resolve. For example, the customer action may be to turn on a specific appliance. The child nodes are executed when the customer acknowledges they have performed the action, but the input to those child nodes may be some signal output from the hazard detection algorithms as executed by system 200. For example, the algorithm output may provide an arcing probability output. Each of three child nodes may include three ranges of arcing probabilities e.g., if the arcing probability is greater than 90%, then execute the child node which concludes that the source of the arcing has been found. If the arcing probability is less than 30%, then execute the child node which rules out that appliance as an issue. If the arcing probability is between 30% and 90%, then execute the child node which asks the customer to move the appliance to a different outlet.

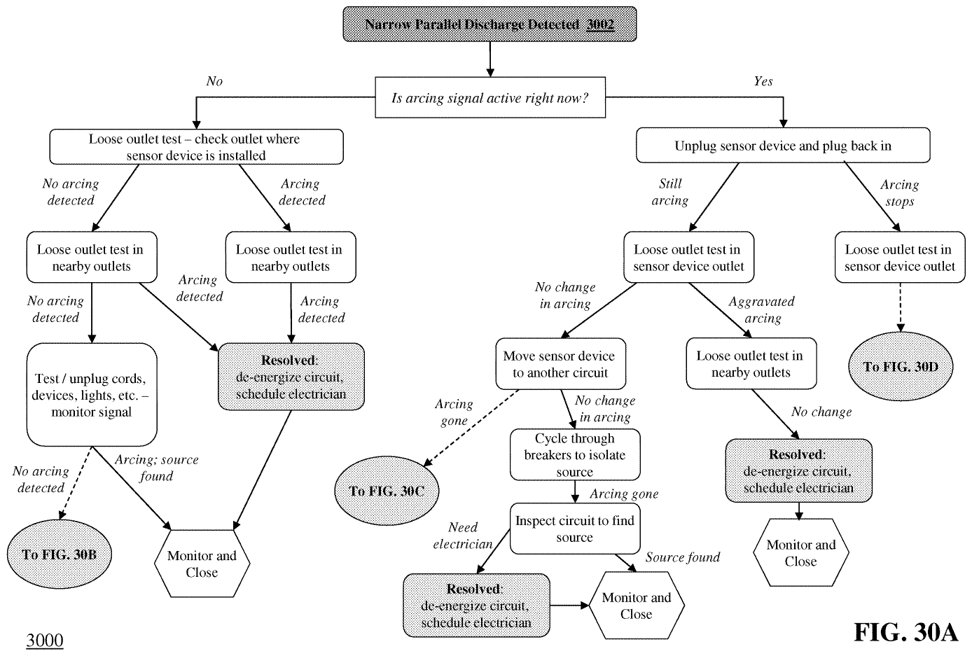

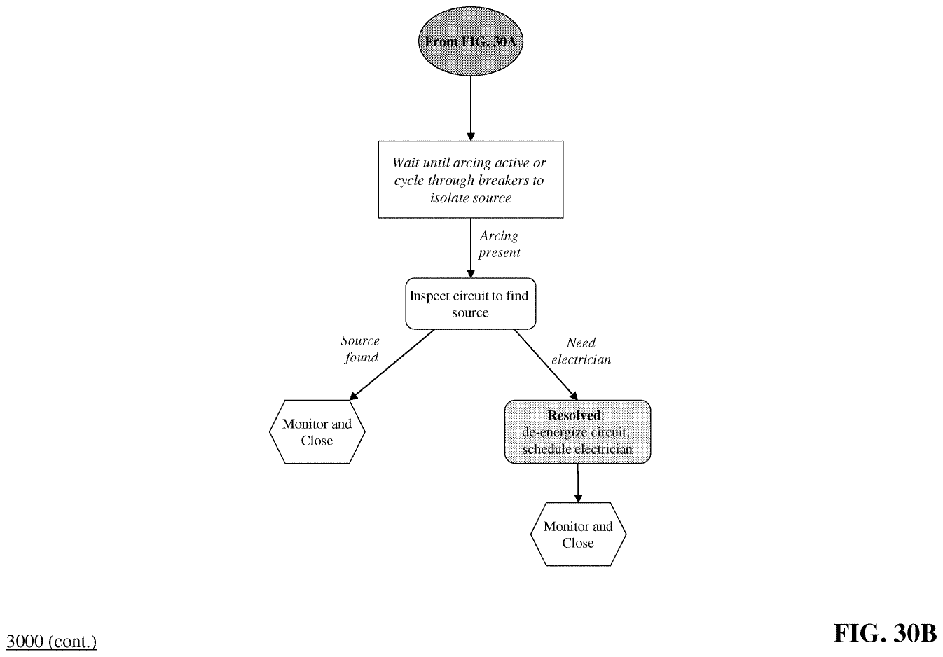

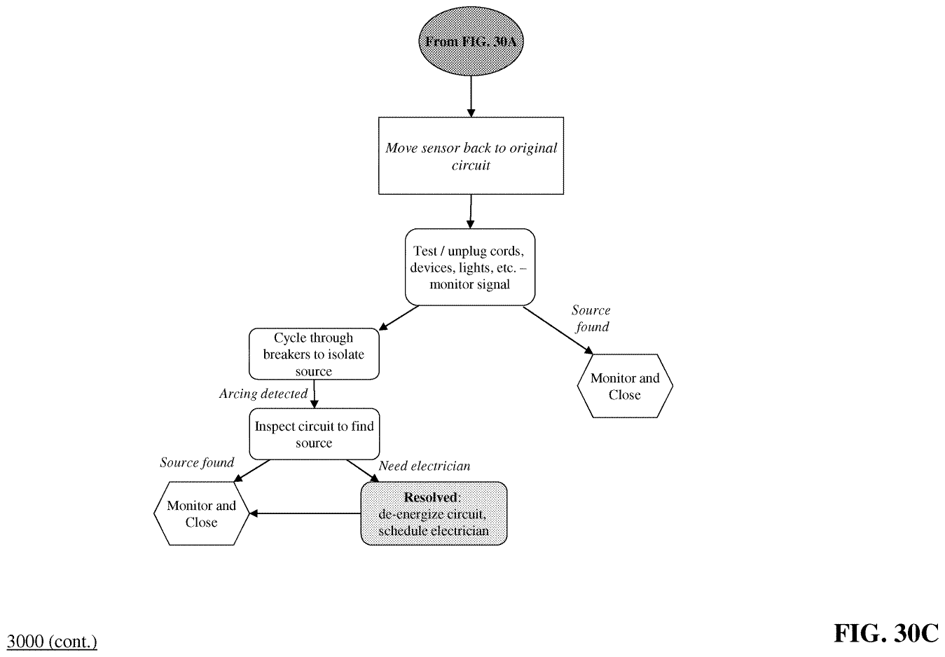

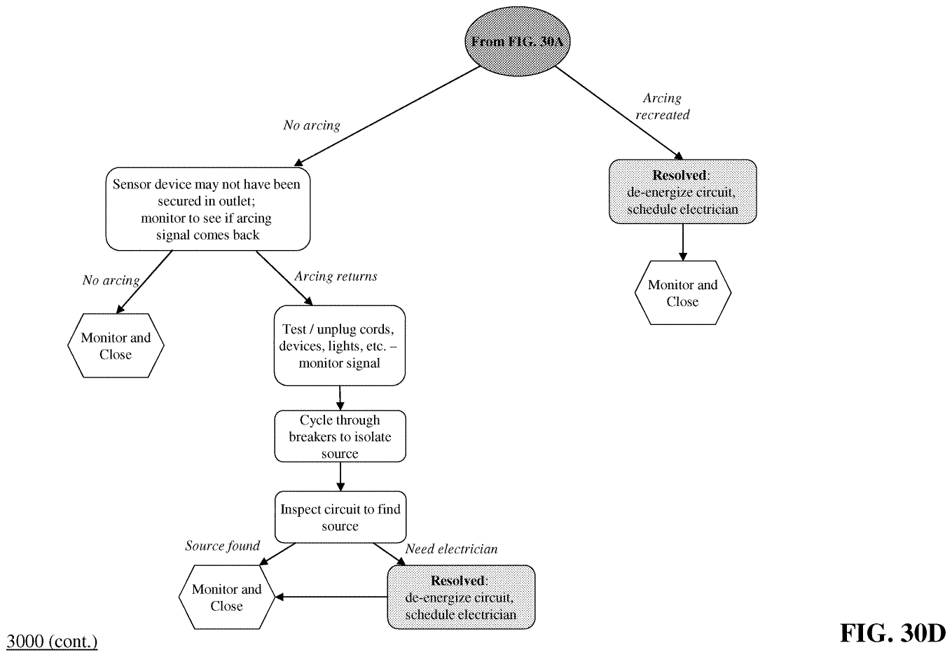

FIGS. 30A-30D comprise a diagram of an exemplary decision tree algorithm 3000 for troubleshooting a narrow parallel discharge detected by system 200. As shown in FIG. 30A, the decision tree algorithm 3000 includes a root node 3002 that is activated when system 200 detects a narrow parallel discharge occurring based on analysis of the electrical activity data described above. Alert generation module 214b of server computing device 214 can step through the nodes of decision tree algorithm 3000 depicted in FIGS. 30A-30D and communicate with a computing device of the customer/service representative at each node, including: instructing the customer to perform certain actions, analyzing the electrical activity signal received from sensor device 204, and/or asking questions of the customer, in order to make a decision and generate output to proceed to the next node in the algorithm 3000.

In some embodiments, server computing device 214 can comprise a virtual assistant application (e.g., chatbot, interactive service application) that uses the hazard information collected from sensor device 214 and analyzed by transient analysis module 214b, and a decision tree algorithm identified by alert generation module 214b in response to the hazard information, to initiate an automated conversation with the customer via an application installed on the customer's computing device (e.g., a mobile device or smartphone). For example, the virtual assistant application can utilize the decision tree to generate prompts for display to the customer in order to solicit responses from the customer and ask the customer to perform certain actions as part of traversing the decision tree to reach a resolution. In some embodiments, the virtual assistant application can utilize a generative natural language model (such as ChatGPT™ available from OpenAI, Inc.) to conduct the conversation with the customer. In certain circumstances, the virtual assistant application can reach a node in the decision tree algorithm where there is not a matching child node for the output generated at the current node. In this case, the virtual assistant can automatically connect a live service representative to the conversation to assist the customer. Beneficially, the live service representative can immediately continue with traversal of the currently active decision tree algorithm at the point where the virtual assistant application handed off the conversation. In addition, because the specialized troubleshooting steps and decision points are fully integrated into the decision tree, such live service representatives do not need to have specific knowledge or expertise in a given technical area in order to perform simple troubleshooting with the customer. Furthermore, by tracking interactions with the customer and the resulting decision tree steps which arrive as a resolution for electrical hazards, system 200 can continually update the decision tree algorithms with improved nodes and pathways, which leads to faster resolution times and more effective outcomes.

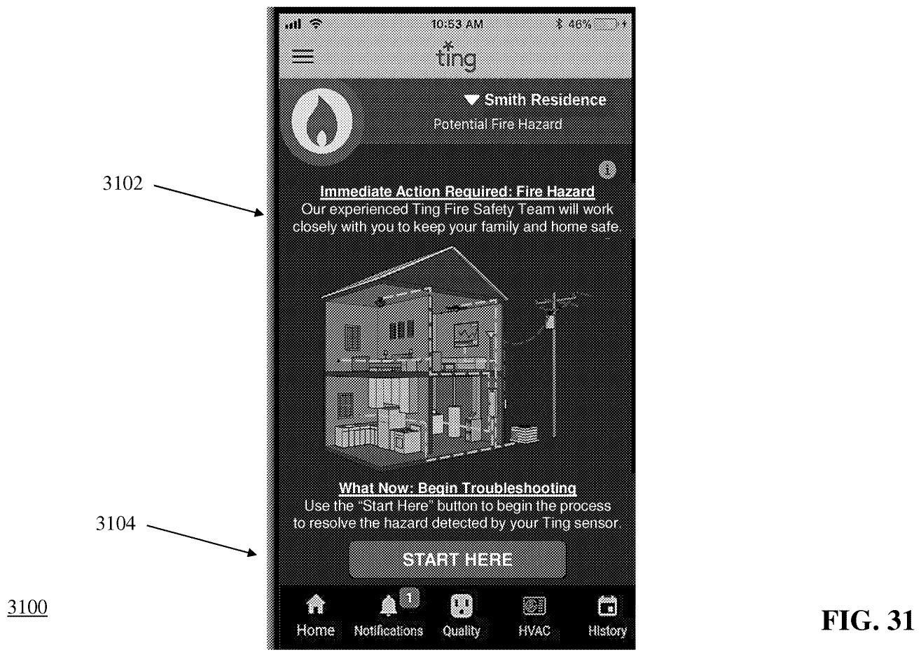

FIG. 31 is a diagram of an exemplary user interface 3100 for alerting a customer of a fire hazard detected by system 200. As shown in FIG. 31, the user interface 3100 includes a message 3102 indicating that a fire hazard is detected at the customer's residence and prompting the customer to begin the troubleshooting process. For example, the customer can select the “Start Here” button 3104—which instructs the alert generation module 214b to identify a particular decision tree algorithm that is related to the specific fire hazard that was detected and to initiate traversal of the decision tree algorithm to help the customer locate, mitigate, and/or remediate the hazard.

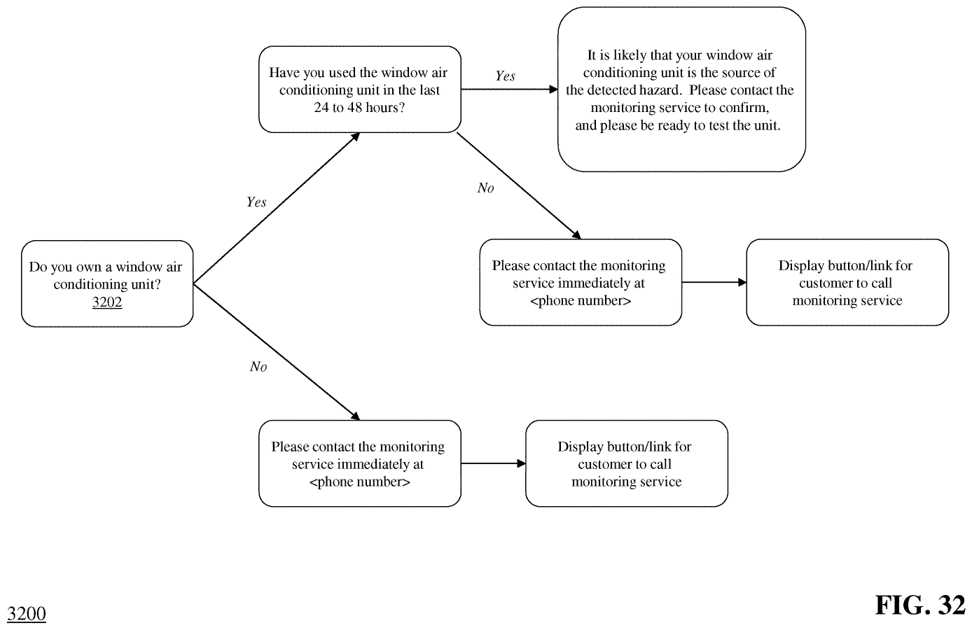

Also, it should be appreciated that system 200 can leverage the known electrical activity pattern database (as described previously) in order to streamline the troubleshooting process by selecting a decision tree algorithm that is customized to one or more specific electrical activity patterns. FIG. 32 is a diagram of an exemplary decision tree algorithm 3200 for troubleshooting a hazard using a detected electrical activity pattern that matches a known hazardous electrical discharge pattern. As shown in FIG. 32, the algorithm 3200 relates to a detected electrical activity pattern that matches a known hazard pattern associated with a window air conditioning unit. As can be understood, this is merely one example of a device signature, and this methodology is applicable to any number of different electrical discharge activity patterns detectable by system 200.

After system 200 detects the hazardous activity pattern, alert generation module 214b begins the decision tree at the root node 3202 by asking the customer if they own a window air conditioning unit. Depending upon the customer's response, module 214b traverses the decision tree to either instruct the user to contact the mitigation service for further assistance or ask additional questions to narrow down the potential cause of the hazardous activity.

As described above, system 200 is capable of identifying multiple categories of electrical discharge activity. In some embodiments, system 200 further implements an AI-based threat detection subsystem that consolidates outputs from a plurality of specialized hazard detection models together with contextual data to generate a prioritized, composite threat assessment for each sensor device 204, and/or logical or physical group(s) of sensor device(s), in the network.

As mentioned previously, the term “threat” as used herein refers to any condition, event, or pattern of activity detected by the system that indicates an elevated likelihood of harm, damage, or hazardous outcomes at a monitored location. In some embodiments, a threat comprises an electrical fire hazard arising from electrical discharge activity in electrical wiring, including but not limited to arc faults, glowing connections, carbonization of insulation, and other conditions that may precede or cause an electrical fire. In other embodiments, a threat may encompass other categories of hazardous conditions detectable from electrical waveform data or other sensor data, including but not limited to power quality hazards, equipment failure conditions, or other electrical or environmental conditions that pose a risk to persons, property, or electrical infrastructure. The term “threat” is not limited to conditions that have been confirmed as genuine hazards, and may encompass candidate conditions that have been assigned a probability score above a predetermined threshold by one or more of the specialized hazard detection models described herein. As used herein, a “composite threat score” represents a unified quantitative assessment of the likelihood and severity of one or more such threats at a monitored location, as generated by the threat assessment subsystem described herein. The foregoing examples are illustrative and non-limiting, and the methods and systems described herein may be adapted to detect and assess threats of other types without departing from the scope of the technology.

It should be appreciated that the threat detection subsystem may be implemented in different ways depending upon the architecture of the system 200 and the computational resources available. In some embodiments, the threat detection subsystem is implemented entirely within transient analysis module 214a (or other module(s)) of the server computing device 214, such that all hazard signal aggregation, machine learning inference, and threat score generation are performed by transient analysis module 214a using data received from the sensor devices 204 via the network 212. This server-side implementation is advantageous where the machine learning models employed by the threat detection subsystem are computationally intensive, where the threat detection subsystem draws upon data aggregated from a plurality of sensor devices 204 deployed across multiple locations, and/or where frequent model updates are required—as server-side deployment allows updated models to be deployed centrally without requiring firmware updates to individual sensor devices 204.

In other embodiments, all or a portion of the threat detection subsystem is implemented within the processing module 204a (or other module(s)) of sensor device 204 itself. In such embodiments, the sensor device 204 comprises a processor and memory sufficient to execute one or more of the specialized hazard detection models and, in some cases, a lightweight version of the threat score generation model, locally on the sensor device 204—enabling the sensor device 204 to generate a local threat assessment without requiring continuous communication with the server computing device 214. This edge-based implementation may be advantageous where network connectivity is intermittent or unavailable, where low-latency threat detection is required, or where it is desirable to minimize the volume of raw waveform data transmitted over the network 212.

In some embodiments, a hybrid implementation is employed in which computationally lighter detection tasks-such as initial candidate event detection and fast filtering—are performed locally on the sensor device 204, while more computationally intensive tasks-such as false positive rejection using gradient boosted tree classifiers and composite threat score generation—are performed by the server computing device 214 using features or intermediate results transmitted by the sensor device 204.

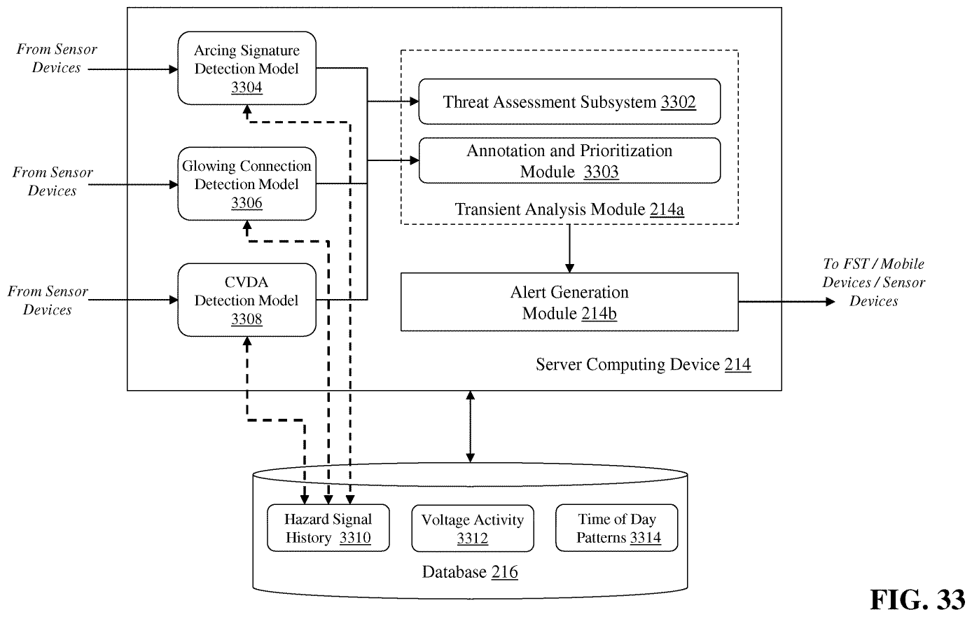

In other embodiments, all or a portion of the threat detection subsystem is implemented within the processing module 204a (or other module(s)) of sensor device 204 itself, or in a hybrid configuration in which certain detection tasks are performed locally on the sensor device 204 while more computationally intensive tasks are performed by the server computing device 214. These alternative implementations are described in further detail below with respect to FIG. 33.

Generally and without limitation, the threat detection subsystem aggregates outputs from a plurality of specialized AI-based hazard detection models, each of which is configured to identify a distinct category of hazardous electrical activity based upon characteristic features of the waveform data collected by the sensor devices 204. In some embodiments, each specialized hazard detection model is trained according to the particular signal signature associated with its target hazard type, employing a combination of signal processing techniques, statistical analysis, and machine learning algorithms to distinguish genuine hazard events of that type from benign electrical activity and false positives. In some embodiments, the specialized hazard detection models are configured to operate in parallel, each processing the same underlying waveform data or summarized sensor data independently, such that multiple hazard types may be detected simultaneously from a single stream of sensor data. The outputs of the specialized detection models-which may include binary hazard indicators, continuous probability scores, or feature vectors characterizing detected candidate events—are provided to the threat detection subsystem as inputs to the composite threat score generation process described above. In this way, the threat detection subsystem is capable of recognizing hazard scenarios that may involve multiple overlapping hazard types, or that may not be conclusively identified by any single specialized model acting alone, by synthesizing evidence across the full suite of specialized detection models. In some embodiments, the continuous monitoring function of the threat assessment subsystem 3302 employs two complementary and parallel analytical approaches to identify sensor devices warranting escalation. The first approach applies image recognition techniques, including the convolutional neural network-based image classification methods described above with respect to FIGS. 27-29, to the two-dimensional visualizations of electrical discharge activity patterns generated from the waveform data collected by the sensor devices 204, enabling the threat assessment subsystem 3302 to identify spatial and structural patterns in the discharge activity that are characteristic of known hazardous electrical conditions. The second approach applies temporal pattern recognition techniques to the time-series of composite threat scores, detection model probability scores, and voltage activity measurements associated with each sensor device 204, enabling the threat assessment subsystem to identify trends, recurrences, and anomalies in the sensor device's hazard activity history over time that may not be apparent from analysis of any single analysis window in isolation. In some embodiments, the outputs of both the image recognition and temporal pattern recognition approaches are provided as inputs to the machine learning model of the threat assessment subsystem, enabling the composite threat score to reflect both the structural characteristics of the detected discharge activity patterns and their temporal evolution over time

In some embodiments, the specialized hazard detection models share a number of common architectural features. For example, each model can receive as input a summary of the waveform data collected by one or more sensor devices 204 over a preceding time window-such as the previous hour of data—as prepared by transient analysis module 214a of server computing device 214. Each model can apply a multi-stage detection pipeline in which an initial, computationally efficient filtering stage rapidly eliminates candidate events that are clearly inconsistent with the target hazard type, and one or more subsequent stages apply progressively more sophisticated and computationally intensive analyses to the surviving candidate events to confirm genuine hazard events and reject false positives. Each model can also incorporate a machine learning-based false positive rejection stage—in some embodiments implemented using a gradient boosted tree classifier such as XGBoost—that is trained on labeled historical data comprising confirmed hazard events and confirmed non-hazard events, and that generates a probability score quantifying the likelihood that a given candidate event represents a genuine hazard of the target type. Additionally, each model is designed to account for external confounding factors-such as utility grid disturbances and atmospheric events—that may produce electrical signatures resembling those of the target hazard type, by querying external data sources and filtering candidate events whose timing coincides with known confounding events. Three non-limiting examples of such specialized hazard detection models are described in detail below: a coincident voltage dip and arcing (CVDA) detection model, a glowing connection (GC) detection model, and an arcing signature (AS) detection model. It should be appreciated that these model types are exemplary, and the threat assessment subsystem can be configured to utilize other types of specialized hazard detection models without departing from the scope of the technology described herein.

FIG. 33 is a block diagram of an artificial intelligence-based threat assessment subsystem 3302 for identifying and prioritizing severe fire risks by aggregating outputs from a plurality of specialized hazard detection models. As shown in FIG. 33, the threat assessment subsystem 3302 is implemented within transient analysis module 214a of server computing device 214. It should be appreciated, however, that this represents one embodiment of the system 200, and that in other embodiments all or a portion of the threat assessment subsystem 3302 may be implemented within the sensor device 204 itself. In such embodiments, the sensor device 204 comprises a processor and memory sufficient to execute one or more of the specialized hazard detection models-such as the arcing signature detection model 3304, the glowing connection detection model 3306, and/or the CVDA detection model 3308—and, in some cases, a lightweight version of the composite threat score generation model, locally on the sensor device 204. This edge-based implementation enables the sensor device 204 to perform at least a portion of the threat assessment process without requiring continuous communication with the server computing device 214, which may be advantageous where network connectivity between the sensor device 204 and the server computing device 214 is intermittent or unavailable, where low-latency local threat detection is required, or where it is desirable to reduce the volume of raw waveform data transmitted over the network 212. In some embodiments, a hybrid implementation is employed in which computationally lighter detection tasks (such as initial candidate event detection and fast filtering as performed by one or more of the specialized detection models) are executed locally on the sensor device 204, while more computationally intensive tasks (such as false positive rejection and composite threat score generation) are performed by the threat assessment subsystem 3302 executing on the server computing device 214 using features or intermediate results transmitted by the sensor device 204 via the network 212. In any of the foregoing implementations, the threat assessment subsystem 3302—whether executing on the server computing device 214, the sensor device 204, or both—may be updated over time by distributing updated model parameters or firmware to the sensor devices 204 and/or by updating the models executing on the server computing device 214, consistent with the continuous learning and model improvement process described herein. It should further be appreciated that the embodiment depicted in FIG. 33, in which the specialized detection models 3304, 3306, and 3308 are shown within the server computing device 214, represents a server-side implementation of the threat assessment subsystem 3302. In embodiments in which all or a portion of the detection models are implemented on the sensor devices 204, the architecture of FIG. 33 would be modified accordingly, with some or all of the detection model processing occurring at the sensor device 204 prior to transmission of results to the server computing device 214.

As shown in FIG. 33, database 216 comprises three categories of data that are used by the threat assessment subsystem 3302 to generate the composite threat score for each sensor device 204 in the network: hazard signal history data 3310, voltage activity data 3312, and time-of-day pattern data 3314.

The hazard signal history data 3310 comprises a time-series record of the outputs generated by the specialized hazard detection models 3304, 3306, and 3308 for each sensor device 204 in the network over a preceding time period (e.g., days, weeks, or months) of sensor activity. For each analysis window processed by each of the specialized detection models, the hazard signal history data 3310 stores one or more of: the probability scores generated by each of the specialized detection models for that window; binary indicators specifying whether a candidate hazard event of each type was detected during that window; the characterization features associated with any confirmed candidate events, including transient amplitude ratios, exponential decay fit parameters, and coincidence detection outputs as applicable to each model; the severity classification of any confirmed hazard events; and the outcome of any fire safety team (FST) review or customer engagement associated with confirmed hazard events, including whether a genuine hazard was ultimately identified and the nature of the hazard.

The fire safety team (FST) is a human review body comprising case managers responsible for evaluating escalated sensor cases generated by the threat assessment subsystem. In some embodiments, FST members operate computing devices through which they access a case review interface presenting the composite threat score, specialized detection model outputs, hazard characterization flags, heatmap visualizations, automated annotations, categorical tags, and level transition history associated with each escalated sensor device.

The FST's review process can comprise a plurality of sequential steps. First, a sensor device is entered into the FST review queue when its composite threat score meets or exceeds the configurable escalation threshold (the “ready-to-engage” determination). Second, the assigned FST case manager performs a case readiness determination-evaluating the structured case readiness summary to decide whether the available evidence is sufficient to initiate active customer engagement, including contact with the homeowner and coordination of guided troubleshooting, and hazard mitigation and/or remediation with electricians or other service professionals.

The outcome of FST review (including whether a genuine hazard was ultimately identified and the nature of that hazard) is recorded in the hazard signal history data and written back to the system to serve as labeled training examples for continuous improvement of the machine learning models employed by the threat assessment subsystem. Advantageously, the FST functions not only as a human oversight layer in the escalation pipeline, but also as a feedback mechanism that closes the loop between field-confirmed hazard outcomes and ongoing model training.

Over time, the accumulation of hazard signal history data 3310 for a given sensor device 204 enables the threat assessment subsystem 3302 to identify trends in hazard activity at the monitored location—such as an increasing frequency or severity of detected events, a pattern of events occurring in recurring clusters, or a progression from lower-severity to higher-severity hazard indicators—and to weight the composite threat score accordingly. In some embodiments, the hazard signal history data 3310 also serves as the primary source of labeled training examples used to train and update the machine learning model employed by the threat assessment subsystem 3302, as confirmed hazard outcomes reported by the FST are written back to the hazard signal history data 3310 and incorporated into subsequent model training cycles.

The voltage activity data 3312 comprises a time-series record of the voltage activity measurements collected by each sensor device 204 over a preceding time period. In some embodiments, the voltage activity data 3312 includes, for each voltage cycle or predetermined time interval within the observation period, one or more of: the RMS voltage of the cycle or interval; the peak voltage amplitude; the transient amplitude ratio computed across the cycle; the count and amplitude of candidate transient events detected within the cycle; and indicators of any voltage quality events (such as sags, surges, or brownouts) detected during the interval. The voltage activity data 3312 enables the threat assessment subsystem 3302 to characterize the baseline electrical environment of the location monitored by each sensor device 204 and to identify deviations from that baseline that may be indicative of developing hazard conditions. For example, a gradual and sustained decrease in RMS voltage over multiple successive hours may indicate the presence of a developing glowing connection at the monitored location, even in the absence of a confirmed detection event from the GC detection model 3306. Similarly, an increasing trend in transient amplitude ratios stored in the voltage activity data 3312 over time may indicate a worsening arcing condition that has not yet reached the detection threshold of the AS detection model 3304. By incorporating voltage activity data 3312 into the composite threat score, the threat assessment subsystem 3302 is able to identify and escalate developing hazard conditions at an earlier stage than would be possible using the outputs of the specialized detection models alone.

The time-of-day pattern data 3314 comprises a structured record of the temporal patterns associated with the electrical discharge activity and voltage activity detected at each sensor device location, organized by time of day and, in some embodiments, by day of week and season. In some embodiments, the time-of-day pattern data 3314 is generated by analyzing the hazard signal history data 3310 and voltage activity data 3312 for each sensor device 204 to identify recurring patterns of electrical activity that are consistently associated with particular times of day-such as a recurring elevation in transient activity each morning when a specific appliance is switched on, or a recurring voltage dip at a consistent time each afternoon correlated with peak demand on the utility grid. By storing and analyzing these temporal patterns, the threat assessment subsystem 3302 is able to distinguish recurring, time-correlated electrical activity-which may be attributable to known device behavior or external grid conditions and therefore may not represent a genuine hazard—from anomalous activity that does not conform to the established temporal patterns of the location and is therefore more likely to indicate a genuine and developing hazard condition. In some embodiments, the time-of-day pattern data 3314 is also used by the threat assessment subsystem 3302 to adjust the sensitivity of hazard detection at particular times of day. For example, a lower detection threshold may be applied during nighttime hours when the risk of an undetected electrical fire causing harm is elevated due to the reduced likelihood that occupants of the monitored building will be awake and able to respond to a fire.

Also shown in FIG. 33, the threat assessment subsystem 3302 receives inputs from a plurality of specialized hazard detection models 3304, 3306, and 3308 that operate on waveform data collected from the sensor devices 204. Each of these specialized detection models 3304, 3306, and 3308 analyzes the sensor waveform data to detect a particular category of hazardous electrical activity, as described in detail below, and transmits the output of its analysis to the threat assessment subsystem 3302. In some embodiments, the output transmitted by each specialized detection model to the threat assessment subsystem 3302 comprises one or more of: a binary hazard indicator specifying whether a hazard event of the model's target type was detected during the most recent analysis window; a continuous probability score quantifying the likelihood that the detected activity represents a genuine hazard of the target type; one or more characterization features describing the nature and severity of the detected activity, such as the amplitude, frequency, duration, and phase distribution of detected transient events; and/or a count or rate of hazard candidate events identified within the analysis window. As shown in FIG. 33, each of the specialized detection models 3304, 3306, and 3308 also communicates bidirectionally with the database 216, retrieving data required for its detection processing (such as libraries of known hazardous electrical discharge activity patterns used by the arcing signature detection model 3304, known waveform characteristics used by the glowing connection detection model 3306, and trained classifier model parameters used by each of the specialized detection models) as indicated by the dashed arrows between the database 216 and the detection models in FIG. 33. In some embodiments, the known waveform characteristics associated with glowing connection events are represented as shapelet templates derived from labeled training data comprising confirmed glowing connection events.

In some embodiments, the outputs of the specialized detection models 3304, 3306, and 3308 are provided not only to the threat assessment subsystem 3302 but also to an automated annotation and prioritization module 3303. The automated annotation and prioritization module 3303 performs three distinct functions with respect to each confirmed candidate hazard event generated by the specialized detection models 3304, 3306, 3308. First, module 3303 annotates each confirmed candidate hazard event with structured metadata derived from the outputs of the specialized detection models, including the hazard type, the probability score generated by the relevant detection model, the characterization features associated with the confirmed event, and the timestamp and sensor device identifier associated with the event. The automated annotations can be stored in the hazard signal history data 3310 of the database 216 and the annotations are surfaced to FST reviewers as part of the case review interface described herein, enabling reviewers to rapidly assess the nature and severity of the detected hazard activity without having to interpret raw waveform data or model outputs directly. In some embodiments, the automated annotation function further assigns one or more structured categorical tags to each confirmed candidate hazard event and to the sensor device 204 with which the event is associated. In some embodiments, the categorical tags are derived from the outputs of the specialized detection models 3304, 3306, and 3308 and the threat assessment subsystem 3302, and characterize one or more of: the type of hazardous electrical activity detected; the severity and confidence level of the detection; the pattern of prior hazard activity at the sensor device location; and the recommended escalation action associated with the detected event. In some embodiments, the categorical tags are displayed to FST reviewers in the case review interface as color-coded visual indicators associated with each sensor case in the review queue, enabling reviewers to rapidly assess the nature and severity of each case without reading the full case detail. In some embodiments, the set of available categorical tags is configurable by an operator of the system 200 and may be updated over time as new hazard types are identified and new detection models are developed and deployed.

Second, module 3303 can automatically promote certain confirmed candidate hazard events to a heightened escalation status, thereby bypassing the configurable composite threat score threshold mechanism of the threat assessment subsystem 3302, when the probability score generated by one or more of the specialized detection models meets or exceeds a predetermined threshold. In some embodiments, the threshold is set independently for each of the specialized detection models 3304, 3306, and 3308, reflecting the differing specificities and false positive rates of each model's detection pipeline. For example, a confirmed CVDA candidate event that has survived both false positive rejection and grid event and lightning filtering stages and has been assigned a very high probability score by the CVDA detection model 3308 may be automatically promoted to the highest escalation tier without requiring computation of the composite threat score by the threat assessment subsystem 3302, reflecting the high specificity of the CVDA detection pipeline and the severity of the fire risk associated with confirmed CVDA events. In some embodiments, automatically promoted events are flagged in the review queue with a visual indicator distinguishing them from events escalated through the composite threat score threshold mechanism, enabling FST reviewers to immediately identify and prioritize the most time-sensitive cases.

Third, module 3303 can populate a structured manual review queue of sensor cases that do not meet the threshold but for which the outputs of one or more of the specialized detection models suggest that human review may be warranted. In some embodiments, the criteria for inclusion in the manual review queue are configurable and may include one or more of: a probability score generated by any of the specialized detection models that meets or exceeds a predetermined manual review threshold lower than the threshold; the detection of a confirmed candidate event of a hazard type that has previously been confirmed as a genuine hazard at the same sensor device location; or the detection of confirmed candidate events by two or more of the specialized detection models within the same analysis window. Sensor cases in the manual review queue are presented to FST reviewers alongside automated annotations and hazard characterization flags as described herein, enabling reviewers to efficiently triage and prioritize the queue and determine which cases warrant active customer engagement.

The arcing signature detection model 3304 performs the arcing detection and transient signal analysis functions described above with respect to FIGS. 5, 6A-6C, 7A-7C, 8A-8C, 9, 10, 19, 20, and 27-29. As described in detail in those sections, arcing signature detection model 3304 identifies transient signals within the voltage waveform data collected by the sensor devices 204, generates transient characteristics based upon the identified transient signals, and analyzes those characteristics (including through the computation of the transient amplitude ratio and the phase distribution of transient activity across the voltage cycle) to identify electrical discharge indications in the waveform data. In some embodiments, arcing signature detection model employs one or more of Methods A, B, and C as described above with respect to FIGS. 6A-6C to perform transient identification and characterization. In some embodiments, the Arcing Signature Detection Model 3304 further performs the multi-cycle pattern detection and classification functions described above with respect to FIGS. 27-29, including grouping detected electrical discharge activity instances into patterns across a plurality of voltage cycles, generating two-dimensional visualizations of the detected patterns, and comparing the detected patterns against a library of known hazardous electrical discharge activity patterns stored in the database 216 to classify the detected activity. In some embodiments, the output of arcing signature detection model 3304 comprises an arcing probability score and one or more characterization features describing the detected transient activity, which is then provided to the threat assessment subsystem 3302 as described herein.

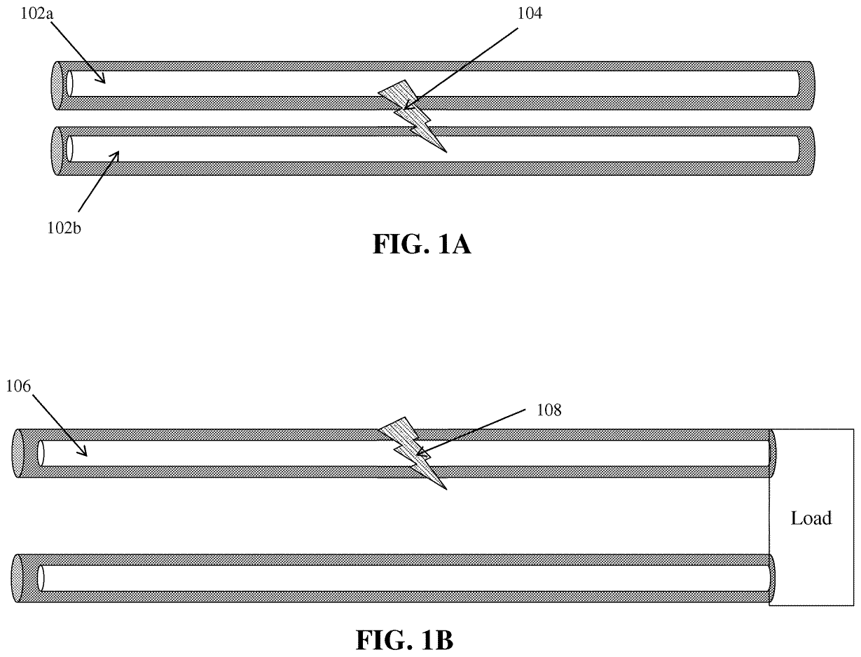

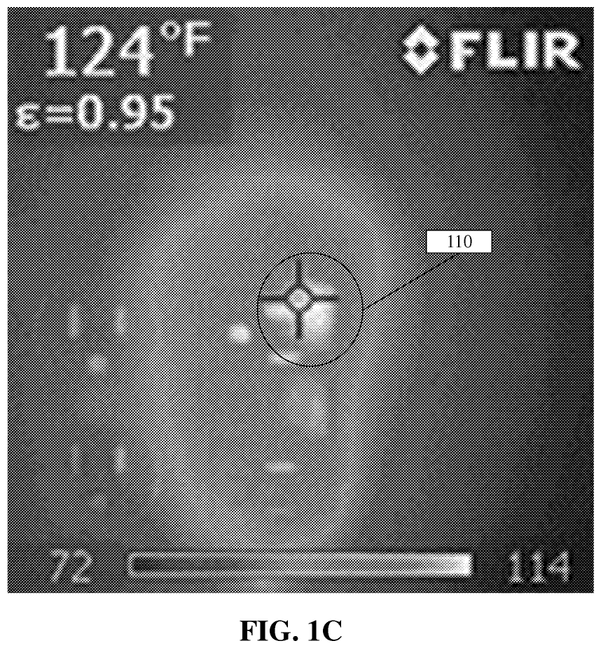

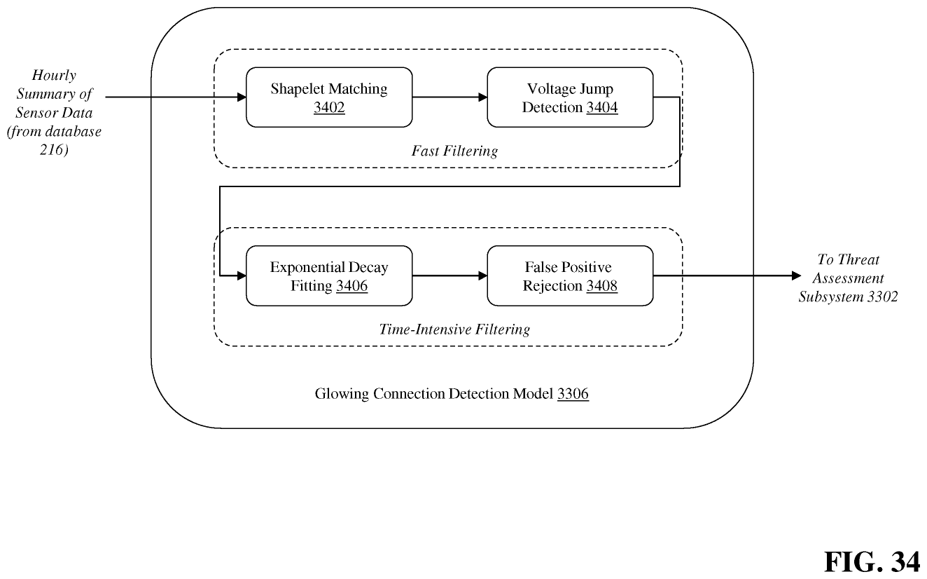

FIG. 34 is a block diagram illustrating the algorithmic processing performed by the glowing connection detection model 3306. As described above with respect to FIG. 1C, glowing connections produce minimal arcing activity and exhibit a characteristic exponential increase in resistance over time, making them difficult to detect using arcing-based methods alone. As shown in FIG. 34, glowing connection detection model 3306 processes hourly summary data received from the sensor devices 204 through a two-stage detection pipeline comprising a fast filtering stage and a time-intensive filtering stage.

In some embodiments, the waveform characteristics matching performed in the fast filtering stage is implemented using a shapelet matching function 3402. It should be appreciated that the shapelet matching function 3402 represents one non-limiting implementation of a waveform characteristics matching approach, and that other techniques for identifying segments of waveform data exhibiting characteristics associated with glowing connection events (including but not limited to template correlation, dynamic time warping, feature-based similarity matching, and machine learning-based pattern recognition) may be substituted without departing from the scope of the technology described herein. In the embodiment depicted in FIG. 34, the shapelet matching function 3402 applies a time-series shapelets analysis technique to the summary data to identify segments of the waveform data that match one or more known waveform characteristics associated with glowing connection events.

As shown in FIG. 34, within the glowing connection detection model 3306, the fast filtering stage comprises a shapelet matching function 3402 and a voltage jump detection function 3404 operating in sequence, and the time-intensive filtering stage comprises an exponential decay fitting function 3406 and a false positive rejection function 3408, also operating in sequence. The input to the glowing connection detection model 3306 is the hourly summary of sensor data retrieved from the database 216, and the output is transmitted to the threat assessment subsystem 3302.

In some embodiments, the hourly summary data generated by each sensor device 204 represents a compressed and structured aggregation of the raw waveform data collected by the sensor device 204 over the preceding one-hour time window. Because each sensor device 204 samples the voltage waveform at up to 27 million samples per second, the raw waveform data generated over one hour is extremely voluminous (on the order of approximately 97 billion raw samples per sensor per hour) and is not transmitted or stored in its entirety. Instead, the sensor device 204 continuously processes the raw waveform data using the transient detection methods described herein and transmits to the server computing device 214 a structured summary of the processed data for each one-hour window. As described previously, the hourly summary data may comprise, for each voltage cycle captured during the one-hour window, one or more of:
the maximum amplitude value for each of the plurality of bins into which the sampled voltage cycle waveform is divided;
the mean amplitude value for each bin;
the difference between the maximum and mean amplitude values for each bin;
the accumulated maximum value for each bin across the preceding fifteen cycles;
the derivative of the accumulated maximum values across the bins;
the computed transient amplitude ratio for the cycle; and
the average transient amplitude for each of the plurality of phase sections within the cycle.

In some embodiments, the hourly summary data may further comprise, for each voltage cycle or for each predetermined time interval within the one-hour window: the root mean square (RMS) voltage of the cycle or interval, computed from the low-speed sampled voltage waveform as described herein; a count of candidate transient events detected within the cycle or interval; and, where Method C sampling has been triggered, the stored waveform samples for any individual transient events that exceeded the floating threshold during the cycle. In some embodiments, the hourly summary data additionally comprises summary statistics computed across all cycles within the one-hour window, including the mean and maximum transient amplitude ratio, the mean and maximum RMS voltage, the count of voltage dip events detected during the window, and a time-series of per-cycle RMS voltage values that enables the specialized detection models to identify trends such as exponential voltage decay indicative of a glowing connection. Because the low-speed sampling path generates RMS voltage measurements independently of the high-speed transient sampling path, the per-cycle RMS voltage time-series is available continuously and is not subject to the data volume constraints associated with the high-speed waveform data

The resulting hourly summary data is substantially more compact than the raw waveform data and is structured to provide each of the specialized hazard detection models, including the arcing signature detection model 3304, the glowing connection detection model 3306, and the CVDA detection model 3308, with the specific feature data required to perform their respective detection analyses, as described herein.

In the fast filtering stage, glowing connection detection model 3306 processes the incoming summary data using a shapelet matching function 3402. The shapelet matching function 3402 applies a time-series shapelets analysis technique to the summary data to identify segments of the waveform data that match one or more known waveform characteristics (e.g., shapelet templates) associated with glowing connection events. In some embodiments, the waveform characteristics are derived from labeled training data comprising confirmed glowing connection events detected in the field or reproduced in laboratory settings. In some embodiments, the waveform characteristics applied by function 3402 are stored in the database 216 and retrieved by the glowing connection detection model 3306 at the time of processing, and are updated over time as additional confirmed glowing connection events are identified and added to a library of known waveform characteristics.

Candidate segments identified by the shapelet matching function 3402 are passed to the voltage jump detection function 3404, which evaluates whether the identified segments contain abrupt, step-wise changes in voltage level consistent with the onset of a glowing connection-such as sudden increases or decreases in RMS voltage not attributable to known device switching events on the circuit. Candidate glowing connection events that survive both the shapelet matching function 3402 and the voltage jump detection function 3404 are passed forward to the time-intensive filtering stage.

In the time-intensive filtering stage, model 3306 applies the exponential decay fitting function 3406 to the candidate glowing connection events. The exponential decay fitting function 3406 attempts to fit an exponential decay function to the RMS voltage measurements observed during each candidate GC event. As described above, a glowing connection is expected to produce a characteristic exponential decay in the measured voltage as the resistance at the connection increases over time. The exponential decay fitting function 3406 evaluates the goodness-of-fit of the exponential decay model to the candidate event data and compares the fit quality against a predetermined threshold, passing forward only those candidate events for which the fit quality meets or exceeds the threshold. As shown in FIG. 34, the output of the exponential decay fitting function 3406 is passed directly to the false positive rejection function 3408 within the time-intensive filtering stage.

Glowing connection detection model 3306 then applies the false positive rejection function 3408 to the remaining candidate GC events—that is, those candidate events that have survived the fast filtering stage and have been confirmed by the exponential decay fitting function 3406 as exhibiting a voltage profile consistent with an exponentially increasing resistance—in order to distinguish genuine hazard events from false positives. In some embodiments, the false positive rejection function 3408 employs a gradient boosted tree machine learning classifier (e.g., XGBoost) trained on a labeled historical dataset comprising confirmed genuine GC events (positive training examples) and confirmed false positive candidate events (negative training examples). In some embodiments, the negative training examples include candidate events generated by other electrical phenomena that may produce a voltage signature superficially resembling a glowing connection (such as the gradual voltage drop associated with a heavily loaded circuit, the exponential voltage recovery following a power quality sag event, or the slow thermal drift in resistance exhibited by certain heating appliances during their warm-up phase) and which therefore may survive the fast filtering and exponential decay fitting stages despite not representing a genuine glowing connection condition. The classifier receives as input a feature vector derived from each surviving candidate event, comprising one or more of: the parameters of the fitted exponential decay function, including the decay rate constant and the initial voltage amplitude; the goodness-of-fit metric generated by the function 3406; the magnitude and duration of any voltage jumps detected by the function 3404; the degree of match between the candidate event waveform and the known GC shapelet waveform characteristics as scored by function 3402; summary statistics derived from the per-cycle transient amplitude ratio and RMS voltage time-series within the analysis window; and any available environmental and contextual features, such as the time of day and recent voltage activity patterns associated with the sensor device 204. Based upon these input features, the classifier generates a probability score for each surviving candidate event, quantifying the likelihood that the event represents a genuine GC hazard. In some embodiments, candidate events with a probability score below a predetermined threshold are rejected as false positives and discarded, while candidate events with a probability score at or above the threshold are confirmed as genuine glowing connection hazard events and their probability scores and characterization features are transmitted to the threat assessment subsystem 3302 as described herein. In some embodiments, the predetermined threshold applied by the function 3408 is configurable and may be adjusted by an operator of the system 200 to balance the sensitivity of GC detection against the false positive rate, consistent with the tunable threshold mechanism described above with respect to the threat assessment subsystem 3302.

In some embodiments, confirmed glowing connection events that remain after processing by the exponential decay fitting function 3406 and the false positive rejection function 3408 are output from the GC detection model 3306 as a GC probability score quantifying the likelihood of a genuine glowing connection condition, together with characterization features including the exponential decay fit parameters, the magnitude of any detected voltage jumps, and the degree of match between the detected waveform and the known glowing connection shapelet waveform characteristics. These outputs are provided to the threat assessment subsystem 3302 for further processing as described herein.

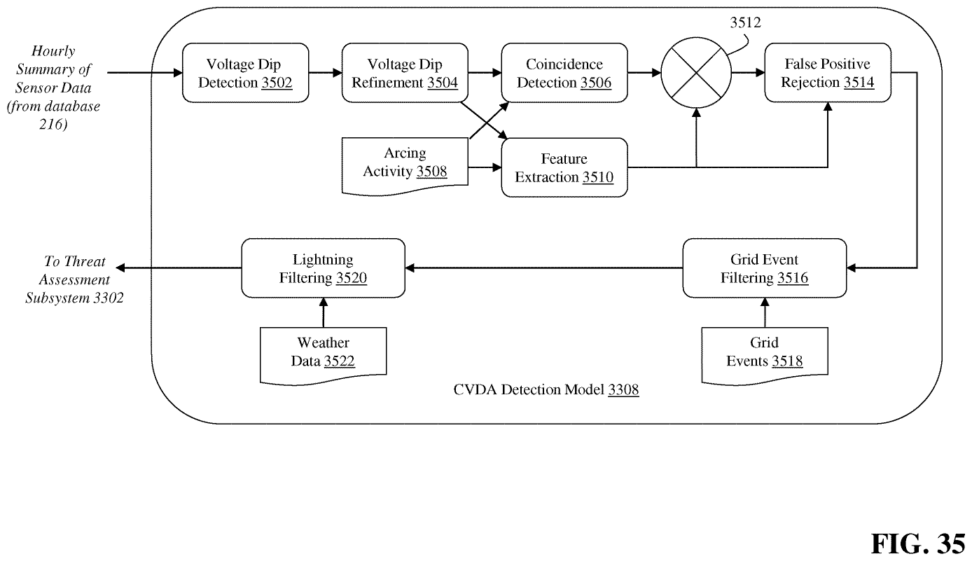

FIG. 35 is a block diagram illustrating the algorithmic processing performed by the CVDA detection model 3308. As described above, the CVDA detection model 3308 is designed to identify a category of highly hazardous electrical discharge event characterized by the temporal coincidence of a significant voltage dip and a concurrent spike in arcing activity on the circuit. As shown in FIG. 35, the CVDA detection model 3308 receives as input the hourly summary of sensor data retrieved from the database 216, and processes that data through a multi-stage sequential pipeline whose output is transmitted to the threat assessment subsystem 3302.

In the first stage, model 3308 applies the voltage dip detection function 3502 to identify candidate voltage dip events in the hourly summary data by monitoring the per-cycle RMS voltage measurements and flagging time windows in which the RMS voltage falls below a predetermined threshold or in which the rate of voltage decline exceeds a predetermined rate threshold. Candidate voltage dip events identified by function 3502 are passed to the voltage dip refinement function 3504, which applies additional filtering criteria to eliminate candidate events unlikely to represent genuine CVDA hazard events. In some embodiments, voltage dip refinement function 3504 evaluates one or more of the duration of the candidate voltage dip, the total magnitude of the voltage drop, and the noise characteristics of the voltage signal during the dip against predetermined criteria, and passes forward only those candidate events satisfying all applicable criteria to coincidence detection function 3506 and feature extraction function 3510.

Coincidence detection function 3506 receives data (e.g., feature vectors associated with the candidate events) corresponding to the candidate CVDA hazard events from function 3504 and data corresponding to detected arcing activity 3508. In some embodiments, coincidence detection function 3506 determines whether the voltage dip events identified by function 3504 are temporally coincident with elevated arcing activity as represented in the arcing activity data 3508. In some embodiments, function 3506 applies a predetermined coincidence window (which may be on the order of milliseconds to seconds) and confirms a candidate CVDA event only when a refined voltage dip event and a corresponding elevation in arcing activity are both detected within the coincidence window. Candidate events failing the coincidence test are discarded, while confirmed candidate CVDA events proceed to the subsequent processing stages. In some embodiments, the arcing activity data 3508 that serves as one of the two inputs to the coincidence detection function 3506 is generated by applying the image-based pattern matching process of the arcing signature detection model 3304 described herein to the same hourly summary data that serves as the primary input to the CVDA detection model 3308, such that the arcing characterization pipeline runs concurrently with the voltage dip detection and refinement stages of the pipeline.

In parallel with the coincidence detection, model 3308 applies the feature extraction function 3510 to the candidate CVDA hazard events from function 3504 and data corresponding to detected arcing activity 3508. In some embodiments, function 3510 generates a feature vector for each candidate voltage dip event characterizing both the voltage dip and the arcing activity detected within and around the candidate event time window. In some embodiments, the features extracted by function 3510 include, without limitation, the magnitude and duration of the candidate voltage dip, the rate of voltage decline during the dip, the peak amplitude and count of arcing transients detected during the candidate event window, the transient amplitude ratio computed across the candidate event window, the degree of noise elevation during the voltage dip, and statistical measures of the temporal relationship between the onset of the voltage dip and the onset of elevated arcing activity.

As shown in FIG. 35, the outputs of the coincidence detection function 3506 and the feature extraction function 3510 are combined at feature merging stage 3512 prior to being provided to the false positive rejection function 3514. The merging stage 3512 generates a unified input representation comprising both the coincidence determination produced by function 3506 and the quantitative characterization feature vector produced by function 3510, ensuring that the false positive rejection classifier receives a complete description of each confirmed candidate CVDA event-including both the temporal coincidence assessment and the underlying signal characteristics—as required to make an accurate classification decision.

Model 3308 applies the false positive rejection function 3514 to the candidate CVDA events. Function 3514 applies a gradient boosted tree machine learning classifier (e.g., XGBoost) to the feature vectors generated by the feature extraction function 3510 to distinguish genuine CVDA hazard events from false positives. As described above with respect to the GC model 3306, the classifier employed by function 3514 is trained on a labeled historical dataset comprising confirmed genuine CVDA hazard events and confirmed false positive candidate events, and the classifier generates a probability score for each candidate event quantifying the likelihood that the event represents a genuine CVDA hazard. Candidate events with a probability score below a predetermined threshold are rejected as false positives and discarded.

As shown in FIG. 35, the external filtering stages are depicted in the lower portion of the figure, with the flow proceeding from grid event filtering function 3516 through lightning filtering function 3520, before the confirmed CVDA hazard events exit the CVDA detection model 3308 and are transmitted to the threat assessment subsystem 3302. Candidate CVDA events remaining after application of false positive rejection function 3514 are then subjected to two external filtering stages designed to remove events whose timing coincides with known external confounding phenomena. Grid event filtering function 3516 analyzes grid event data 3518 (e.g., retrieved from database 216) comprising records of known utility grid disturbances-such as voltage sags, switching events, and other power quality events on the utility distribution network- and removes candidate CVDA events whose timing coincides with a known grid event, as such events may produce voltage dips resembling the CVDA signature in the absence of any hazardous arcing condition within the home. The remaining candidate CVDA events are then processed using the lightning filtering function 3520, which analyzes weather data 3522 (e.g., retrieved from database 216) comprising real-time or historical lightning strike geolocation and timing data and removes candidate CVDA events whose timing coincides with a nearby lightning strike, as lightning events can produce impulsive voltage disturbances that may independently trigger both the voltage dip and arcing detection stages of the pipeline. In some embodiments, both the grid events data 3518 and the weather data 3522 can be updated in near-real-time via external data feeds received by the server computing device 214 and/or the database 216 over the network 212. Candidate CVDA events that remain after all filtering stages of model 3308 are output as confirmed CVDA hazard events. The output of model 3308 can comprise a CVDA probability score and the characterization feature vector generated by feature extraction function 3510. Such output is provided to the threat assessment subsystem 3302 for incorporation into the composite threat score, as described herein.

The probability scores and characterization feature vectors generated by each of the specialized detection models 3304, 3306, and 3308 upon completion of their respective detection pipelines are transmitted to the threat assessment subsystem 3302. Returning to FIG. 33, the threat assessment subsystem 3302 aggregates these outputs together with the hazard signal history data 3310, voltage activity data 3312, and time-of-day pattern data 3314 retrieved from the database 216, and generates a composite threat score for each sensor device 204 as described below. Threat assessment subsystem 3302 generates a composite threat score for each sensor device 204 in the network by applying one or more machine learning algorithms to a feature set derived from the hazard signal history data 3310, voltage activity data 3312, and time-of-day pattern data 3314 retrieved from the database 216, together with the probability scores and characterization features transmitted by the specialized hazard detection models 3304, 3306, and 3308 for the most recent analysis window. The composite threat score represents a single, unified quantitative assessment of the likelihood that a genuine, high-severity fire hazard currently exists at the location monitored by the sensor device 204. In some embodiments, the composite threat score is computed on a continuous scale from 0.0 to 1.0, wherein a score of 0.0 indicates no detected hazard activity and a score of 1.0 indicates the highest possible likelihood of a genuine fire hazard.

In some embodiments, the feature set provided as input to the machine learning model of the threat assessment subsystem 3302 comprises one or more of the following categories of features. The first category comprises current detection model outputs, including the probability scores generated by each of the specialized detection models 3304, 3306, and 3308 for the most recent hourly analysis window, binary indicators specifying whether a confirmed candidate hazard event of each type was detected during that window, and the characterization features associated with any confirmed candidate events (such as the transient amplitude ratio, exponential decay fit parameters, and coincidence detection outputs as applicable to each model). The second category comprises hazard signal history features derived from the hazard signal history data 3310, including the frequency and severity of confirmed candidate events detected by each specialized detection model over preceding time windows of varying durations-such as the preceding twenty-four hours, seven days, thirty days, etc.—the trend in probability scores generated by each specialized detection model over the preceding time windows, and binary indicators specifying whether FST-confirmed genuine hazard events have previously been detected at the monitored location. The third category comprises voltage activity features derived from the voltage activity data 3312, including the mean and maximum RMS voltage measured during the most recent analysis window, the trend in RMS voltage over the preceding time windows, the count and amplitude of voltage dip events detected during the most recent analysis window, and indicators of any power quality events detected during the analysis window. The fourth category comprises temporal pattern features derived from the time-of-day pattern data 3314, including the degree to which the electrical activity detected during the most recent analysis window conforms to or deviates from the established temporal patterns of the monitored location, the time of day and day of week of the most recent analysis window, and the consistency and recurrence rate of any detected hazard activity across prior instances of the same time-of-day window.

In some embodiments, the machine learning model employed by the threat assessment subsystem 3302 to generate the composite threat score is a gradient boosted tree model (e.g., XGBoost) trained on a labeled historical dataset comprising prior analysis windows for which the ground truth hazard status has been determined through FST review and customer engagement. The gradient boosted tree model is well-suited to this task because it is capable of learning complex, non-linear relationships between the input features and the hazard outcome, is robust to missing or sparse feature values that may arise when certain detection models have not generated confirmed candidate events during a given analysis window, and produces probability outputs that are well-calibrated and interpretable as a continuous threat score. In other embodiments, the machine learning model is a logistic regression model, a random forest model, a deep neural network, or an ensemble of two or more such models, and the selection of the model architecture may be informed by the volume of available labeled training data, the computational resources available to the server computing device 214, and the desired balance between model interpretability and predictive accuracy.

In some embodiments, the threat assessment subsystem 3302 applies a set of predefined weighting rules to the outputs of the specialized detection models prior to or in combination with the machine learning model, in order to ensure that certain hazard types or combinations of hazard indicators are given appropriate weight in the composite threat score regardless of the learned model parameters. For example, in some embodiments, the simultaneous detection of confirmed candidate events by two or more of the specialized detection models 3304, 3306, and 3308 within the same analysis window is treated as a strong indicator of a genuine hazard and results in an automatic elevation of the composite threat score above a predetermined minimum value, on the basis that the independent confirmation of hazardous activity by multiple detection models significantly reduces the likelihood of a false positive outcome. In some embodiments, a confirmed CVDA candidate event that has survived both the false positive rejection function 3514 and the grid event and lightning filtering stages 3516 and 3520 is treated as a particularly strong hazard indicator and is assigned a disproportionately high weight in the composite threat score, reflecting the high specificity of the CVDA detection pipeline and the severity of the fire risk associated with confirmed CVDA events.

In some embodiments, the threat assessment subsystem 3302 further applies a temporal smoothing function to the composite threat scores generated across successive analysis windows for a given sensor device 204, in order to reduce the impact of transient fluctuations in the detection model outputs and produce a more stable and reliable threat score time-series. In some embodiments, the temporal smoothing function is an exponentially weighted moving average applied to the composite threat scores over a sliding time window, wherein the smoothing factor is configurable and may be adjusted to balance the responsiveness of the composite threat score to new detection events against its stability in the absence of sustained hazard activity. In some embodiments, the threat assessment subsystem 3302 also computes a trend metric quantifying the rate of change of the composite threat score over the preceding time windows, and incorporates the trend metric as an additional input to the escalation decision-such that a sensor device 204 exhibiting a rapidly increasing composite threat score is escalated for FST review at a lower absolute threshold value than a sensor device 204 whose composite threat score has been stable over the same period, reflecting the heightened urgency associated with a developing and worsening hazard condition.

As shown in FIG. 33, the composite threat score generated by the threat assessment subsystem 3302 for each sensor device 204 is transmitted to the alert generation module 214b of server computing device 214. The alert generation module 214b receives the composite threat score and, in some embodiments, the underlying probability scores, characterization features, and trend metrics generated by the threat assessment subsystem 3302 and the specialized detection models 3304, 3306, and 3308, and uses these inputs to determine whether and how to generate and transmit one or more alert signals to one or more remote computing devices associated with the monitored location. The alert generation module 214b performs this determination continuously as new composite threat scores are generated by the threat assessment subsystem 3302 for each sensor device 204 in the network, enabling real-time or near-real-time notification of hazard conditions as they develop.

In some embodiments, the alert generation module 214b maintains a discrete level classification for each sensor device 204 in the network, wherein the level classification represents a persistent, stateful characterization of the sensor device's current hazard status and escalation priority. In some embodiments, the level classification comprises a plurality of named levels representing distinct escalation states-including, without limitation, a monitoring level indicating that the sensor device is under automated observation with no active escalation, a watching level indicating that the sensor device has exhibited hazard activity warranting elevated monitoring but has not yet met the threshold for FST engagement, and a ready-to-engage level indicating that the sensor device has met the composite threat score threshold and has been escalated for FST review and potential customer engagement. In some embodiments, additional intermediate levels may be defined to represent transitional states between the primary escalation levels, enabling more granular characterization of the sensor device's hazard status trajectory.

The alert generation module 214b updates the level classification of each sensor device 204 automatically as new composite threat scores are generated by the threat assessment subsystem 3302, applying predetermined transition rules to determine when a sensor device should be advanced to a higher escalation level or returned to a lower escalation level based upon its current and historical composite threat scores. The current level classification of each sensor device 204, together with a timestamped history of all level transitions over a preceding time period, is stored in the hazard signal history data 3310 of the database 216 and is presented to FST reviewers as part of the case review interface described herein. In some embodiments, the level transition history displayed to FST reviewers includes, for each transition, the timestamp of the transition, the prior and subsequent level classifications, the composite threat score at the time of the transition, and the specific detection model outputs that contributed to the transition. This level transition history enables FST reviewers to understand not only the current escalation status of a sensor device but also the trajectory and persistence of its hazard activity over time, and serves as one of the inputs to the case readiness determination described below.

In some embodiments, the alert generation module 214b compares the composite threat score received from the threat assessment subsystem 3302 against a configurable escalation threshold to determine whether the sensor device 204 should be escalated for active review and engagement. As described herein, this threshold is tunable between a selective mode and a sensitive mode, enabling an operator of the system 200 to calibrate the escalation rate to balance the competing risks of missed hazard detections and excessive false positive escalations. When the composite threat score meets or exceeds the escalation threshold, the alert generation module 214b initiates the generation and transmission of one or more alert signals to the appropriate remote computing devices, as described in further detail below. When the composite threat score falls below the escalation threshold, the alert generation module 214b does not generate an immediate alert signal, and the sensor device 204 is instead maintained in a lower-priority monitoring queue for continued automated observation by the threat assessment subsystem 3302.

In some embodiments, the alert generation module 214b determines the urgency level of the alert signal based upon the magnitude of the composite threat score, the specific combination of specialized detection model outputs contributing to the score, and the trend in the composite threat score over the preceding time windows. In some embodiments, the alert generation module 214b applies a multi-tier urgency classification to the composite threat score, wherein each tier corresponds to a predetermined range of threat score values and a corresponding set of alert actions. For example, in some embodiments, sensor devices 204 with composite threat scores in a highest urgency tier (such as those at or above a first threshold value, or those exhibiting a rapidly increasing threat score trend) trigger immediate, high-priority alert signals that are simultaneously transmitted to FST computing devices, homeowner mobile devices, and the sensor devices 204 themselves. Sensor devices 204 with composite threat scores in an intermediate urgency tier may trigger alert signals transmitted to FST computing devices for review and case assignment, without an immediate notification to the homeowner, pending FST assessment of the detected hazard. Sensor devices 204 with composite threat scores in a lower urgency tier may trigger only internal logging and continued automated monitoring without any immediate outbound alert signal, while remaining in an elevated monitoring state that reduces the time between successive composite threat score computations to enable more rapid detection of any worsening hazard condition.

When the alert generation module 214b determines that an alert signal should be generated, it prepares and transmits the alert signal to one or more of the following categories of remote computing devices. First, in some embodiments, the alert generation module 214b transmits the alert signal to one or more FST computing devices—that is, computing devices operated by members of the Fire Safety Team responsible for reviewing escalated sensor cases and coordinating hazard mitigation with homeowners and electricians. The alert signal transmitted to FST computing devices comprises, in some embodiments, a notification indicating that the sensor device 204 has been escalated for review, together with the composite threat score, the underlying probability scores generated by each of the specialized detection models 3304, 3306, and 3308, the characterization features associated with any confirmed candidate hazard events, the hazard signal history data 3310 for the sensor device 204, one or more heatmap visualizations of the arcing probability and threat score over time as described herein, and relevant metadata identifying the sensor device 204 and its associated customer account. In some embodiments, the heatmap visualization generated by the threat assessment subsystem 3302 further overlays numerical probability values on individual heatmap cells whose probability scores meet or exceed a predetermined display threshold. In some embodiments, the overlaid numerical values are rendered in a contrasting color relative to the background color of the heatmap cell—for example, in a high-contrast foreground color against the color-coded cell background-such that FST reviewers can both visually assess the overall distribution of hazard probability across the time-of-day and date dimensions of the heatmap and quantitatively evaluate the specific probability values associated with the highest-risk time windows without requiring a separate data table or tooltip interaction. In some embodiments, the display threshold above which numerical values are overlaid is configurable and may be adjusted by an operator of the system 200 or by individual FST reviewers to suit their review preferences and workflow requirements

In some embodiments, the alert signal transmitted to FST computing devices further comprises one or more algorithm-generated hazard characterization flags that translate the outputs of the specialized detection models into structured plain-language descriptions of the detected hazard activity for the benefit of FST reviewers. In some embodiments, each hazard characterization flag comprises a hazard type identifier specifying the category of hazardous electrical activity detected-such as continuous wide parallel arcing, glowing connection, or coincident voltage dip and arcing-together with a count of confirmed candidate events of that hazard type detected within a preceding time window and the duration of that time window. For example, a hazard characterization flag might indicate that a continuous wide parallel arcing condition has been detected, with four confirmed events identified within the preceding three days. In some embodiments, the alert generation module 214b generates hazard characterization flags for each of the specialized detection models 3304, 3306, and 3308 that has produced one or more confirmed candidate events within the analysis window, and presents the flags in order of decreasing severity to enable FST reviewers to rapidly assess the most critical aspects of the detected hazard activity. In some embodiments, the hazard characterization flags are also used by the alert generation module 214b to determine the content of the push notification transmitted to homeowner mobile devices, as described below. In some embodiments, the transmission of the alert signal to FST computing devices initiates the entry of the sensor device 204 into a review queue, enabling FST members to review the escalated case and determine whether and how to engage the customer.

In some embodiments, the review queue and associated case management functions of the hazard engagement pipeline are implemented in conjunction with one or more external case management or customer relationship management systems communicably coupled to the server computing device 214 via the network 212. In such embodiments, escalated sensor cases are automatically synchronized between the alert generation module 214b and the external case management system, such that FST case managers can access the full case detail-including the composite threat score, hazard characterization flags, heatmap visualizations, automated annotations, categorical tags, and level transition history described herein-directly within the external case management system's interface without requiring a separate login to the system 200. In some embodiments, communications between FST members and homeowners conducted through the external case management system (including notes, call logs, and customer responses to troubleshooting prompts) are automatically synchronized back to the hazard signal history data 3310 of the database 216 and incorporated into the case readiness summary and the continuous learning feedback loop of the threat assessment subsystem 3302.

In some embodiments, the FST review process comprises two sequential determination steps before active customer engagement is initiated. The first step is the ‘ready-to-engage’ escalation determination described above—i.e., a determination that the sensor device's composite threat score meets or exceeds the configurable escalation threshold, resulting in the entry of the sensor device into the FST review queue. The second step is a case readiness determination, in which the assigned FST case manager evaluates a structured summary of the sensor device's history to determine whether the case is ready for active customer engagement—i.e., whether the available evidence is sufficient to warrant contacting the homeowner and initiating the guided troubleshooting process described herein.

In some embodiments, the case readiness determination is supported by a case readiness summary generated by the alert generation module 214b and presented to the FST case manager in the case review interface. The case readiness summary comprises, in some embodiments, one or more of: the number of times the sensor device has entered the ready-to-engage escalation level within a preceding time period, such as the preceding ninety days; the number of times the sensor device has been manually annotated by FST reviewers as exhibiting confirmed or probable hazard activity within the preceding time period; the number of times the sensor device has been in the watching escalation level within the preceding time period; the current and historical composite threat scores generated by the threat assessment subsystem 3302; the outputs and probability scores of each of the specialized detection models 3304, 3306, and 3308 for the most recent and preceding analysis windows; and the algorithm-generated hazard characterization flags described herein. In some embodiments, the alert generation module 214b further generates an automated case readiness recommendation based upon the case readiness summary. For example, module 214b can recommend immediate customer engagement when the sensor device has entered the ready-to-engage level multiple times within the preceding thirty days and has been annotated as exhibiting confirmed hazard activity on one or more prior occasions, or module 214b can recommend continued monitoring when the sensor device has entered the ready-to-engage level for the first time and the hazard characterization flags do not indicate a high-urgency hazard type. In some embodiments, the automated case readiness recommendation is presented to the FST case manager as a suggested action, which the case manager may accept or override based upon additional contextual information available to the reviewer. In all cases, the final case readiness determination is made by the FST case manager, and the outcome of that determination, together with any annotations or comments added by the reviewer, is recorded in the hazard signal history data 3310 of the database 216

Second, in some embodiments, the alert generation module 214b transmits the alert signal to one or more mobile computing devices associated with the owner or occupant of the building in which the sensor device 204 is installed via a mobile application installed on the device and communicably coupled to the server computing device 214 via the network 212. In some embodiments, the alert signal transmitted to homeowner mobile devices is in the form of a push notification that is automatically displayed on the screen of the mobile device upon receipt, and that includes a brief summary of the detected hazard condition and a prompt to open the mobile application for further information and guided troubleshooting steps. In some embodiments, the content, format, and urgency of the notification displayed to the homeowner are determined by the alert generation module 214b based upon the urgency tier of the composite threat score and the specific hazard type or types identified by the specialized detection models. For example, a confirmed CVDA hazard event may generate a notification indicating an immediate fire hazard requiring urgent action, while a lower-urgency arcing signature detection may generate a notification indicating that elevated electrical activity has been detected and that the homeowner should monitor the situation and contact the FST if the activity persists. In some embodiments, the mobile application displays to the homeowner a user interface consistent with that described above with respect to FIG. 31, prompting the homeowner to initiate the guided troubleshooting process using the decision tree algorithms described above with respect to FIGS. 30A-30D and FIG. 32.

Third, in some embodiments, the alert generation module 214b transmits the alert signal to one or more of the sensor devices 204 installed in the building associated with the escalated sensor device. Upon receipt of the alert signal, the sensor device 204 activates one or more embedded alert indication components to provide a local, physical indication of the detected hazard condition to persons in proximity to the sensor device 204. In some embodiments, the alert indication component activated by the sensor device 204 upon receipt of the alert signal comprises a light emitting diode (LED) element embedded in the exterior of the sensor device 204 that illuminates or flashes in a predetermined pattern to indicate that a hazard condition has been detected. In some embodiments, the sensor device 204 activates different visual indicator patterns depending upon the urgency tier of the received alert signal—e.g., a slow, steady illumination of the LED for a lower-urgency alert and a rapid flashing pattern for a highest-urgency alert—to enable persons in proximity to the sensor device 204 to immediately assess the relative severity of the detected condition. In some embodiments, the sensor device 204 additionally or alternatively activates an audible alert component, such as a speaker or buzzer embedded in the sensor device 204, upon receipt of a highest-urgency alert signal.

In some embodiments, the alert generation module 214b maintains a record of all alert signals generated and transmitted for each sensor device 204 in the hazard signal history data 3310 of the database 216, including the timestamp of each alert signal, the composite threat score and urgency tier at the time of generation, the specific remote computing devices to which the alert signal was transmitted, and the subsequent disposition of the escalated case as determined through FST review and customer engagement. This record enables the alert generation module 214b to avoid generating duplicate or redundant alert signals for the same underlying hazard condition, to track the progression of a hazard condition over time as successive composite threat scores are generated by the threat assessment subsystem 3302, and to provide the FST with a complete chronological history of alert activity associated with each sensor device 204 for use in case review and hazard investigation. In some embodiments, the historical alert record maintained in the hazard signal history data 3310—including the timestamps, urgency tiers, and disposition outcomes of all generated alert signals—also serves as a source of labeled training examples for the continuous improvement of the machine learning model employed by the threat assessment subsystem 3302, as described herein, thereby closing the feedback loop between the alert generation process and the model learning cycle.

The above-described techniques can be implemented in digital and/or analog electronic circuitry, or in computer hardware, firmware, software, or in combinations of them. The implementation can be as a computer program product, i.e., a computer program tangibly embodied in a machine-readable storage device, for execution by, or to control the operation of, a data processing apparatus, e.g., a programmable processor, a computer, and/or multiple computers. A computer program can be written in any form of computer or programming language, including source code, compiled code, interpreted code and/or machine code, and the computer program can be deployed in any form, including as a stand-alone program or as a subroutine, element, or other unit suitable for use in a computing environment. A computer program can be deployed to be executed on one computer or on multiple computers at one or more sites.

Method steps can be performed by one or more special-purpose processors executing a computer program to perform functions of the technology by operating on input data and/or generating output data. Method steps can also be performed by, and an apparatus can be implemented as, special purpose logic circuitry, e.g., a FPGA (field programmable gate array), a FPAA (field-programmable analog array), a CPLD (complex programmable logic device), a PSoC (Programmable System-on-Chip), ASIP (application-specific instruction-set processor), or an ASIC (application-specific integrated circuit), or the like. Subroutines can refer to portions of the stored computer program and/or the processor, and/or the special circuitry that implements one or more functions.

Processors suitable for the execution of a computer program include, by way of example, both general and special purpose microprocessors, and any one or more processors of any kind of digital or analog computer. Generally, a processor receives instructions and data from a read-only memory or a random-access memory or both. The essential elements of a computer are a processor for executing instructions and one or more memory devices for storing instructions and/or data. Memory devices, such as a cache, can be used to temporarily store data. Memory devices can also be used for long-term data storage. Generally, a computer also includes, or is operatively coupled to receive data from or transfer data to, or both, one or more mass storage devices for storing data, e.g., magnetic, magneto-optical disks, or optical disks. A computer can also be operatively coupled to a communications network in order to receive instructions and/or data from the network and/or to transfer instructions and/or data to the network. Computer-readable storage mediums suitable for embodying computer program instructions and data include all forms of volatile and non-volatile memory, including by way of example semiconductor memory devices, e.g., DRAM, SRAM, EPROM, EEPROM, and flash memory devices; magnetic disks, e.g., internal hard disks or removable disks; magneto-optical disks; and optical disks, e.g., CD, DVD, HD-DVD, and Blu-ray disks. The processor and the memory can be supplemented by and/or incorporated in special purpose logic circuitry.

To provide for interaction with a user, the above described techniques can be implemented on a computer in communication with a display device, e.g., a CRT (cathode ray tube), plasma, or LCD (liquid crystal display) monitor, for displaying information to the user and a keyboard and a pointing device, e.g., a mouse, a trackball, a touchpad, or a motion sensor, by which the user can provide input to the computer (e.g., interact with a user interface element). Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, and/or tactile input.

The above-described techniques can be implemented in a distributed computing system that includes a back-end component. The back-end component can, for example, be a data server, a middleware component, and/or an application server. The above-described techniques can be implemented in a distributed computing system that includes a front-end component. The front-end component can, for example, be a client computer having a graphical user interface, a Web browser through which a user can interact with an example implementation, and/or other graphical user interfaces for a transmitting device. The above-described techniques can be implemented in a distributed computing system that includes any combination of such back-end, middleware, or front-end components.

The components of the computing system can be interconnected by transmission medium, which can include any form or medium of digital or analog data communication (e.g., a communication network). Transmission medium can include one or more packet-based networks and/or one or more circuit-based networks in any configuration. Packet-based networks can include, for example, the Internet, a carrier internet protocol (IP) network (e.g., local area network (LAN), wide area network (WAN), campus area network (CAN), metropolitan area network (MAN), home area network (HAN)), a private IP network, an IP private branch exchange (IPBX), a wireless network (e.g., radio access network (RAN), Bluetooth, Wi-Fi, WiMAX, general packet radio service (GPRS) network, HiperLAN), and/or other packet-based networks. Circuit-based networks can include, for example, the public switched telephone network (PSTN), a legacy private branch exchange (PBX), a wireless network (e.g., RAN, code-division multiple access (CDMA) network, time division multiple access (TDMA) network, global system for mobile communications (GSM) network), and/or other circuit-based networks.

Information transfer over transmission medium can be based on one or more communication protocols. Communication protocols can include, for example, Ethernet protocol, Internet Protocol (IP), Voice over IP (VOIP), a Peer-to-Peer (P2P) protocol, Hypertext Transfer Protocol (HTTP), Session Initiation Protocol (SIP), H.323, Media Gateway Control Protocol (MGCP), Signaling System #7 (SS7), a Global System for Mobile Communications (GSM) protocol, a Push-to-Talk (PTT) protocol, a PTT over Cellular (POC) protocol, and/or other communication protocols.

Devices of the computing system can include, for example, a computer, a computer with a browser device, a telephone, an IP phone, a mobile device (e.g., cellular phone, personal digital assistant (PDA) device, laptop computer, electronic mail device), and/or other communication devices. The browser device includes, for example, a computer (e.g., desktop computer, laptop computer) with a World Wide Web browser (e.g., Microsoft® Internet Explorer® available from Microsoft Corporation, Mozilla® Firefox available from Mozilla Corporation). Mobile computing device include, for example, a Blackberry®. IP phones include, for example, a Cisco® Unified IP Phone 7985G available from Cisco Systems, Inc., and/or a Cisco® Unified Wireless Phone 7920 available from Cisco Systems, Inc.

Comprise, include, and/or plural forms of each are open ended and include the listed parts and can include additional parts that are not listed. And/or is open ended and includes one or more of the listed parts and combinations of the listed parts.

One skilled in the art will realize the invention may be embodied in other specific forms without departing from the spirit or essential characteristics thereof. The foregoing embodiments are therefore to be considered in all respects illustrative rather than limiting the invention described herein.

What is claimed is:

1. A computerized method of detecting hazardous electrical discharge activity in electrical wiring, the method comprising:
sensing, by one or more sensor devices coupled to a circuit, a multiple voltage cycle waveform generated by electrical activity on the circuit or on nearby branch circuits;
applying, by a computing device coupled to the one or more sensor devices, plurality of specialized hazard detection models to the waveform data, each specialized hazard detection model generating a probability score for a distinct category of hazardous electrical activity;
generating, by the computing device, a composite threat score for each of the one or more sensor devices based upon the probability scores; and
generating, by the computing device, one or more alert signals when the composite threat score for a sensor device meets or exceeds a configurable threshold.

2. The method of claim 1, wherein applying the plurality of specialized hazard detection models comprises applying each model to a structured summary of the waveform data collected over a preceding time window.

3. The method of claim 2, wherein the structured summary comprises, for each voltage cycle captured during the time window, one or more of: bin amplitude values; a transient amplitude ratio; an average transient amplitude for each of a plurality of phase sections; a root mean square voltage; and a count of candidate transient events.

4. The method of claim 1, wherein the plurality of specialized hazard detection models comprises a glowing connection detection model, and wherein applying the glowing connection detection model comprises:
identifying segments of the waveform data matching known glowing connection waveform characteristics;
determining abrupt voltage changes that are consistent with a glowing connection in the identified segments; and
classifying the identified segments to generate a glowing connection probability score.

5. The method of claim 1, wherein the plurality of specialized hazard detection models comprises a coincident voltage dip and arcing detection model, and wherein applying the coincident voltage dip and arcing detection model comprises:
detecting and refining candidate voltage dip events in the waveform data;
determining whether each refined candidate voltage dip event is temporally coincident with elevated arcing activity within a predetermined window;
extracting a feature vector characterizing both the voltage dip and the coincident arcing activity;
classifying the feature vector and the coincidence determination to generate a coincident voltage dip and arcing probability score.

6. The method of claim 5, further comprising filtering confirmed candidate events by removing events whose timing coincides with one or more of: a known utility grid disturbance and a nearby weather event.

7. The method of claim 1, wherein generating the composite threat score comprises applying a machine learning model to a feature set derived from one or more of: current detection model outputs;
hazard signal history data for the sensor device; voltage activity data for the sensor device; and time-of-day pattern data for the sensor device.

8. The method of claim 1, further comprising:
quantifying a rate of change of composite threat scores generated across successive analysis windows;
wherein the configurable threshold has greater sensitivity for a sensor device exhibiting a rapidly increasing rate of change.

9. The method of claim 1, further comprising applying one or more predefined weighting rules to the probability scores, wherein detection of confirmed candidate events by two or more specialized hazard detection models within a same analysis window results in an automatic elevation of the composite threat score.

10. The method of claim 1, further comprising:
annotating each confirmed candidate hazard event with structured metadata comprising the hazard type, probability score, and associated characterization features; and
assigning one or more categorical tags to each confirmed candidate hazard event characterizing one or more of the hazard type, severity, confidence level, and recommended escalation action.

11. The method of claim 1, further comprising automatically promoting a confirmed candidate hazard event to a heightened escalation status, bypassing the configurable threshold, when a probability score generated by one or more of the specialized hazard detection models meets or exceeds a predetermined hazard threshold.

12. A system for detecting hazardous electrical discharge activity in electrical wiring, the system comprising:
one or more sensor devices coupled to a circuit, each sensor device configured to sense a multiple voltage cycle waveform generated by electrical activity on the circuit or on nearby branch circuits; and
a computing device coupled to the one or more sensor devices, the computing device configured to:
apply a plurality of specialized hazard detection models to waveform data generated by the one or more sensor devices, each specialized hazard detection model generating a probability score for a distinct category of hazardous electrical activity;
generate a composite threat score for each of the one or more sensor devices based upon the probability scores; and
generate one or more alert signals when the composite threat score for a sensor device meets or exceeds a configurable threshold.

13. The system of claim 12, wherein the computing device is configured to apply each of the plurality of specialized hazard detection models to a structured summary of the waveform data collected over a preceding time window.

14. The system of claim 13, wherein the structured summary comprises, for each voltage cycle captured during the time window, one or more of: bin amplitude values; a transient amplitude ratio; an average transient amplitude for each of a plurality of phase sections; a root mean square voltage; and a count of candidate transient events.

15. The system of claim 12, wherein the plurality of specialized hazard detection models comprises a glowing connection detection model, and wherein the computing device is configured to apply the glowing connection detection model by:
identifying segments of the waveform data matching known glowing connection waveform characteristics;
determining abrupt voltage changes that are consistent with a glowing connection in the identified segments; and
classifying the identified segments to generate a glowing connection probability score.

16. The system of claim 12, wherein the plurality of specialized hazard detection models comprises a coincident voltage dip and arcing detection model, and wherein the computing device is configured to apply the coincident voltage dip and arcing detection model by:
detecting and refining candidate voltage dip events in the waveform data;
determining whether each refined candidate voltage dip event is temporally coincident with elevated arcing activity within a predetermined window;
extracting a feature vector characterizing both the voltage dip and the coincident arcing activity; and
classifying the feature vector and the coincidence determination to generate a coincident voltage dip and arcing probability score.

17. The system of claim 16, wherein the computing device is further configured to filter confirmed candidate events by removing events whose timing coincides with one or more of: a known utility grid disturbance and a nearby weather event.

18. The system of claim 12, wherein the computing device is configured to generate the composite threat score by applying a machine learning model to a feature set derived from one or more of: current detection model outputs; hazard signal history data for the sensor device; voltage activity data for the sensor device; and time-of-day pattern data for the sensor device.

19. The system of claim 12, wherein the computing device is further configured to:
quantify a rate of change of composite threat scores generated across successive analysis windows; and
increase the sensitivity of the configurable threshold for a sensor device exhibiting a rapidly increasing rate of change.

20. The system of claim 12, wherein the computing device is further configured to apply one or more predefined weighting rules to the probability scores, wherein detection of confirmed candidate events by two or more specialized hazard detection models within a same analysis window results in an automatic elevation of the composite threat score.

21. The system of claim 12, wherein the computing device is further configured to:
annotate each confirmed candidate hazard event with structured metadata comprising the hazard type, probability score, and associated characterization features; and
assign one or more categorical tags to each confirmed candidate hazard event characterizing one or more of the hazard type, severity, confidence level, and recommended escalation action.

22. The system of claim 12, wherein the computing device is further configured to automatically promote a confirmed candidate hazard event to a heightened escalation status, bypassing the configurable threshold, when a probability score generated by one or more of the specialized hazard detection models meets or exceeds a predetermined hazard threshold.
